(19) United States
(12) Patent Application Publication
(10) Pub. No.: US 2026/0271300 A1
(43) Pub. Date: Sep. 10, 2026

(54) Semiconductor Device

(71) Applicant: Semiconductor Energy Laboratory Co., Ltd., Kanagawa-ken (JP)

(72) Inventors: Fumito ISAKA, Zama, Kanagawa (JP); Yuji EGI, Atsugi, Kanagawa (JP); Shiyuu NUMATA, Atsugi, Kanagawa (JP); Shoki MIYATA, Atsugi, Kanagawa (JP); Takanori MATSUZAKI, Atsugi, Kanagawa (JP); Masahiro TAKAHASHI, Atsugi, Kanagawa (JP); Shunpei YAMAZAKI, Setagaya, Tokyo (JP)

(73) Assignee: Semiconductor Energy Laboratory Co., Ltd., Kanagawa-ken (JP)

(21) Appl. No.: 19/165,711

(22) PCT Filed: Mar. 11, 2024
(86) PCT No.: PCT/IB2024/052312

§ 371 Date: Sep. 16, 2025

(30) Foreign Application Priority Data
Mar. 17, 2023 (JP) 2023-042985
Jan. 10, 2024 (JP) 2024-001908

(51) Int. Cl. H10B 53/30; H10B 12/00; H10B 53/20; H10D 1/68; H10D 30/67; H10D 30/69; H10D 64/68

(52) U.S. Cl. CPC H10B 53/30; H10B 12/036; H10B 53/20; H10D 1/714; H10D 1/716; H10D 30/6728; H10D 30/6731; H10D 30/6739; H10D 30/6755; H10D 30/701; H10D 64/689; H10B 12/00

(57) ABSTRACT

A novel semiconductor device is provided. The semiconductor device includes a first conductive layer, a first insulating layer over the first conductive layer, a second conductive layer over the first insulating layer, a first semiconductor layer, a second insulating layer over the first semiconductor layer, a third insulating layer over the second insulating layer, and a third conductive layer over the third insulating layer. An opening portion reaching the first conductive layer is provided in the first insulating layer and the second conductive layer. In the opening portion, the first semiconductor layer includes a region in contact with the top surface of the first conductive layer, a region in contact with a side surface of the first insulating layer, and a region in contact with a side surface of the second conductive layer. The second insulating layer has a barrier property against oxygen. The third insulating layer is a ferroelectric containing hafnium, zirconium, at least one of the Group 3 elements in the periodic table, and oxygen, and the content percentage of at least one of the Group 3 elements in the periodic table in the third insulating layer is higher than or equal to 0.1 atomic % and lower than or equal to 5 atomic %.

### TECHNICAL FIELD

One embodiment of the present invention relates to a semiconductor device, a memory device, and an electronic device. One embodiment of the present invention relates to a method for manufacturing a semiconductor device.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

Thus, examples of the technical field of one embodiment of the present invention include a semiconductor device, a display device, a liquid crystal display device, a light-emitting device, a power storage device, an imaging device, a memory device, a signal processing device, a processor, an electronic device, a system, a driving method thereof, a manufacturing method thereof, a testing method thereof, and a usage method thereof.

### BACKGROUND ART

In recent years, semiconductor devices such as LSI, CPUs, and memories (memory devices) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM, an SRAM, and a flash memory.

Memories using ferroelectrics have been actively researched and developed as disclosed in Non-Patent Document 1. For the next-generation ferroelectric memories, researches on hafnium oxide, such as research on ferroelectric HfO₂-based materials (Non-Patent Document 2); research on ferroelectricity of a Hf_{0.5}Zr_{0.5}O₂ thin film (Non-Patent Document 3); research on ferroelectricity of a HfO₂ thin film (Non-Patent Document 4); and demonstration of integration of an FeRAM (Ferroelectric Random Access Memory) using a ferroelectric Hf_{0.5}Zr_{0.5}O₂ and a CMOS (Non-Patent Document 5) have been actively carried out.

### REFERENCE

### Non-Patent Documents

[Non-Patent Document 1] T. S. Boescke, et al., “Ferroelectricity in hafnium oxide thin films”, APL99, 2011
[Non-Patent Document 2] Zhen Fan, et al., “Ferroelectric HfO₂-based materials for next-generation ferroelectric memories”, JOURNAL OF ADVANCED DIELECTRICS, Vol. 6, No. 2, 2016
[Non-Patent Document 3] Jun Okuno, et al., “SoC compatible ITIC FeRAM memory array based on ferroelectric Hf_{0.5}Zr_{0.5}O₂”, VLSI 2020
[Non-Patent Document 4] Akira Toriumi, “Ferroelectric properties of thin HfO₂ films”, the Japan Society of Applied Physics, Vol. 88, No. 9, 2019 [Non-Patent Document 5] T. Francois, et al., “Demonstration of BEOL-compatible ferroelectric Hf_{0.5}Zr_{0.5}O₂ scaled FeRAM co-integrated with 130 nm CMOS for embedded NVM applications”, IEDM 2019

### SUMMARY OF THE INVENTION

### Problems to be Solved by the Invention

An object of one embodiment of the present invention is to provide a novel semiconductor device. An object of one embodiment of the present invention is to provide a semiconductor device that occupies a small area. An object of one embodiment of the present invention is to provide a highly reliable semiconductor device. An object of one embodiment of the present invention is to provide a semiconductor device with low power consumption. An object of one embodiment of the present invention is to provide a semiconductor device with high storage capacity.

Note that the objects of one embodiment of the present invention are not limited to the objects listed above. The objects listed above do not preclude the existence of other objects. The other objects are objects that are not described in this section and will be described below. The objects that are not described in this section will be derived from the description of the specification, the drawings, and the like and can be extracted as appropriate from the description by those skilled in the art. Note that the objects of one embodiment of the present invention do not have to achieve all of the objects listed above and the other objects. One embodiment of the present invention achieves at least one of the objects listed above and the other objects.

### Means for Solving the Problems

One embodiment of the present invention is a semiconductor device that includes a first conductive layer, a first insulating layer over the first conductive layer, a second conductive layer over the first insulating layer, a first semiconductor layer, a second insulating layer over the first semiconductor layer, a third insulating layer over the second insulating layer, and a third conductive layer over the third insulating layer. An opening portion reaching the first conductive layer is provided in the first insulating layer and the second conductive layer. At least a part of the first semiconductor layer is provided in the opening portion. In the opening portion, the first semiconductor layer includes a region in contact with a top surface of the first conductive layer, a region in contact with a side surface of the first insulating layer, and a region in contact with a side surface of the second conductive layer. The second insulating layer has a barrier property against oxygen. The third insulating layer has ferroelectricity. The third insulating layer contains hafnium, zirconium, at least one of Group 3 elements in the periodic table, and oxygen. A content percentage of the at least one of the Group 3 elements in the periodic table in the third insulating layer is higher than or equal to 0.1 atomic % and lower than or equal to 5 atomic %.

In the above semiconductor device, the at least one of the Group 3 elements in the periodic table is preferably one or both of lanthanum and yttrium.

In the above semiconductor device, the second insulating layer preferably contains aluminum and oxygen.

In the above semiconductor device, the third conductive layer preferably includes a region having a nitrogen concentration lower than or equal to 1 atomic %.

In the above semiconductor device, the third conductive layer preferably contains tungsten or ruthenium.

The above semiconductor device preferably includes a first layer between the third insulating layer and the third conductive layer, and the first layer preferably contains a metal contained in the third conductive layer and oxygen.

The above semiconductor device preferably includes a fourth conductive layer between the second insulating layer and the third insulating layer. At least a part of the fourth conductive layer is preferably positioned in the opening portion provided in the first insulating layer and the second conductive layer.

The above semiconductor device preferably includes a transistor above the second insulating layer, and the third conductive layer preferably includes a region in contact with the second semiconductor layer included in the transistor.

In the above semiconductor device, the first semiconductor layer preferably contains one or both of indium and zinc.

One embodiment of the present invention is a semiconductor device that includes a transistor and a capacitor. The capacitor includes a first conductive layer, a first insulating layer over the first conductive layer, and a second conductive layer over the first insulating layer. The first insulating layer has ferroelectricity. The first insulating layer contains hafnium, zirconium, at least one of Group 3 elements in the periodic table, and oxygen. A content percentage of the at least one of the Group 3 elements in the periodic table in the first insulating layer is higher than or equal to 0.1 atomic % and lower than or equal to 5 atomic %. The first conductive layer and the second conductive layer each include a region having a nitrogen concentration lower than or equal to 1 atomic %.

The above semiconductor device may include a second insulating layer, and a part of the capacitor may be positioned in an opening portion included in the second insulating layer.

The above semiconductor device may include a third insulating layer, and a part of the transistor may be positioned in an opening portion included in the third insulating layer.

In the above semiconductor device, the second conductive layer preferably has a function of one of a pair of electrodes of the capacitor and a function of one of a source electrode and a drain electrode of the transistor.

In the above semiconductor device, the first conductive layer preferably has a function of one of a pair of electrodes of the capacitor and a function of a gate electrode of the transistor.

In the above semiconductor device, the at least one of the Group 3 elements in the periodic table is preferably one or both of lanthanum and yttrium.

In the above semiconductor device, the first conductive layer and the second conductive layer each preferably contain tungsten or ruthenium.

It is preferable that, in the above semiconductor device, the capacitor further include a first layer and a second layer, the first layer be positioned between the first conductive layer and the first insulating layer, the second layer be positioned between the first insulating layer and the second conductive layer, the first layer contain a metal contained in the first conductive layer and oxygen, and the second layer contain a metal contained in the second conductive layer and oxygen.

In the above semiconductor device, the semiconductor layer included in the transistor preferably contains one or both of indium and zinc.

### Effect of the Invention

One embodiment of the present invention can provide a novel semiconductor device. One embodiment of the present invention can provide a semiconductor device that occupies a small area. One embodiment of the present invention can provide a highly reliable semiconductor device. One embodiment of the present invention can provide a semiconductor device with low power consumption. One embodiment of the present invention can provide a semiconductor device with high storage capacity.

Note that the effects of one embodiment of the present invention are not limited to the effects listed above. The effects listed above do not preclude the existence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1A is a plan view illustrating a structure example of a semiconductor device. FIG. 1B to

FIG. 1D are cross-sectional views illustrating the structure example of the semiconductor device.

FIG. 1E is an equivalent circuit diagram of the semiconductor device.

FIG. 2A to FIG. 2C are cross-sectional views illustrating structure examples of semiconductor devices.

FIG. 3A to FIG. 3D are cross-sectional views illustrating structure examples of semiconductor devices.

FIG. 4A and FIG. 4B are cross-sectional views illustrating a structure example of a semiconductor device.

FIG. 5A is a plan view illustrating a structure example of a semiconductor device. FIG. 5B to FIG. 5D are cross-sectional views illustrating the structure example of the semiconductor device.

FIG. 5E is an equivalent circuit diagram of the semiconductor device.

FIG. 6 is a cross-sectional view illustrating a structure example of a semiconductor device.

FIG. 7A is a plan view illustrating a structure example of a semiconductor device. FIG. 7B and FIG. 7C are cross-sectional views illustrating the structure example of the semiconductor device.

FIG. 8A is a plan view illustrating a structure example of a semiconductor device. FIG. 8B and FIG. 8C are cross-sectional views illustrating the structure example of the semiconductor device.

FIG. 9A is a plan view illustrating a structure example of a semiconductor device. FIG. 9B and FIG. 9C are cross-sectional views illustrating the structure example of the semiconductor device.

FIG. 10A is a plan view illustrating a structure example of a semiconductor device. FIG. 10B and FIG. 10C are cross-sectional views illustrating the structure example of the semiconductor device.

FIG. 11A and FIG. 11B are cross-sectional views illustrating structure examples of semiconductor devices.

FIG. 12 is a graph showing an example of hysteresis characteristics.

FIG. 13A and FIG. 13B are equivalent circuit diagrams of semiconductor devices. FIG. 13C is a diagram illustrating Id-Vg characteristics of transistors.

FIG. 14A is a timing chart for explaining an operation of a semiconductor device. FIG. 14B is a circuit diagram for explaining the operation of the semiconductor device.

FIG. 15A is a timing chart for explaining an operation of a semiconductor device. FIG. 15B is a circuit diagram for explaining the operation of the semiconductor device.

FIG. 16A is a timing chart for explaining an operation of a semiconductor device. FIG. 16B is a circuit diagram for explaining the operation of the semiconductor device.

FIG. 17A and FIG. 17B are cross-sectional views illustrating a structure example of a semiconductor device. FIG. 17C is an equivalent circuit diagram of the semiconductor device.

FIG. 18A and FIG. 18B are cross-sectional views illustrating a structure example of a semiconductor device. FIG. 18C is an equivalent circuit diagram of the semiconductor device.

FIG. 19A and FIG. 19B are cross-sectional views illustrating a structure example of a semiconductor device. FIG. 19C is an equivalent circuit diagram of the semiconductor device.

FIG. 20A and FIG. 20B are cross-sectional views illustrating a structure example of a semiconductor device. FIG. 20C is an equivalent circuit diagram of the semiconductor device.

FIG. 21 is a block diagram illustrating a structure example of a semiconductor device.

FIG. 22A and FIG. 22B are perspective views illustrating structure examples of semiconductor devices.

FIG. 23 is a block diagram illustrating a CPU.

FIG. 24A and FIG. 24B are perspective views of semiconductor devices.

FIG. 25A and FIG. 25B are perspective views of semiconductor devices.

FIG. 26A and FIG. 26B are drawings each showing a hierarchy of a variety of memory devices.

FIG. 27A and FIG. 27B are diagrams each illustrating an example of an electronic component.

FIG. 28A and FIG. 28B are diagrams each illustrating an example of an electronic device, and FIG. 28C to FIG. 28E are diagrams illustrating an example of a large computer.

FIG. 29 is a diagram illustrating an example of space equipment.

FIG. 30 is a diagram illustrating an example of a storage system that can be used in a data center.

FIG. 31A and FIG. 31B are cross-sectional views illustrating samples fabricated in Example.

FIG. 32A to FIG. 32D are diagrams showing P-V characteristics of Example.

FIG. 33A to FIG. 33C are diagrams showing P-V characteristics of Example.

FIG. 34A to FIG. 34D are diagrams showing rewrite endurance of Example.

FIG. 35A to FIG. 35C are diagrams showing rewrite endurance of Example.

FIG. 36A to FIG. 36D are diagrams showing I-V characteristics of Example.

FIG. 37A to FIG. 37C are diagrams showing I-V characteristics of Example.

FIG. 38A to FIG. 38C are diagrams showing P-E characteristics of Example.

FIG. 39A to FIG. 39C are diagrams showing endurance characteristics of Example.

FIG. 40A to FIG. 40C are diagrams showing rewrite endurance of Example.

FIG. 41A is a diagram showing P-V characteristics of Example. FIG. 41B is a diagram showing rewrite endurance of Example.

FIG. 42A and FIG. 42B are diagrams each showing XPS analysis results of Example.

### MODE FOR CARRYING OUT THE INVENTION

Embodiments and the like below will be described in detail with reference to the drawings. Note that the present invention is not limited to the following description, and it is readily understood by those skilled in the art that modes and details can be changed in various ways without departing from the spirit and scope of the present invention. Thus, the present invention should not be construed as being limited to the description in the following embodiments. Note that in the structures of the invention described below, the same portions or portions having similar functions are denoted by the same reference numerals in different drawings, and repeated description thereof is omitted in some cases.

In this specification and the like, a semiconductor device refers to a device that utilizes semiconductor characteristics, and means a circuit including a semiconductor element (a transistor, a diode, a photodiode, and the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting device, a lighting device, an electronic device, and the like themselves might be semiconductor devices, or might include semiconductor devices.

The position, size, range, and the like of each component illustrated in drawings and the like do not represent the actual position, size, range, and the like in some cases for easy understanding of the invention. Therefore, the disclosed invention is not necessarily limited to the position, size, range, and the like disclosed in the drawings and the like. For example, in the actual manufacturing process, a layer, a resist mask, and the like might be unintentionally reduced in size by treatment such as etching, which is not illustrated in some cases for easy understanding of the invention.

In this specification and the like, in the case where an etching step (a removal step) is performed after a resist mask is formed by a lithography method (e.g., a photolithography method, an X-ray lithography method, an electron beam lithography method, a multiphoton lithography method, an interference lithography method, or a nanoimprinting method), the resist mask is removed after the etching step, unless otherwise specified.

Especially in a plan view (also referred to as a “top view”), a perspective view, and the like, the illustration of some components might be omitted for easy understanding of the invention. The illustration of some hidden lines and the like might also be omitted.

Note that in the structures of the invention in the embodiments, the same portions or portions having similar functions are denoted by the same reference numerals in different drawings, and repeated description thereof is omitted in some cases. The same hatch pattern is used for the portions having similar functions, and the portions are not especially denoted by reference numerals in some cases. Some components are omitted in a perspective view, a plan view, and the like for easy understanding of the drawings in some cases.

Ordinal numbers such as “first” and “second” in this specification and the like are used in order to avoid confusion among components and do not denote any priority or order such as the order of steps or the stacking order. A term without an ordinal number in this specification and the like may be provided with an ordinal number in the scope of claims in order to avoid confusion among components. An ordinal number provided in this specification and the like and an ordinal number provided in the scope of claims might be different from each other. Even when a term is provided with an ordinal number in this specification and the like, the ordinal number might be omitted in the scope of claims and the like.

In this specification and the like, terms such as “electrode”, “wiring”, and “terminal” do not limit the functions of such components. For example, an “electrode” is used as part of a “wiring” in some cases, and vice versa. Furthermore, terms such as “electrode” and “wiring” also include the case where a plurality of “electrodes” and “wirings” are provided in an integrated manner, for example. As another example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, terms such as “electrode”, “wiring”, and “terminal” can sometimes be replaced with a term such as “region” depending on the case.

In this specification and the like, supply of a signal refers to supply of a predetermined potential to a wiring or the like. The term “signal” can be replaced with a term such as “potential” in some cases. A term such as “potential” can be replaced with the term “signal” in some cases. The “signal” may be a variable potential or a fixed potential. For example, it may be a power supply potential.

Note that the term “film” and the term “layer” can be interchanged with each other depending on the case or circumstances. For example, the term “conductive layer” can be replaced with the term “conductive film” in some cases. As another example, the term “insulating film” can be replaced with the term “insulating layer” in some cases.

In this specification and the like, a “capacitor element” can be, for example, a circuit element having an electrostatic capacitance value greater than 0 F, a region of a wiring having an electrostatic capacitance value greater than 0 F, parasitic capacitance, or gate capacitance of a transistor. The term “capacitor element”, “parasitic capacitance”, or “gate capacitance” can be replaced with the term “capacitor” in some cases. Conversely, the term “capacitor” can be replaced with the term “capacitor element”, “parasitic capacitance”, or “gate capacitance” in some cases. In addition, a “capacitor” (including a “capacitor” with three or more terminals) includes an insulating layer and a pair of conductive layers between which the insulating layer is interposed. Thus, the term “pair of conductive layers” of “capacitor” can be replaced with “pair of electrodes”, “pair of conductive regions”, “pair of regions”, or “pair of terminals”. The term “one of a pair of terminals” is referred to as “one terminal” or “first terminal” in some cases. The term “the other of the pair of terminals” is referred to as “the other terminal” or “second terminal” in some cases. Note that the electrostatic capacitance value can be greater than or equal to 0.05 fF and less than or equal to 10 pF, for example. As another example, the electrostatic capacitance value may be greater than or equal to 1 pF and less than or equal to 10 μF.

Functions of a “source” and a “drain” of a transistor are sometimes interchanged with each other when a transistor of the opposite conductivity type is used or when the direction of current flow is changed in circuit operation, for example. Therefore, the terms “source” and “drain” can be used interchangeably in this specification and the like.

In this specification and the like, a “gate” refers to part or the whole of a gate electrode and a gate wiring. A gate wiring refers to a wiring for electrically connecting a gate electrode of at least one transistor to another electrode or another wiring.

In this specification and the like, a “source” refers to part or the whole of a source region, a source electrode, and a source wiring. A source region refers to a region in a semiconductor layer where the resistivity is lower than or equal to a given value. A source electrode refers to a conductive layer including part connected to a source region. A source wiring refers to a wiring for electrically connecting a source electrode of at least one transistor to another electrode or another wiring.

In this specification and the like, a “drain” refers to part or the whole of a drain region, a drain electrode, and a drain wiring. A drain region refers to a region in a semiconductor layer where the resistivity is lower than or equal to a given value. A drain electrode refers to a conductive layer including part connected to a drain region. A drain wiring refers to a wiring for electrically connecting a drain electrode of at least one transistor to another electrode or another wiring.

Unless otherwise specified, a transistor described in this specification and the like is an enhancement-mode (a normally-off mode) field-effect transistor. In the case where a transistor in this specification and the like is an n-channel transistor and unless otherwise specified, the threshold voltage (also referred to as “Vth”) of the transistor is higher than 0 V. In the case where the transistor in this specification and the like is a p-channel transistor and unless otherwise specified, Vth of the transistor is lower than or equal to 0 V. Unless otherwise specified, a plurality of transistors having the same conductivity type all have the same Vth.

Unless otherwise specified, an off-state current in this specification and the like refers to a current flowing between a source and a drain (also referred to as a “drain current” or “Id”) of a transistor in an off state (also referred to as a “non-conduction state” or a “cutoff state”). Unless otherwise specified, the off state of an n-channel transistor refers to a state where the potential difference between its gate and source based on the source (also referred to as a “gate voltage” or “Vg”) is lower than the threshold voltage, and the off state of a p-channel transistor refers to a state where Vg is higher than the threshold voltage. For example, the off-state current of an n-channel transistor sometimes refers to a drain current at the time when Vg is lower than Vth.

In this specification and the like, leakage current sometimes expresses the same meaning as off-state current. Furthermore, in this specification and the like, the off-state current sometimes refers to current that flows between a source and a drain of a transistor in an off state, for example.

Unless otherwise specified, an on-state current in this specification and the like refers to Id of a transistor in an on state (also referred to as a “conduction state”). Unless otherwise specified, the on state of an n-channel transistor refers to a state where Vg is higher than or equal to Vth, and the on state of a p-channel transistor refers to a state where Vg is lower than or equal to the threshold voltage. For example, the on-state current of an n-channel transistor sometimes refers to a drain current at the time when Vg is higher than or equal to Vth.

In this specification and the like, a high power supply potential VDD (hereinafter also simply referred to as “VDD” or a “potential H”) is a power supply potential higher than a low power supply potential VSS. The low power supply potential VSS (hereinafter also simply referred to as “VSS” or a “potential L”) is a power supply potential lower than the high power supply potential VDD. In addition, a ground potential GND (hereinafter also simply referred to as “GND”) can be used as VDD or VSS. For example, VSS is a potential lower than GND when VDD is GND, and VDD is a potential higher than GND when VSS is GND. Note that in this specification and the like, VSS is a reference potential unless otherwise specified.

A “voltage” usually refers to a potential difference between a given potential and a reference potential (e.g., a ground potential or a source potential). A “potential” is a relative value, and a potential supplied to a wiring or the like changes depending on the reference potential in some cases. Therefore, the terms “voltage” and “potential” can be replaced with each other in some cases.

In this specification and the like, terms for describing arrangement, such as “over”, “under”, “above”, and “below”, are sometimes used for convenience to describe the positional relationship between components with reference to drawings. The positional relationship between components changes as appropriate in accordance with a direction in which each component is described. Thus, without limitation to terms described in this specification and the like, the description can be changed appropriately depending on the situation. For example, the expression “an insulating layer positioned over a conductive layer” can be replaced with the expression “an insulating layer positioned under a conductive layer” when the direction of a drawing illustrating these components is rotated by 180°. For example, the expression “an insulating layer positioned over an opening” includes “an insulating layer positioned on a side surface of an opening” in some cases.

The term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and does not exclude the state where the electrode B is formed under the insulating layer A or the state where the electrode B is formed on the right (or left) side of the insulating layer A.

The terms “adjacent” and “close” in this specification and the like do not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In the drawings and the like for this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numeral. For example, a conductive layer 260 may be denoted separately as a conductive layer 260a and a conductive layer 260b.

### Embodiment 1

In this embodiment, a semiconductor device of one embodiment of the present invention will be described.

### <Structure Example of Semiconductor Device 10>

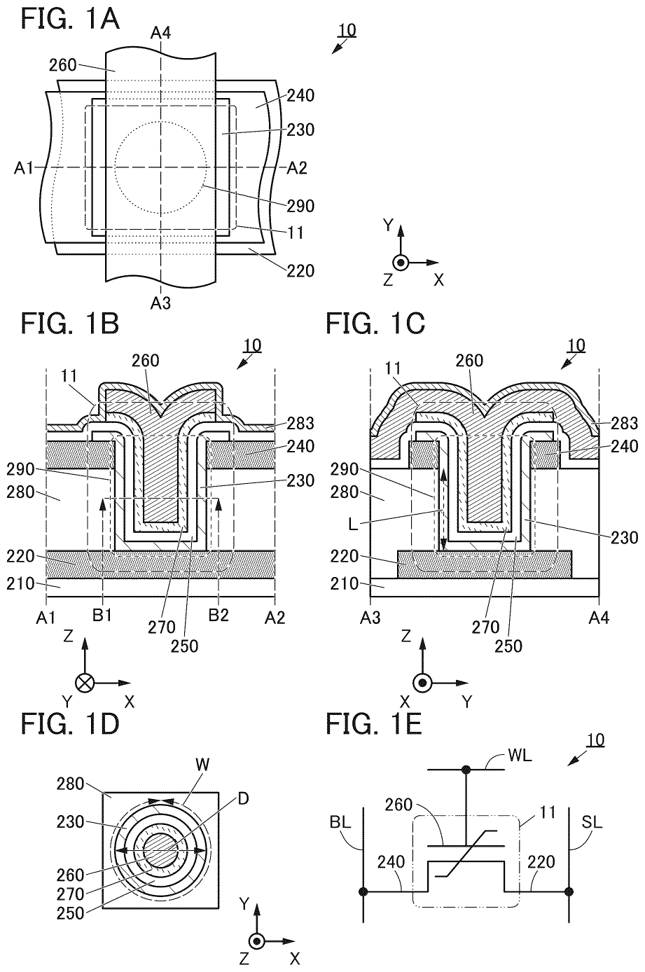

A semiconductor device 10 will be described with reference to FIG. 1A to FIG. 1E. FIG. 1A is a plan view of the semiconductor device 10. FIG. 1B is a cross-sectional view of a portion indicated by the dashed-dotted line A1-A2 in FIG. 1A, which is seen from the Y direction. FIG. 1C is a cross-sectional view of a portion indicated by the dashed-dotted line A3-A4 in FIG. 1A, which is seen from the X direction. Note that for clarity of the drawing, some components are omitted in the plan view of FIG. 1A.

The semiconductor device 10 includes an insulating layer 210 over a substrate (not illustrated), a transistor 11 over the insulating layer 210, an insulating layer 280 over the insulating layer 210, and an insulating layer 283 over the transistor 11. The insulating layer 210, the insulating layer 280, and the insulating layer 283 each function as an interlayer film.

The transistor 11 includes a conductive layer 220, a conductive layer 240 over the insulating layer 280, a semiconductor layer 230 over the conductive layer 220, an insulating layer 250 over the semiconductor layer 230, an insulating layer 270 over the insulating layer 250, and a conductive layer 260 over the insulating layer 270.

Note that in the semiconductor device described in this embodiment, the conductive layer 220 and the conductive layer 240 each include a region extending in the X direction. Note that the direction in which the conductive layer 220 extends and the direction in which the conductive layer 240 extends may be different from each other. For example, the direction in which the conductive layer 220 extends and the direction in which the conductive layer 240 extends may be orthogonal to each other.

The insulating layer 280 is provided over the conductive layer 220. An opening portion 290 reaching the conductive layer 220 is provided in the insulating layer 280 and the conductive layer 240. That is, the opening portion 290 is provided in a region overlapping with part of the conductive layer 220 in the plan view. Here, the bottom portion of the opening portion 290 is the top surface of the conductive layer 220, and a sidewall of the opening portion 290 is a side surface of the insulating layer 280 and a side surface of the conductive layer 240. The opening portion 290 includes an opening portion included in the insulating layer 280 and an opening portion included in the conductive layer 240. The opening portion included in the conductive layer 240 includes a region overlapping with the opening portion included in the insulating layer 280.

At least parts of the components of the transistor 11 are positioned in the opening portion 290. Specifically, at least part of each of the semiconductor layer 230, the insulating layer 250, the insulating layer 270, and the conductive layer 260 is positioned in the opening portion 290.

The semiconductor layer 230 is provided to cover the opening portion 290, the insulating layer 250 is provided to cover the semiconductor layer 230, the insulating layer 270 is provided to cover the insulating layer 250, and the conductive layer 260 is provided to fill a depressed portion that is defined by the insulating layer 270 and reflects the shape of the opening portion 290. Thus, portions of the semiconductor layer 230, the insulating layer 250, the insulating layer 270, and the conductive layer 260 that are positioned in the opening portion 290 reflect the shape of the opening portion 290.

The semiconductor layer 230 includes a region overlapping with a bottom portion of the opening portion 290 and a region overlapping with a side surface of the opening portion 290. In other words, in the opening portion 290, the semiconductor layer 230 includes a region in contact with the top surface of the conductive layer 220, a region in contact with the side surface of the insulating layer 280, and a region in contact with the side surface of the conductive layer 240. The semiconductor layer 230 includes a region in contact with the top surface of the conductive layer 240. In other words, part of the semiconductor layer 230 is electrically connected to the conductive layer 220, and another part of the semiconductor layer 230 is electrically connected to the conductive layer 240.

The thickness of the semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm. The thickness of the insulating layer 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulating layer 250 preferably includes a region with the above-described thickness.

The thickness of the insulating layer 270 is preferably less than or equal to 20 nm, further preferably less than or equal to 10 nm (typically greater than or equal to 2 nm and less than or equal to 9 nm). The thickness of the insulating layer 270 is preferably greater than or equal to 8 nm and less than or equal to 12 nm, for example. At least part of the insulating layer 270 preferably includes a region with the above-described thickness.

A semiconductor film to be the semiconductor layer 230, an insulating film to be the insulating layer 250, and an insulating film to be the insulating layer 270 are preferably formed by an atomic layer deposition (ALD) method. As described above, the semiconductor film to be the semiconductor layer 230, the insulating film to be the insulating layer 250, and the insulating film to be the insulating layer 270 are preferably deposited to have a small thickness and need to have small thickness variation. By contrast, the ALD method is a deposition method in which a precursor and a reactant (e.g., oxidizer) are alternately introduced and the film thickness can be adjusted with the number of repetition times of the cycle, enabling precise control of the film thickness. The ALD method enables atomic layers to be deposited one by one on the bottom portion and the side surface of the opening portion 290, whereby the semiconductor film to be the semiconductor layer 230, the insulating film to be the insulating layer 250, and the insulating film to be the insulating layer 270 can be deposited in the opening portion 290 with good coverage.

As illustrated in FIG. 1A, the conductive layer 260 includes a region extending beyond an end portion of the insulating layer 270. In the semiconductor device described in this embodiment, the conductive layer 260 includes a region extending in the Y direction.

The semiconductor layer 230 includes a region functioning as a semiconductor layer where a channel of the transistor 11 is formed (a semiconductor layer including a channel formation region), the conductive layer 260 includes a region functioning as a gate electrode of the transistor 11, and the insulating layer 250 and the insulating layer 270 each include a region functioning as a gate insulating layer of the transistor 11. Note that the gate insulating layer is referred to as a gate insulating film or a gate insulator in some cases.

The conductive layer 220 includes a region functioning as one of a source electrode and a drain electrode of the transistor 11, and the conductive layer 240 includes a region functioning as the other of the source electrode and the drain electrode of the transistor 11. For example, in the case where the conductive layer 220 includes a region functioning as the drain electrode of the transistor 11, the conductive layer 240 includes a region functioning as the source electrode of the transistor 11.

The channel of the transistor 11 is formed in the semiconductor layer 230 between a region of the semiconductor layer 230 that is in contact with the conductive layer 220 and a region of the semiconductor layer 230 that is in contact with the conductive layer 240. In other words, the transistor 11 is provided in a region including the opening portion 290.

The source electrode and the drain electrode of the transistor 11 are placed in the Z direction. That is, the source and the drain of the transistor 11 are positioned at different levels. In other words, the source and the drain of the transistor 11 are placed at different positions in the Z direction. Such a transistor is also referred to as a “vertical-channel transistor”, a “vertical transistor”, or a “VFET (Vertical Field Effect Transistor)”.

The source electrode and the drain electrode of the vertical-channel transistor of one embodiment of the present invention are positioned in the Z direction. That is, the channel formation region, the source region, and the drain region are positioned in the Z direction. The area occupied by the vertical-channel transistor can be smaller than that occupied by a planar transistor in which a channel formation region, a source region, and a drain region are provided separately on the XY plane.

Thus, when the vertical-channel transistor is used in a semiconductor device, the area occupied by the semiconductor device can be reduced. When the vertical-channel transistor is used in a semiconductor device, high integration of the semiconductor device can be achieved. For example, it is possible to increase the storage capacity per unit area of a memory device including the semiconductor device.

Here, FIG. 1D is a cross-sectional view of a portion indicated by the dashed-dotted line B1-B2 in FIG. 1B, which is seen from the Z direction. That is, FIG. 1D can be regarded as a cross-sectional view along the XY plane including the insulating layer 280.

As illustrated in FIG. 1D, the insulating layer 280 is in contact with the entire outer circumference of the semiconductor layer 230. Thus, the channel formation region of the transistor 11 can be formed in the entire outer circumference of a portion of the semiconductor layer 230 that is formed in the same layer as the insulating layer 280. Note that FIG. 1D can also be regarded as a cross-sectional view along the XY plane including the channel formation region of the semiconductor layer 230.

As illustrated in FIG. 1D, the semiconductor layer 230, the insulating layer 250, the insulating layer 270, and the conductive layer 260 are provided concentrically. Thus, a side surface of the conductive layer 260 provided at the center faces a side surface of the semiconductor layer 230 with the insulating layer 270 and the insulating layer 250 therebetween. That is, in the plan view, all the circumference of the semiconductor layer 230 serves as the channel formation region. In this case, for example, the channel width of the transistor 11 is determined by the length of the outer circumference of the semiconductor layer 230. In other words, the channel width of the transistor 11 is determined by the maximum width of the opening portion 290 (the maximum diameter in the case where the opening portion 290 is circular in the plan view). In FIG. 1D, a maximum width D of the opening portion 290 is indicated by a dashed double-dotted double-headed arrow, and a channel width W of the transistor 11 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thicknesses of the semiconductor layer 230, the insulating layer 250, the insulating layer 270, and the conductive layer 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be “D X x”.

In the case where the opening portion 290 is formed to be circular in the plan view, the semiconductor layer 230, the insulating layer 250, the insulating layer 270, and the conductive layer 260 are provided concentrically. This makes the distance between the conductive layer 260 and the semiconductor layer 230 substantially uniform, so that a gate electric field can be substantially uniformly applied to the semiconductor layer 230.

Although this embodiment describes the example where the opening portion 290 is circular in the plan view, the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 can be calculated as appropriate in accordance with the shape of the uppermost portion of the opening portion 290. For example, in the case where the opening portion is quadrangular in the plan view, the maximum width of the opening portion 290 can be the length of a diagonal line of the uppermost portion of the opening portion 290.

The channel length of the transistor 11 is the distance between the source region and the drain region. In other words, the channel length of the transistor 11 is determined by the thickness of the insulating layer 280 over the conductive layer 220. In FIG. 1C, a channel length L of the transistor 11 is indicated by a dashed double-headed arrow. In the cross-sectional view, the channel length L is the distance between an end portion of a region where the semiconductor layer 230 is in contact with the conductive layer 220 and an end portion of a region where the semiconductor layer 230 is in contact with the conductive layer 240. In other words, the channel length L corresponds to the length of the side surface of the insulating layer 280 on the opening portion 290 side in the cross-sectional view.

The channel length of a planar transistor is limited by the light exposure limit of photolithography, making further miniaturization difficult; by contrast, in the present invention, the channel length can be determined by the thickness of the insulating layer 280. Thus, the transistor 11 can have an extremely small channel length less than or equal to the light exposure limit of a photolithography apparatus used for processing (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 11 can have higher on-state current and improved frequency characteristics. The use of a vertical-channel transistor enables a semiconductor device with high operation speed to be provided.

Since the channel length L is determined in accordance with the thickness of the insulating layer 280, the transistor with a short channel length L can be formed with high accuracy. In addition, variations in characteristics among a plurality of the transistors 11 are also reduced. Thus, the semiconductor device including the transistors 11 can operate stably and have high reliability. The reduced variations in characteristics increases the circuit design flexibility of the semiconductor device, thereby reducing the operation voltage. Thus, the power consumption of the semiconductor device can be reduced.

Furthermore, the channel formation region, the source region, and the drain region can be formed in the opening portion 290. Thus, the area occupied by the transistor 11 can be smaller than that occupied by a planar transistor in which a channel formation region, a source region, and a drain region are provided separately on the XY plane. Accordingly, high integration of the semiconductor device can be achieved. In the case where the semiconductor device of one embodiment of the present invention is used in a memory device, the storage capacity per unit area can be increased.

The side surfaces of the insulating layer 280 and the conductive layer 240 in the opening portion 290 may each have a tapered shape. The taper angle of the side surface of each of the insulating layer 280 and the conductive layer 240 in the opening portion 290 (the taper angle of a side surface of the opening portion 290) is greater than or equal to 45° and less than or equal to 90°, preferably greater than or equal to 50° and less than or equal to 75°. Note that the taper angle of a side surface of a layer (an insulating layer, a conductive layer, or a semiconductor layer) refers to the angle formed between the bottom surface and the side surface of the layer. When the taper angle of the side surface of each of the insulating layer 280 and the conductive layer 240 in the opening portion 290 is reduced, the coverage with the semiconductor layer 230, the insulating layer 250, the insulating layer 270, and the conductive layer 260 that are formed in the opening portion 290 can be improved. By contrast, when the taper angle of the side surface of each of the insulating layer 280 and the conductive layer 240 in the opening portion 290 is increased, the area occupied by the transistor 11 can be reduced.

In the semiconductor device of one embodiment of the present invention, the channel length L of the transistor 11 is preferably smaller than at least the channel width W of the transistor 11. The channel length L of the transistor 11 of one embodiment of the present invention is greater than or equal to 0.1 times and less than or equal to 0.99 times, preferably greater than or equal to 0.5 times and less than or equal to 0.8 times the channel width W of the transistor 11. This structure enables a transistor with favorable electrical characteristics and high reliability.

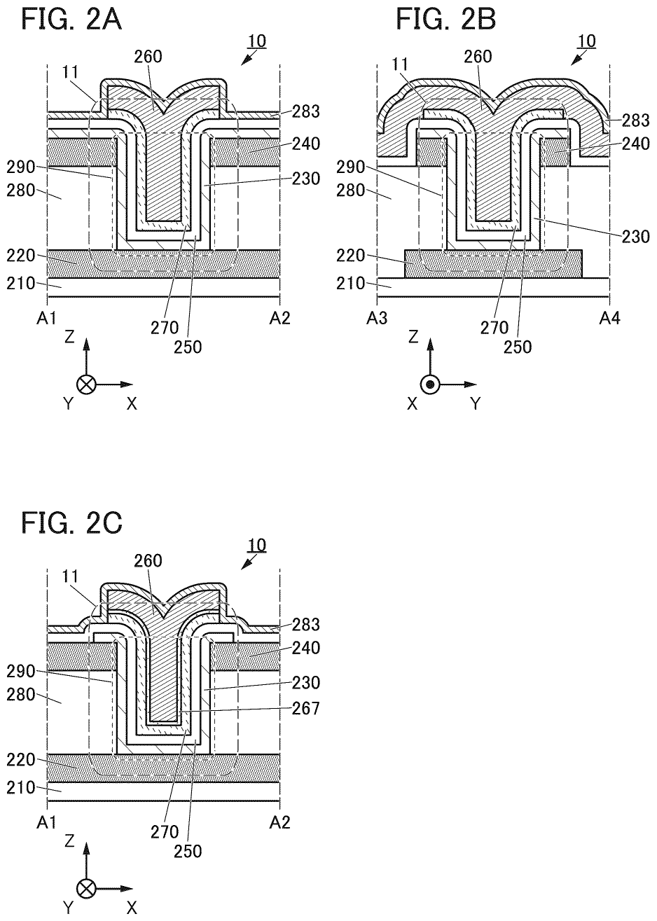

Although FIG. 1B illustrates the structure in which the semiconductor layer 230 is divided in the X direction, the present invention is not limited thereto. For example, as illustrated in FIG. 2A, the semiconductor layer 230 may be provided to extend in the X direction. Note that also in this structure, the semiconductor layer 230 is divided in the Y direction (see FIG. 2B). In this case, end portions of the semiconductor layer 230 and the conductive layer 240 are aligned with each other. Such a structure allows the semiconductor film to be the semiconductor layer 230 and the conductive film to be the conductive layer 240 to be successively processed using the same etching mask, so that the productivity of the semiconductor device can be improved.

A material that can have ferroelectricity is used for the insulating layer 270. In this case, the insulating layer 270 has ferroelectricity. Thus, the transistor 11 functions as an FeFET (Ferroelectric Field Effect Transistor). The threshold voltage of the FeFET is determined in accordance with the polarization generated in a gate insulating layer.

Here, a material that can have ferroelectricity is described. In this specification and the like, a material that can have ferroelectricity refers to a material that can have hysteresis characteristics in the relation between the intensity of an electric field applied to the material (electric field intensity) and the polarization magnitude, or a material in which spontaneous polarization occurs even with no external electric field (electric field applied to the material from the outside). Thus, the material that can have ferroelectricity includes a material having one or more of ferroelectricity, anti-ferroelectricity, and ferrielectricity.

In this specification and the like, the material that can have ferroelectricity processed into a layered shape is referred to as a ferroelectric layer in some cases. A device that includes such a ferroelectric layer is sometimes referred to as a ferroelectric device in this specification and the like.

As the material that can have ferroelectricity, an oxide containing one or both of hafnium and zirconium is given. As the metal oxide containing one or both of hafnium and zirconium, hafnium oxide, zirconium oxide, and hafnium zirconium oxide are given.

Ferroelectricity is presumably exhibited depending on a crystal structure of a crystal included in a ferroelectric layer. Thus, in order that the insulating layer 270 can exhibit ferroelectricity, the insulating layer 270 needs to include a crystal. It is particularly preferable that the insulating layer 270 include a crystal having an orthorhombic (space group: Pca21) crystal structure, in which case ferroelectricity is exhibited. In addition, when the proportion of the crystal having an orthorhombic structure in the insulating layer 270 is increased, the amount of remanent polarization can be increased.

Note that the higher the oxygen vacancy (Vo) concentration in an oxide containing one or both of hafnium and zirconium is, the more likely it is to generate a crystal having an orthorhombic crystal structure. Thus, an element that increases the oxygen vacancy concentration in the oxide containing one or both of hafnium and zirconium is preferably added to the oxide. Examples of the element include Group 3 elements (also referred to as Group IIIa elements) in the periodic table. The Group 3 element in the periodic table that is added to the oxide is further preferably one or more selected from scandium, lanthanum, and yttrium, still further preferably one or both of lanthanum and yttrium. Note that in this specification and the like, the Group 3 elements in the periodic table may be simply referred to as Group 3 elements.

In the oxide containing one or both of hafnium and zirconium, hafnium and zirconium are likely to have a valence of +4. Meanwhile, in an oxide containing a Group 3 element, the Group 3 element is likely to have a valence of +3. Thus, when an element having a valence different from that of hafnium and that of zirconium is added to the oxide containing one or both of hafnium and zirconium, the oxygen vacancy concentration in the oxide can be increased.

When at least one of the Group 3 elements is added to the oxide containing one or both of hafnium and zirconium, the grain size of a crystal included in the oxide can be reduced in some cases. By reducing the grain size of the crystals included in the oxide and reducing the grain size variation, the breakdown voltage of the oxide can be increased, enabling high withstand voltage. Furthermore, the amount of leakage current can be reduced.

When at least one of the Group 3 elements is added to the oxide containing one or both of hafnium and zirconium, a crystal having an orthorhombic crystal structure is sometimes more likely to be generated in the oxide than a crystal having a monoclinic crystal structure. This is probably because an element having a larger ion radius than hafnium and zirconium is added. In view of this, lanthanum and yttrium are particularly preferable as the Group 3 element added to the oxide.

Note that addition of excess Group 3 element to the oxide containing one or both of hafnium and zirconium might decrease the crystallinity of the oxide and adversely affect the generation of ferroelectricity. Thus, the content percentage of the Group 3 element added to the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the total number of metal element atoms contained in the ferroelectric layer. When the Group 3 element is added to the oxide within the above range, the remanent polarization can be improved, high withstand voltage can be achieved, and the amount of leakage current can be reduced, for example.

Accordingly, the insulating layer 270 preferably contains one or both of hafnium and zirconium, at least one of the Group 3 elements, and oxygen, further preferably contains hafnium, zirconium, at least one of the Group 3 elements, and oxygen, still further preferably contains hafnium, zirconium, one or both of lanthanum and yttrium, and oxygen. In other words, for the insulating layer 270, an oxide containing one or both of hafnium and zirconium to which at least one of the Group 3 elements is added is preferably used, hafnium zirconium oxide to which at least one of the Group 3 elements is added is further preferably used, and hafnium zirconium oxide to which one or both of lanthanum and yttrium are added is still further preferably used.

The content percentage of at least one of the Group 3 elements in the insulating layer 270 is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. For example, in the case where the insulating layer 270 contains lanthanum as at least one of the Group 3 elements, the content percentage of lanthanum in the insulating layer 270 preferably falls within the above range. In addition, for example, in the case where the insulating layer 270 contains lanthanum and yttrium as at least one of the Group 3 elements, the sum of the content percentage of lanthanum and the content percentage of yttrium in the insulating layer 270 preferably falls within the above range.

As described above, the insulating film to be the insulating layer 270 is preferably deposited by an ALD method. An ALD method, with which different kinds of precursors are introduced at a time, enables deposition of a film with a certain composition. In the case where different kinds of precursors are introduced, a film with a certain composition can be deposited by controlling the number of cycles for each of the precursors. Thus, an oxide whose content percentage of at least one of the Group 3 elements falls within the above range can be formed.

Note that by forming an oxide containing one or both of hafnium and zirconium, forming an oxide containing at least one of the Group 3 elements, and then performing heat treatment, an oxide containing one or both of hafnium and zirconium and at least one of the Group 3 elements may be formed.

Alternatively, by forming an oxide containing at least one of the Group 3 elements, forming an oxide containing one or both of hafnium and zirconium, and then performing heat treatment, an oxide containing one or both of hafnium and zirconium and at least one of the Group 3 elements may be formed.

Alternatively, by forming an oxide containing one or both of hafnium and zirconium and performing treatment adding the Group 3 element, an oxide containing one or both of hafnium and zirconium and at least one of the Group 3 elements may be formed. In that case, in the treatment adding the Group 3 element, oxygen vacancies are sometimes formed in the oxide containing one or both of hafnium and zirconium. That is, the addition of the Group 3 element can promote an increase in the oxygen vacancy concentration in the oxide. The treatment adding the Group 3 element can be performed by, for example, an ion doping method, an ion implantation method, or the like.

Note that a single layer or stacked layers of any of the materials that can have ferroelectricity and are described later in [Insulating layer] may be used for the insulating layer 270.

FIG. 1E is an equivalent circuit diagram of the semiconductor device 10. In FIG. 1E, one of a source and a drain of the transistor 11 is electrically connected to a wiring SL, the other of the source and the drain of the transistor 11 is electrically connected to a wiring BL, and a gate of the transistor 11 is electrically connected to a wiring WL. The semiconductor device 10 functions as a memory circuit (also referred to as a “memory element” or a “memory cell”). Note that FIG. 1E is an equivalent circuit diagram of the case where the transistor 11 includes a ferroelectric.

The conductive layer 220 functions as at least part of the wiring SL. The conductive layer 240 functions as at least part of the wiring BL. The conductive layer 260 functions as at least part of the wiring WL. Note that the wiring SL and the wiring BL can be interchanged with each other. The conductive layer 220 may function as at least part of the wiring BL, and the conductive layer 240 may function as at least part of the wiring SL.

For the conductive layer 260, a conductive material having a function of absorbing oxygen is preferably used. Since the conductive layer 260 is in contact with the insulating layer 270, the use of a conductive material having a function of absorbing oxygen for the conductive layer 260 enables oxygen to be absorbed from the insulating layer 270, so that the oxygen vacancy concentration in the insulating layer 270 can be increased. Accordingly, the remanent polarization can be increased. Examples of the conductive material having a function of absorbing oxygen include a metal element, an alloy containing a metal element as its component, and an alloy containing a combination of metal elements. As the alloy containing a metal element as its component, an oxide of the alloy may be used. Specific examples include tungsten, molybdenum, ruthenium, titanium, and tantalum. These conductive materials are also conductive materials that do not contain nitrogen. Note that in this specification and the like, a conductive material that does not contain nitrogen refers to a conductive material whose nitrogen concentration is lower than or equal to 1 atomic %.

For example, tungsten is a conductive material with high conductivity and thus can be suitably used for the conductive layer 260. Furthermore, since an oxide of ruthenium also has high conductivity, ruthenium can be suitably used for the conductive layer 260, for example. Thus, tungsten or ruthenium is preferably used for the conductive layer 260.

In the case where a conductive material having a function of absorbing oxygen is used for the conductive layer 260, oxygen in the insulating layer 270 is diffused into the conductive layer 260. Thus, the oxygen vacancy concentration in the insulating layer 270 has a gradient in the direction from the conductive layer 260 side toward the insulating layer 250 side. In other words, the direction in which oxygen vacancies are generated is the same as the direction from the conductive layer 260 side toward the insulating layer 250 side. In the case where an oxide containing one or both of hafnium and zirconium is formed and treatment adding a Group 3 element is performed as described above, the Group 3 element is preferably added in the direction in which oxygen vacancies are generated. Forming the insulating layer 270 in such a manner can further increase the oxygen vacancy concentration in the oxide.

Note that in the case where a conductive material having a function of absorbing oxygen is used for the conductive layer 260, a layer 267 is sometimes formed between the insulating layer 270 and the conductive layer 260 as illustrated in FIG. 2C. Here, when a metal contained in the conductive layer 260 is a metal MX, the layer 267 contains the metal MX and oxygen. In the case where an oxide containing the metal MX is used as the conductive layer 260, the oxygen concentration in the layer 267 is higher than that in the conductive layer 260. The concentration of the metal MX in the layer 267 is lower than that of the metal MX in the conductive layer 260.

The layer 267 may have conductivity or an insulating property. In the case where the layer 267 has conductivity, the layer 267 includes a region functioning as a gate electrode of the transistor 11. In the case where the layer 267 has an insulating property, the layer 267 includes a region functioning as a gate insulating layer of the transistor 11.

A conductive material containing nitrogen can be used for the conductive layer 260. Examples of the conductive material containing nitrogen include tantalum nitride, titanium nitride, a nitride containing titanium and aluminum, a nitride containing tantalum and aluminum, and ruthenium nitride. The use of a conductive material containing nitrogen for the conductive layer 260 can improve the crystallinity of the insulating layer 270 and the ferroelectricity of the insulating layer 270 in some cases. In addition, the reliability of the semiconductor device can be increased.

A conductive material that is less likely to be oxidized, a conductive material having a function of inhibiting diffusion of oxygen, or the like may be used for the conductive layer 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductive layer 260.

For the conductive layer 260, a single layer or stacked layers of any of the conductive materials described later in [Conductive layer] may be used.

The semiconductor layer 230 is provided inside the opening portion included in the insulating layer 280. Since the transistor 11 is a vertical-channel transistor, a channel is formed along a side surface of the opening portion included in the insulating layer 280.

As the semiconductor layer 230, a single layer or stacked layers of any of the semiconductor materials described later in [Semiconductor layer] can be used. In the transistor 11, a metal oxide functioning as a semiconductor (also referred to as an oxide semiconductor) is particularly preferably used for the semiconductor layer 230.

When oxygen vacancies (Vo) and impurities exist in a channel formation region in an oxide semiconductor in a transistor using the oxide semiconductor in the semiconductor layer 230 (also referred to as an OS transistor), the electrical characteristics of the transistor might vary easily and the reliability thereof might be degraded. In some cases, a defect that is an oxygen vacancy into which hydrogen has entered (hereinafter sometimes referred to as VoH) generates an electron serving as a carrier. Thus, when the channel formation region in the oxide semiconductor includes oxygen vacancies, the OS transistor is likely to have normally-on characteristics. Therefore, oxygen vacancies and impurities are preferably reduced as much as possible in the channel formation region in the oxide semiconductor. In other words, the oxide semiconductor preferably includes an i-type (intrinsic) or substantially i-type channel formation region with a low carrier concentration.

Note that in this specification and the like, “normally-on characteristics” means a state where a channel exists without application of a voltage to a gate and a current flows through the transistor. Meanwhile, “normally-off characteristics” means a state where a current does not flow through a transistor when no potential or a ground potential is applied to a gate.

Meanwhile, it is preferable that the source region and the drain region of the OS transistor include more oxygen vacancies, include more VoH, or have a higher concentration of impurities such as hydrogen, nitrogen, and a metal element than the channel formation region, and thus be low-resistance regions with high carrier concentrations. In other words, the source region and the drain region of the OS transistor are preferably n-type regions having a higher carrier concentration and a lower resistance than the channel formation region.

The insulating layer 210 and the insulating layer 280 function as interlayer films and thus preferably have low relative permittivity. When a material with low relative permittivity is used for an interlayer film, parasitic capacitance generated between wirings can be reduced. As the insulating layer 210 and the insulating layer 280, a single layer or stacked layers of any of the insulating layers each containing a material with low relative permittivity described later in [Insulating layer] can be used. Silicon oxide and silicon oxynitride are preferable because they are thermally stable.

The concentration of impurities such as water and hydrogen in the insulating layer 210 and the insulating layer 280 is preferably reduced. This can inhibit entry of impurities such as water and hydrogen into the channel formation region of the semiconductor layer 230.

As the insulating layer 280 placed in the vicinity of the channel formation region, an insulator containing oxygen that is released by heating (hereinafter, sometimes referred to as excess oxygen) is preferably used. By performing heat treatment on the insulating layer 280 containing excess oxygen, oxygen can be supplied from the insulating layer 280 to the channel formation region of the semiconductor layer 230 and oxygen vacancies and VoH can be reduced. Accordingly, the transistor 11 can have stable electrical characteristics and higher reliability.

As the insulating layer 280, any of the insulators having a function of capturing or fixing hydrogen described later in [Insulating layer] may be used. Such a structure enables hydrogen in the semiconductor layer 230 to be captured or fixed by the insulating layer 280, so that the hydrogen concentration in the semiconductor layer 230 can be reduced. For the insulating layer 280, magnesium oxide, aluminum oxide, or the like can be used.

As the insulating layer 280, any of the barrier insulators against hydrogen described later in [Insulating layer] may be used. When the insulating layer 280 provided outside the semiconductor layer 230 has a barrier property against hydrogen, diffusion of hydrogen into the semiconductor layer 230 can be inhibited.

Note that as each of the insulating layer 210 and the insulating layer 280, a single layer or stacked layers of any of the insulating materials described later in [Insulating layer] may be used.

Although the insulating layer 280 has a single layer in FIG. 1B and FIG. 1C, the present invention is not limited thereto. The insulating layer 280 may have a stacked-layer structure.

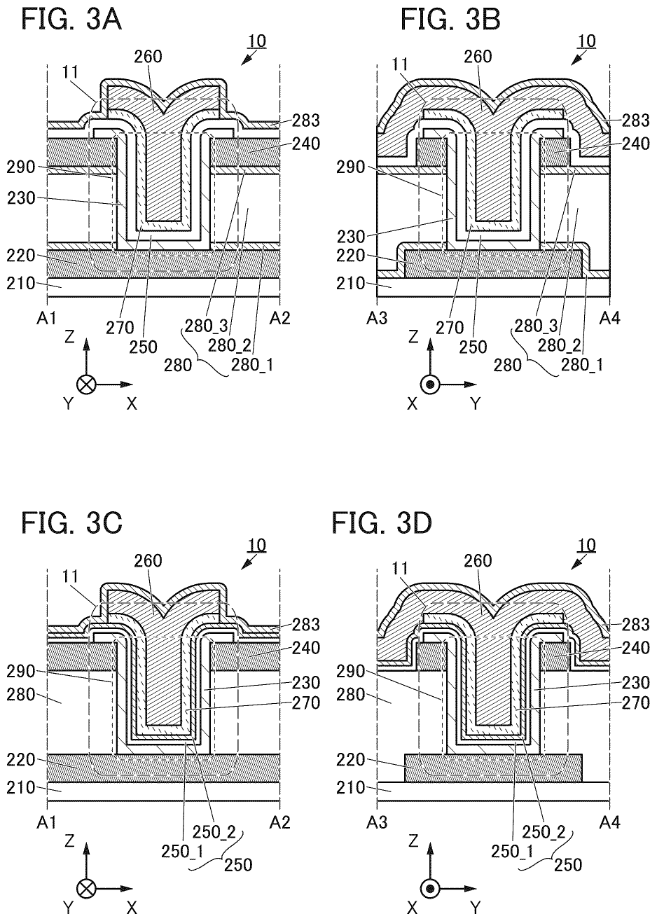

FIG. 3A and FIG. 3B are cross-sectional views of the semiconductor device 10. Note that FIG. 1A can be referred to for the plan view of the semiconductor device 10 illustrated in FIG. 3A and FIG. 3B. For example, as illustrated in FIG. 3A and FIG. 3B, the insulating layer 280 may have a stacked-layer structure of an insulating layer 280_1, an insulating layer 280_2 over the insulating layer 280_1, and an insulating layer 280_3 over the insulating layer 280_2.

The insulating layer 280_1 includes a region in contact with the top surface of the insulating layer 210 and regions in contact with a side surface and the top surface of the conductive layer 220. The insulating layer 280_3 includes a region in contact with the bottom surface of the conductive layer 240.

An insulator containing excess oxygen is preferably used as the insulating layer 280_2. The insulating layer 280_2 is preferably formed using a material with a low dielectric constant. When the insulating layer 280_2 is formed using a material with a low dielectric constant, parasitic capacitance generated between wirings can be reduced. Specifically, for the insulating layer 280_2, silicon oxide or silicon oxynitride can be used.

As each of the insulating layer 280_1 and the insulating layer 280_3, any of the barrier insulators against oxygen described later in [Insulating layer] is preferably used. Providing the insulating layer 280_1 between the insulating layer 280_2 and the conductive layer 220 can inhibit the conductive layer 220 from being oxidized and having high resistance. Furthermore, providing the insulating layer 280_3 between the insulating layer 280_2 and the conductive layer 240 can inhibit the conductive layer 240 from being oxidized and having high resistance. Note that for the insulating layer 280_1 and the insulating layer 280_3, the same material or different materials may be used.

For example, silicon nitride can be used for the insulating layer 280_1 and the insulating layer 280_3, and silicon oxide or silicon oxynitride can be used for the insulating layer 280_2. In that case, the insulating layer 280_1 and the insulating layer 280_3 each contain at least silicon and nitrogen. The insulating layer 280_2 contains at least silicon and oxygen.

As the insulating layer 280_1, an insulator having a function of capturing or fixing hydrogen may be used. With such a structure, diffusion of hydrogen from below the insulating layer 280_1 into the semiconductor layer 230 can be inhibited, and hydrogen contained in the semiconductor layer 230 can be captured or fixed. Thus, the hydrogen concentration in the semiconductor layer 230 can be reduced. Alternatively, for example, a stacked-layer film of aluminum oxide and silicon nitride over the aluminum oxide may be used as the insulating layer 280_1. Note that an insulator having a function of capturing or fixing hydrogen may be used as the insulating layer 280_3.

A material containing hydrogen may be used for the insulating layer 280_1 and the insulating layer 280_3. When the insulating layer containing hydrogen is in contact with the semiconductor layer 230, the semiconductor layer 230 in a region in contact with the insulating layer becomes n-type and can function as a source region or a drain region. For example, a material containing silicon, nitrogen, and hydrogen may be used for the insulating layer. Specifically, silicon nitride containing hydrogen, silicon nitride oxide containing hydrogen, or the like may be used.

The thickness of each of the insulating layer 280_1 and the insulating layer 280_3 is preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. The sizes of the source region and the drain region formed in the semiconductor layer 230 can be controlled by adjusting the thicknesses of the insulating layer 280_1 and the insulating layer 280_3.

The thickness of the insulating layer 280_2 is preferably greater than or equal to 1 nm and less than or equal to 50 nm, further preferably greater than or equal to 2 nm and less than or equal to 30 nm, still further preferably greater than or equal to 3 nm and less than or equal to 20 nm. The size of the channel formation region of the semiconductor layer 230 can be controlled by adjusting the thickness of the insulating layer 280_2.

Although FIG. 3A and FIG. 3B illustrate the structure in which the insulating layer 280_3 is provided over the planarized insulating layer 280_2, the present invention is not limited thereto. For example, the insulating layer 280_3 may be formed without performing planarization treatment on the insulating layer 280_2. By not performing planarization treatment, manufacturing cost can be reduced and production yield can be increased. In addition, the insulating layer 280_1, the insulating layer 280_2, and the insulating layer 280_3 can be successively formed without exposure to the air. By the formation without exposure to the air, impurities or moisture from the atmospheric environment can be prevented from being attached onto the insulating layer 280_1 to the insulating layer 280_3, so that the vicinity of the interface between the insulating layer 280_1 and the insulating layer 280_2 and the vicinity of the interface between the insulating layer 280_2 and the insulating layer 280_3 can be kept clean.

Note that although the insulating layer 280 has a stacked-layer structure of three layers in FIG. 3A and FIG. 3B, the present invention is not limited thereto. The insulating layer 280 may have a stacked-layer structure of two layers or four or more layers.

As the insulating layer 250, any of the barrier insulators against oxygen described later in [Insulating layer] is preferably used. The insulating layer 250 includes a region in contact with the semiconductor layer 230. When the insulating layer 250 has a barrier property against oxygen, release of oxygen from the semiconductor layer 230 at the time of performing heat treatment or the like can be inhibited. This can inhibit formation of oxygen vacancies in the semiconductor layer 230. Accordingly, the transistor 11 can have favorable electrical characteristics and higher reliability. For example, aluminum oxide or hafnium oxide is preferably used for the insulating layer 250. Aluminum oxide and hafnium oxide have a function of capturing or fixing hydrogen. Thus, the hydrogen concentration in the semiconductor layer 230 in contact with the insulating layer 250 can be reduced. Alternatively, for example, silicon nitride may be used for the insulating layer 250.

When a barrier insulator against oxygen is used as the insulating layer 250 provided between the conductive layer 260 and the insulating layer 280, diffusion of oxygen contained in the insulating layer 280 into the conductive layer 260 can be prevented and oxidation of the conductive layer 260 can be inhibited. Furthermore, a reduction in the amount of oxygen supplied from the insulating layer 280 to the semiconductor layer 230 can be inhibited.

In the semiconductor device 10, the insulating layer 270 functions as a gate insulating layer of the transistor 11. In the case where a ferroelectric is used for the insulating layer 270, unintentional current (leakage current) is likely to flow between the conductive layer 260 and the semiconductor layer 230. In view of this, a paraelectric is preferably used as the insulating layer 250 provided between the semiconductor layer 230 and the insulating layer 270. Note that a paraelectric is a material in which a polarization state is not maintained and disappears when voltage application is stopped after polarization is caused by the voltage application. The use of a paraelectric as the insulating layer 250 can prevent an increase in leakage current. Aluminum oxide is a paraelectric and thus is suitable for the insulating layer 250. In the case where aluminum oxide is used as the insulating layer 250, the insulating layer 250 contains at least aluminum and oxygen.

Note that as the insulating layer 250, a single layer or stacked layers of any of the insulating materials described later in [Insulating layer] may be used.

Although the insulating layer 250 has a single layer in FIG. 1B and FIG. 1C, the present invention is not limited thereto. The insulating layer 250 may have a stacked-layer structure.

FIG. 3C and FIG. 3D are cross-sectional views of the semiconductor device 10. Note that FIG. 1A can be referred to for the plan view of the semiconductor device 10 illustrated in FIG. 3C and FIG. 3D. For example, as illustrated in FIG. 3C and FIG. 3D, the insulating layer 250 may have a stacked-layer structure of an insulating layer 250_1 and an insulating layer 250_2 over the insulating layer 250_1.

The insulating layer 250_1 includes a region in contact with the top surface of the semiconductor layer 230 and regions in contact with the top surface and a side surface of the conductive layer 240. The insulating layer 250_2 includes a region in contact with the bottom surface of the insulating layer 270, a region in contact with the bottom surface of the conductive layer 260, and a region in contact with the bottom surface of the insulating layer 283.

As the insulating layer 250_1, any of the insulators having a function of capturing or fixing hydrogen described later in [Insulating layer] is preferably used. As the insulating layer 250_2, any of the barrier insulators against oxygen described later in [Insulating layer] is preferably used. With such a structure, the hydrogen concentration in the semiconductor layer 230 can be reduced. In addition, release of oxygen from the semiconductor layer 230 can be inhibited. Furthermore, oxidation of the conductive layer 260 can be inhibited.

Note that although the insulating layer 250 has a stacked-layer structure of two layers in FIG. 3C and FIG. 3D, the present invention is not limited thereto. The insulating layer 250 may have a stacked-layer structure of three or more layers.

As the conductive layer 220, a single layer or stacked layers of any of the conductors described later in [Conductive layer] can be used. For example, a conductive material with high conductivity such as tungsten can be used for the conductive layer 220. With the use of a conductive material with high conductivity, the conductive layer 220 can have improved conductivity and can function well as a wiring.

A single layer or stacked layers of a conductive material that is less likely to be oxidized, a conductive material having a function of inhibiting diffusion of oxygen, a conductive material containing oxygen, or the like is preferably used as the conductive layer 220. For example, titanium nitride, indium tin oxide to which silicon is added, or the like may be used. Alternatively, a structure in which titanium nitride is stacked over tungsten may be used, for example. Alternatively, for example, a structure in which tungsten is stacked over a first titanium nitride and a second titanium nitride is stacked over the tungsten may be used. Such a structure can inhibit the conductive layer 220 form being oxidized by the insulating layer 280 when an insulating material containing oxygen is used for the insulating layer 280.

As the conductive layer 240, a single layer or stacked layers of any of the conductors described later in [Conductive layer] can be used. For example, ruthenium is preferably used for the conductive layer 240. Ruthenium is a material having favorable contact resistance with the semiconductor layer 230 and thus can be suitably used. Furthermore, since an oxide of ruthenium also has conductivity, ruthenium has high conductivity and thus can be suitably used even in the case where its surface is oxidized in a manufacturing process, for example.

For example, a conductive material with high conductivity such as tungsten may be used for the conductive layer 240.

Alternatively, for example, a conductive material that is less likely to be oxidized, a conductive material having a function of inhibiting diffusion of oxygen, a conductive material containing oxygen, or the like may be used for the conductive layer 240. For example, titanium nitride, tantalum nitride, or the like can be used. Such a structure can inhibit excessive oxidation of the conductive layer 240 due to the semiconductor layer 230.

In the case where an oxide semiconductor is used for the semiconductor layer 230, a conductive material that makes an oxide semiconductor have n-type conductivity may be used for the conductive layer 220 in contact with the semiconductor layer 230 and the conductive layer 240 in contact with the semiconductor layer 230. For example, a conductive material containing nitrogen may be used. For example, a conductive material containing nitrogen and titanium or tantalum may be used. Another conductive material may be provided so as to overlap with the conductive material containing nitrogen. In the case where a conductive material that makes an oxide semiconductor have n-type conductivity is used for the conductive layer 220 and the conductive layer 240, a region of the semiconductor layer 230 that is in contact with the conductive layer 220 functions as one of a source region and a drain region, and a region of the semiconductor layer 230 that is in contact with the conductive layer 240 functions as the other of the source region and the drain region.

As the insulating layer 283, any of the barrier insulators against hydrogen described later in [Insulating layer] is preferably used. In that case, diffusion of hydrogen from above the insulating layer 283 into the semiconductor layer 230 can be inhibited. A silicon nitride film and a silicon nitride oxide film can be suitably used for the insulating layer 283 because they release fewer impurities (e.g., water and hydrogen) and are less likely to transmit oxygen and hydrogen.

As the insulating layer 283, any of the insulators having a function of capturing or fixing hydrogen described later in [Insulating layer] is preferably used. With such a structure, diffusion of hydrogen from above the insulating layer 283 into the semiconductor layer 230 can be inhibited. Furthermore, hydrogen in the semiconductor layer 230 is captured or fixed by the insulating layer 283, so that the hydrogen concentration in the semiconductor layer 230 can be reduced. For the insulating layer 283, magnesium oxide, aluminum oxide, hafnium oxide, or the like can be used. Alternatively, for example, a stacked-layer film of aluminum oxide and silicon nitride over the aluminum oxide may be used as the insulating layer 283.

Note that an insulating layer having a function of capturing or fixing hydrogen may be provided below the conductive layer 220.

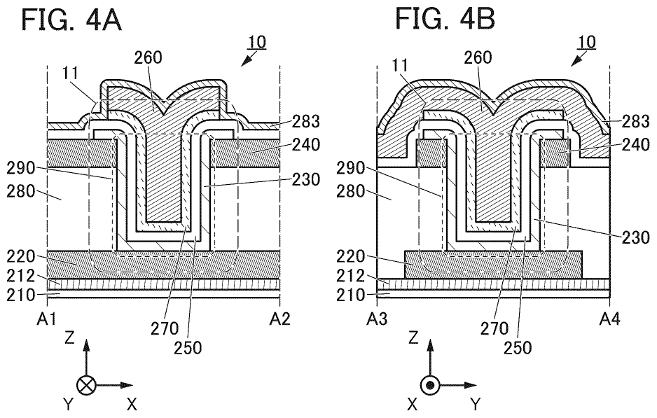

FIG. 4A and FIG. 4B are cross-sectional views of the semiconductor device 10. Note that FIG. 1A can be referred to for the plan view of the semiconductor device 10 illustrated in FIG. 4A and FIG. 4B. In the semiconductor device 10 illustrated in FIG. 4A and FIG. 4B, an insulating layer 212 is provided below the conductive layer 220. Specifically, the insulating layer 212 is provided between the insulating layer 210 and each of the insulating layer 280 and the conductive layer 220. In other words, the insulating layer 212 is provided over the insulating layer 210, and the conductive layer 220 and the insulating layer 280 are provided over the insulating layer 212.

As the insulating layer 212, any of the insulators having a function of capturing or fixing hydrogen described later in [Insulating layer] is preferably used. With such a structure, hydrogen in the semiconductor layer 230 can be diffused into the insulating layer 212 through the conductive layer 220, and the hydrogen can be captured or fixed by the insulating layer 212. Thus, the hydrogen concentration in the semiconductor layer 230 can be reduced.

### <Materials Forming Semiconductor Device>

Examples of materials that can be used for the semiconductor device of one embodiment of the present invention will be described below.

### [Substrate]

In the case where the semiconductor device is provided over a substrate, there is no particular limitation on a material used for the substrate. The material can be determined in accordance with the purpose in consideration of whether it has a light-transmitting property, heat resistance high enough to withstand heat treatment, or the like. For example, an insulator substrate, a semiconductor substrate, or a conductor substrate may be used. As the insulator substrate, for example, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used. Alternatively, a semiconductor substrate, a flexible substrate, a resin substrate, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. Another example is a semiconductor substrate in which an insulator region is included in the semiconductor substrate described above, e.g., an SOI (Silicon On Insulator) substrate. The semiconductor substrate may be a single crystal semiconductor or polycrystalline semiconductor substrate.

Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator.

For the material of the flexible substrate, the resin substrate, or the like, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example.

When the above-described material is used for the substrate, a lightweight semiconductor device can be provided. Furthermore, when the above-described material is used for the substrate, a shock-resistant semiconductor device can be provided. Moreover, when the above-described material is used for the substrate, a semiconductor device that is less likely to be broken can be provided.

Alternatively, these substrates provided with elements may be used. Examples of the element provided for the substrate include a capacitor element, a resistor element, a switching element, a light-emitting element, and a storage element.

### [Insulating Layer]

An insulating oxide, an insulating nitride, an insulating oxynitride, an insulating nitride oxide, an insulating metal oxide, an insulating metal oxynitride, an insulating metal nitride oxide, or the like can be used for the insulating layer.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

As miniaturization and high integration of transistors progress, a problem such as leakage current may arise because of a thinner gate insulating layer. When a high-k material is used for the insulating layer functioning as a gate insulating layer, the voltage at the time of operation of the transistor can be reduced while the physical thickness is maintained. In addition, the equivalent oxide thickness (EOT) of the insulating layer functioning as the gate insulating layer can be reduced. By contrast, when a material with low dielectric constant is used for the insulating layer functioning as an interlayer film, parasitic capacitance generated between wirings can be reduced. Thus, a material is preferably selected depending on the function of an insulating layer. Note that the material with low relative permittivity is a material with high dielectric strength.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of the inorganic insulating material with low relative permittivity include silicon oxide to which fluorine is added, silicon oxide to which carbon is added, and silicon oxide to which carbon and nitrogen are added. Another example is porous silicon oxide. These silicon oxides can contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used.

Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulating layer that is in contact with a semiconductor layer or provided in the vicinity of the semiconductor layer, such as a gate insulating layer, preferably includes a region containing excess oxygen. For example, when an insulating layer including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of the barrier insulator against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the barrier insulator against hydrogen include aluminum oxide, magnesium oxide, hafnium oxide, gallium oxide, indium gallium zinc oxide, silicon nitride, and silicon nitride oxide.

The barrier insulator against oxygen and the barrier insulator against hydrogen can each be regarded as a barrier insulator against one or both of oxygen and hydrogen.

Note that a function of capturing or fixing a target substance can also be referred to as a property that does not easily allow diffusion of a target substance. Thus, a function of capturing or fixing a target substance can be rephrased as a barrier property.

Examples of the insulator having a function of capturing or fixing hydrogen include an oxide containing magnesium and an oxide containing one or both of aluminum and hafnium. Examples of the oxide containing one or both of aluminum and hafnium include aluminum oxide, hafnium oxide, and an oxide containing aluminum and hafnium (hafnium aluminate). Silicon oxide may be added to these oxides. Examples of the insulator having a function of capturing or fixing hydrogen include an oxide containing magnesium and silicon, an oxide containing aluminum and silicon, and an oxide containing hafnium and silicon (hafnium silicate).

Each of the above oxides preferably contains an oxygen atom having a dangling bond. Such an oxide has a property of capturing or fixing hydrogen with the dangling bond in some cases. For example, the above oxides preferably have an amorphous structure. This is because some oxygen atoms in an oxide having an amorphous structure have dangling bonds. Note that the above oxides preferably have an amorphous structure, but a crystal region may be partly formed. Furthermore, the above oxides may have a crystal grain boundary. This is because, in an oxide having a crystal grain boundary, some oxygen atoms in the vicinity of the crystal grain boundary have dangling bonds in some cases.

Note that in this specification and the like, a barrier insulator refers to an insulator having a barrier property. The barrier property refers to a property that does not easily allow diffusion of a target substance (also referred to as a property that does not easily allow passage of a target substance, a property with low permeability to a target substance, or a function of inhibiting diffusion of a target substance). Hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

As the material that can have ferroelectricity, for example, hafnium oxide is preferably used. Alternatively, as the material that can have ferroelectricity, a metal oxide such as zirconium oxide or hafnium zirconium oxide (sometimes referred to as HfZrOx) may be used. Alternatively, as the material that can have ferroelectricity, a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide may be used.

Here, the atomic ratio of hafnium to the element J1 can be set as appropriate. For example, the atomic ratio of hafnium to a zirconium is preferably 1:1 or in the neighborhood thereof. Alternatively, as the material that can have ferroelectricity, a material in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide, or the like can be used. The atomic ratio of zirconium to the element J2 can be set as appropriate; the atomic ratio of zirconium to the element J2 is preferably, for example, 1:1 or in the neighborhood thereof. As the material that can have ferroelectricity, a piezoelectric ceramic having a perovskite structure, such as lead titanate (PbTiOx), barium strontium titanate (BST), strontium titanate, lead zirconate titanate (PZT), strontium bismuth tantalate (SBT), bismuth ferrite (BFO), or barium titanate, may be used.

As the material that can have ferroelectricity, scandium aluminum nitride (Al₁₋ₐScₐN_{b} (a is a real number greater than 0 and less than 0.5, and b is 1 or an approximate value thereof), hereinafter simply referred to as “AlScN” in some cases), Al—Ga—Sc nitride, Ga—Sc nitride, or the like can be used. As the material that can have ferroelectricity, a metal nitride containing an element M1, an element M2, and nitrogen can also be used. Here, the element M1 is one or more selected from aluminum (Al), gallium (Ga), indium (In), and the like. The element M2 is one or more selected from boron (B), scandium (Sc), yttrium (Y), lanthanoids (lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu)), actinoids (15 elements from actinium (Ac) to lawrencium (Lr)), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen has ferroelectricity in some cases even though the metal oxide does not contain the element M2. As the material that can have ferroelectricity, a material in which an element M3 is added to the above metal nitride can be used. Note that the element M3 is one or more selected from magnesium (Mg), calcium (Ca), strontium (Sr), zinc (Zn), cadmium (Cd), and the like. Here, the atomic ratio of the element M1, the element M2, and the element M3 can be set as appropriate. Since the above metal nitride contains at least a Group 13 element and nitrogen, which is a Group 15 element, the metal nitride is referred to as a ferroelectric of Group 13-15, a ferroelectric of a Group 13 nitride, or the like in some cases.

As the material that can have ferroelectricity, a perovskite-type oxynitride such as SrTaO₂N or BaTaO₂N, GaFeO₃ with a k-alumina-type structure, or the like can be used.

The material that can have ferroelectricity can be, for example, a mixture or a compound formed of a plurality of materials selected from the above-listed materials. Alternatively, the material that can have ferroelectricity can have a stacked-layer structure of a plurality of materials selected from the above-listed materials. The above-listed materials may change their crystal structures or characteristics according to a variety of processes and the like as well as film formation conditions; in this specification and the like, not only a material that exhibits ferroelectricity but also a material that can have ferroelectricity is referred to as a ferroelectric. In other words, the term “ferroelectric” in this specification and the like includes both a material that exhibits ferroelectricity and a material that can have ferroelectricity.

A material containing hafnium oxide or hafnium oxide and zirconium oxide (typically, HfZrOx) is suitable as a ferroelectric because the material can have ferroelectricity even when having a thickness of several nanometers.

Scandium aluminum nitride (AlScN), which can be formed by a sputtering method, is suitable as a ferroelectric because the impurity concentration in the film can be reduced or a dense film can be formed. In the case where scandium aluminum nitride (AlScN) is used as a ferroelectric, achievement of a highly reliable ferroelectric can be expected.

The thickness of a ferroelectric layer can be less than or equal to 100 nm, preferably less than or equal to 50 nm, further preferably less than or equal to 20 nm, and still further preferably less than or equal to 10 nm (typically, greater than or equal to 2 nm and less than or equal to 9 nm). For example, the thickness of the ferroelectric layer is preferably greater than or equal to 8 nm and less than or equal to 12 nm. When the thickness of the ferroelectric layer is in the above range, ferroelectricity can be exhibited with a thin film.

A reduction in the thickness of the ferroelectric layer facilitates miniaturization of a ferroelectric device such as an FeFET or a capacitor using a ferroelectric as a dielectric (also referred to as a “ferroelectric capacitor”). Accordingly, miniaturization of a semiconductor device including a ferroelectric device or a semiconductor device including a combination of a ferroelectric capacitor and a semiconductor element such as a transistor can be facilitated. That is, a semiconductor device that occupies a small area can be easily achieved.

In the case where HfZrOx is used as a ferroelectric, an ALD method, specifically, a thermal ALD method is preferably used for formation. In the case where a ferroelectric is formed by a thermal ALD method, it is suitable to use a material that does not contain hydrocarbon (also referred to as Hydro Carbon or HC) for a precursor. When one or both of hydrogen and carbon are contained in the ferroelectric, crystallization of the ferroelectric might be hindered. Thus, the precursor that does not contain hydrocarbon is preferably used as described above to reduce the concentration(s) of one or both of hydrogen and carbon in the ferroelectric. Examples of the precursor that does not contain hydrocarbon include a chlorine-based material. In the case where HfZrOx is used as the ferroelectric, HfCl4 and/or ZrCl4 are/is used as the precursor. On the other hand, a dopant (typically, silicon, carbon, or the like) for controlling the polarization state may be added to the ferroelectric. In that case, a formation method using a material containing hydrocarbon as a precursor may be used as a way of adding carbon as a dopant.

In the case where a layer including a ferroelectric is formed, impurities in the layer, at least one of hydrogen, hydrocarbon, and carbon here, are thoroughly removed, whereby a highly purified intrinsic ferroelectric layer can be formed. Note that the highly purified intrinsic ferroelectric layer and a highly purified intrinsic oxide semiconductor described later are highly compatible with each other in the manufacturing process. Thus, a semiconductor device with high productivity can be provided.

The impurity concentration in a ferroelectric is preferably low. In particular, the concentrations of hydrogen (H) and carbon (C) are preferably as low as possible. Specifically, the hydrogen concentration in the ferroelectric is preferably lower than or equal to 5×10²⁰ atoms/cm³, further preferably lower than or equal to 1×10²⁰ atoms/cm³. The carbon concentration in the ferroelectric is preferably lower than or equal to 5×10¹⁹ atoms/cm³, further preferably lower than or equal to 1×10¹⁹ atoms/cm³.

In the case where HfZrOx is used as a ferroelectric, a film of hafnium oxide and a film of zirconium oxide are preferably formed alternately by an ALD method so as to have a composition of 1:1.

In the case where a ferroelectric is formed by an ALD method, H₂O or O₃ can be used as an oxidizer. However, the oxidizer in the ALD method is not limited thereto. For example, the oxidizer in the ALD method can contain any one or more selected from O₂, O₃, N₂O, NO₂, H₂O, and H₂O₂.

In particular, the ferroelectric layer preferably has an orthorhombic crystal structure because ferroelectricity is easily exhibited. Note that the ferroelectric layer may have another crystal structure in addition to the orthorhombic crystal structure. For example, the ferroelectric layer may have any one or more crystal structures selected from a cubic crystal structure, a tetragonal crystal structure, an orthorhombic crystal structure, and a monoclinic crystal structure in addition to the orthorhombic crystal structure. Note that a layer for improving crystallinity may be formed before the ferroelectric layer is formed. For example, in the case where HfZrOx is used as the ferroelectric layer, a metal oxide such as hafnium oxide or zirconium oxide, hafnium, or zirconium can be used for the layer for improving crystallinity.

In the case where scandium aluminum nitride is used as the ferroelectric layer, the ferroelectric layer preferably has a hexagonal crystal structure. Note that the ferroelectric layer can have another crystal structure in addition to the hexagonal crystal structure. For the layer for improving crystallinity, a metal nitride such as aluminum nitride or scandium nitride, aluminum, or scandium is preferably used.

Note that the layer for improving crystallinity may be formed after the ferroelectric layer is formed. Alternatively, the ferroelectric layer may have a composite structure of an amorphous structure and a crystal structure.

There is no particular limitation on the formation method of the insulating material, and a variety of formation methods such as an evaporation method, an ALD method, a chemical vapor deposition (CVD) method, a sputtering method, and a spin coating method can be employed.

### [Conductive Layer]

As a conductive layer, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may also be employed. A stacked-layer structure combining a material containing the above metal element, a conductive material containing oxygen, and a conductive material containing nitrogen may also be employed.

In the case where a metal oxide is used for the channel formation region of the transistor, the conductive layer functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductive layer functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases. [Semiconductor layer]

For the semiconductor layer 230, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, or a nitride semiconductor may be used. As the compound semiconductor, an organic substance having semiconductor characteristics or a metal oxide having semiconductor characteristics (also referred to as an oxide semiconductor) can be used. These semiconductor materials may contain an impurity as a dopant.

For the semiconductor layer 230, single crystal silicon, polycrystalline silicon, microcrystalline silicon, and amorphous silicon may be used, for example. As the polycrystalline silicon, for example, low-temperature polysilicon (LTPS) may be used.

The transistor including amorphous silicon in the semiconductor layer 230 can be formed over a large glass substrate, and can be manufactured at low cost. The transistor including polycrystalline silicon in the semiconductor layer 230 has high field-effect mobility and enables high-speed operation. The transistor including microcrystalline silicon in the semiconductor layer 230 has higher field-effect mobility and enables higher speed operation than the transistor including amorphous silicon.

The semiconductor layer 230 may include a layered substance functioning as a semiconductor. The layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen (a Group 16 element). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

An oxide semiconductor has a band gap of 2 eV or more; thus, a transistor using an oxide semiconductor, which is a kind of metal oxide, for a semiconductor layer where a channel is formed (also referred to as an “OS transistor”) has an extremely low off-state current. Thus, the power consumption of a semiconductor device including an OS transistor can be reduced. The OS transistor operates stably even in a high-temperature environment and has small change in characteristics. For example, the off-state current hardly increases even in a high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. Therefore, the semiconductor device including the OS transistor can operate stably and have high reliability even in a high-temperature environment.

Note that in this embodiment and the like, an OS transistor is preferably used as the transistor included in the semiconductor device. Since an OS transistor has a high breakdown voltage between the source and the drain, the channel length can be shortened. The on-state current can be increased accordingly. Thus, the OS transistor is suitably used as a vertical-channel transistor.

Examples of the metal oxide that can be used for the semiconductor layer of the transistor include indium oxide, gallium oxide, and zinc oxide. The metal oxide preferably contains at least indium (In) or zinc (Zn). The metal oxide preferably contains one or both of indium and zinc. The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, copper, cobalt, nickel, zirconium, molybdenum, hafnium, tantalum, tungsten, lanthanum, cerium, neodymium, magnesium, calcium, strontium, barium, beryllium, boron, silicon, germanium, and antimony. The element M contained in the metal oxide is preferably one or more kinds of the above elements, further preferably one or more kinds selected from aluminum, gallium, tin, and yttrium, and still further preferably gallium. Note that in this specification and the like, a metal element and a metalloid element may be collectively referred to as a “metal element”, and a “metal element” in this specification and the like may refer to a metalloid element.

Examples of the metal oxide include indium oxide (In oxide), indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as “IGTO”), gallium zinc oxide (Ga—Zn oxide, also referred to as “GZO”), aluminum zinc oxide (Al—Zn oxide, also referred to as “AZO”), indium aluminum zinc oxide (In—Al—Zn oxide, also referred to as “IAZO”), indium tin zinc oxide (In—Sn—Zn oxide), indium titanium zinc oxide (In—Ti—Zn oxide), indium gallium zinc oxide (In—Ga—Zn oxide, also referred to as “IGZO”), indium gallium tin zinc oxide (In—Ga—Sn—Zn oxide, also referred to as “IGZTO”), and indium gallium aluminum zinc oxide (In—Ga—Al—Zn oxide, also referred to as “IGAZO” or “IAGZO”). Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

As the semiconductor layer of the transistor, specifically, a metal oxide film with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof may be used. Note that a composition in the neighborhood includes the range of +30% of an intended atomic ratio. Gallium is preferably used as the element M.

The semiconductor layer of the transistor may have a structure not containing the element M. For example, an In—Zn oxide may be used for the semiconductor layer. Alternatively, indium oxide may be used for the semiconductor layer, for example.

Note that in the case where the metal oxide is an In—Zn oxide, examples of the atomic ratio of metal elements in the In—Zn oxide include In:Zn=1:1, In:Zn=2:1, In:Zn=4:1, and compositions in the neighborhood thereof. In addition, the In—Zn oxide may contain a slight amount of the element M. For example, in the case where Sn is contained as the element M, examples of the atomic ratio of the metal elements in the metal oxide include In:Sn:Zn=2:0.1:1, In:Sn:Zn=4:0.1:1, and compositions in the neighborhood thereof.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

The metal oxide can be formed by a sputtering method, a CVD method such as a metal organic chemical vapor deposition (MOCVD) method, an ALD method, or the like.

Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately higher than or equal to 40% and lower than or equal to 90% of the atomic ratio of zinc contained in the target.

Note that when a film of the metal oxide is formed by a sputtering method, the above atomic ratio is not limited to the atomic ratio of the formed metal oxide film and may be the atomic ratio of a sputtering target used for forming the metal oxide film.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which achieves a highly reliable display device.

The higher the crystallinity of the metal oxide layer used as the semiconductor layer is, the lower the density of defect states in the semiconductor layer can be. By contrast, the use of a metal oxide layer having low crystallinity achieves a transistor through which a large amount of current can flow.

In the case where a metal oxide layer is formed by a sputtering method, the metal oxide layer with higher crystallinity can be formed as the substrate temperature (the stage temperature) in formation is increased. The metal oxide layer with higher crystallinity can be formed as the proportion of a flow rate of an oxygen gas to the whole gas (also referred to as oxygen flow rate ratio) used in film formation is increased.

The semiconductor layer of the OS transistor may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer may have different compositions.

### <Structure Example of Semiconductor Device 20>

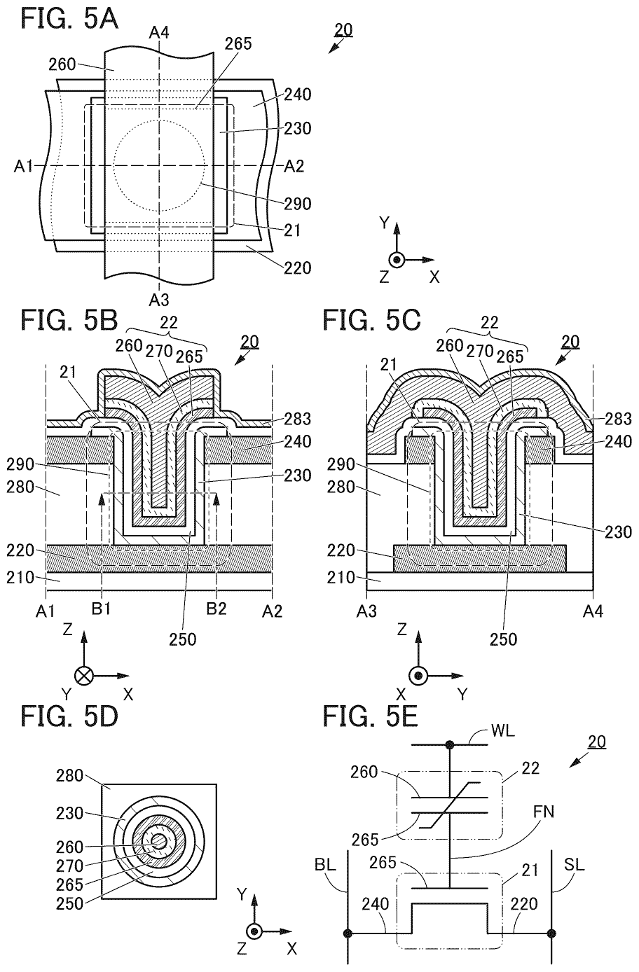

A semiconductor device 20, which is another example of the semiconductor device, will be described with reference to FIG. 5A to FIG. 5E. FIG. 5A is a plan view of the semiconductor device 20. FIG. 5B is a cross-sectional view of a portion indicated by the dashed-dotted line A1-A2 in FIG. 5A, which is seen from the Y direction, and FIG. 5C is a cross-sectional view of a portion indicated by the dashed-dotted line A3-A4 in FIG. 5A, which is seen from the X direction. FIG. 5D is an enlarged cross-sectional view of a portion indicated by the dashed-dotted line B1-B2 in FIG. 5B, which is seen from the Z direction. Note that for clarity of the drawing, some components are omitted in the plan view of FIG. 5A.

The semiconductor device 20 illustrated in FIG. 5A to FIG. 5C is also a variation example of the semiconductor device 10 illustrated in FIG. 1A to FIG. 1C. Specifically, the semiconductor device 20 illustrated in FIG. 5A to FIG. 5C is different from the semiconductor device 10 illustrated in FIG. 1A to FIG. 1C mainly in including a conductive layer 265. Portions different from the above description of <Structure example of semiconductor device 10> are mainly described below, the above description is referred to for the same portion, and the description of the same portions is omitted in some cases.

The conductive layer 265 is provided between the insulating layer 250 and the insulating layer 270. The conductive layer 265 includes a region overlapping with the conductive layer 260 with the insulating layer 270 therebetween. At least part of the conductive layer 265 is positioned in the opening portion 290. The conductive layer 265 is provided to cover the insulating layer 250, and the insulating layer 270 is provided to cover the conductive layer 265. Thus, a portion of the conductive layer 265 that is positioned in the opening portion 290 reflects the shape of the opening portion 290.

The semiconductor device 20 includes a transistor 21 and a capacitor 22 over the transistor 21. The semiconductor device 20 has a structure in which the transistor 21 and the capacitor 22 are provided to overlap with each other. When the transistor 21 and the capacitor 22 are provided to overlap with each other, the area occupied by the semiconductor device 20 can be reduced.

In general, a capacitor is formed with a pair of electrodes with a dielectric interposed therebetween. In the semiconductor device 20, at least part of the conductive layer 265 functions as one of a pair of electrodes of the capacitor 22, at least part of the conductive layer 260 functions as the other of the pair of electrodes of the capacitor 22, and at least part of the insulating layer 270 functions as a dielectric of the capacitor 22. That is, a region where the conductive layer 265 and the conductive layer 260 overlap with each other with the insulating layer 270 therebetween functions as the capacitor 22. In the semiconductor device 20, part of the capacitor 22 is provided in the opening portion 290. Part of the capacitor 22 overlaps with a side surface of the opening portion 290. In other words, the capacitor 22 includes a region that overlaps, in the opening portion 290, with a side surface of the insulating layer 280 with the insulating layer 250 and the semiconductor layer 230 therebetween.

The electrostatic capacitance value (also referred to as capacitance value) of the capacitor 22 is proportional to the area of the region where the conductive layer 265 and the conductive layer 260 overlap with each other with the insulating layer 270 therebetween. When at least part of the capacitor 22 is provided in the opening portion 290, a reduction in electrostatic capacitance value due to a reduction in the area occupied by the semiconductor device 20 can be prevented. That is, a reduction in electrostatic capacitance value due to a reduction in the area occupied by the capacitor 22 can be prevented. In addition, when at least part of the capacitor 22 is provided in the opening portion 290, a necessary electrostatic capacitance value can be ensured even when the area occupied by the semiconductor device 20 is reduced. That is, a necessary electrostatic capacitance value can be ensured even when the area occupied by the capacitor 22 is reduced.

### [Transistor 21]

The conductive layer 220 includes a region functioning as one of a source electrode and a drain electrode of the transistor 21. The conductive layer 240 includes a region functioning as the other of the source electrode and the drain electrode of the transistor 21. For example, in the case where the conductive layer 220 includes a region functioning as the drain electrode of the transistor 21, the conductive layer 240 includes a region functioning as the source electrode of the transistor 21.

The semiconductor layer 230 includes a region functioning as a semiconductor layer where a channel of the transistor 21 is formed. The conductive layer 265 includes a region functioning as a gate electrode of the transistor 21. The conductive layer 250 includes a region functioning as a gate insulating layer of the transistor 21. The channel of the transistor 21 is formed in the semiconductor layer 230 between a region of the semiconductor layer 230 that is in contact with the conductive layer 220 and a region of the semiconductor layer 230 that is in contact with the conductive layer 240. In other words, the transistor 21 is provided in a region including the opening portion 290.

### [Capacitor 22]

The capacitor 22 includes the conductive layer 265, the insulating layer 270 over the conductive layer 265, and the conductive layer 260 over the insulating layer 270. As described above, the region where the conductive layer 265 and the conductive layer 260 overlap with each other with the insulating layer 270 therebetween functions as the capacitor 22. The above-described ferroelectric is preferably used for the insulating layer 270. In that case, the insulating layer 270 has ferroelectricity. The ferroelectric has a property of causing internal dielectric polarization by application of an electric field from the outside and maintaining the polarization even after the electric field is made zero. Accordingly, a nonvolatile memory element can be obtained using a ferroelectric capacitor. Note that a nonvolatile memory element using a ferroelectric is referred to as a “ferroelectric memory” or the like in some cases.

The conductive layer 265 has a function of one of the pair of electrodes of the capacitor 22 and a function of the gate electrode of the transistor 21. As the conductive layer 265, any of the conductors that can be used for the conductive layer 260 can be used. For the conductive layer 265, a conductive material having a function of absorbing oxygen can be used. For example, a conductive material that does not contain nitrogen is preferably used for the conductive layer 265. In addition, a conductive material containing nitrogen, a conductive material that is less likely to be oxidized, a conductive material having a function of inhibiting diffusion of oxygen, or the like can be used for the conductive layer 265.

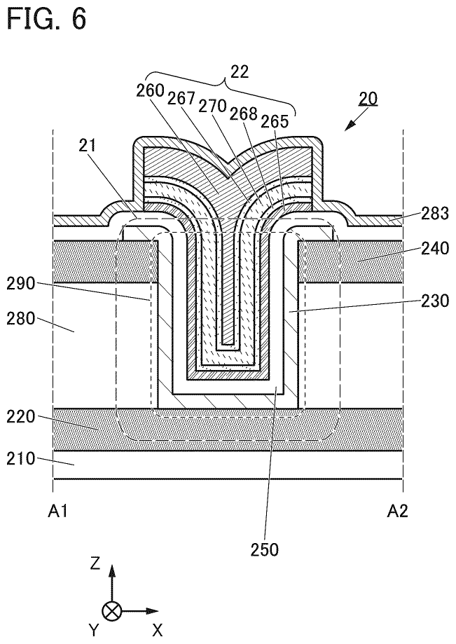

Note that in the case where a conductive material having a function of absorbing oxygen is used for the conductive layer 260, the layer 267 is sometimes formed between the conductive layer 260 and the insulating layer 270 as described above (see FIG. 6). In the case where a conductive material having a function of absorbing oxygen is used for the conductive layer 265, a layer 268 is sometimes formed between the conductive layer 265 and the insulating layer 270 as illustrated in FIG. 6. Here, when a metal contained in the conductive layer 265 is a metal MY, the layer 268 contains the metal MY and oxygen. In the case where an oxide containing the metal MY is used as the conductive layer 265, the oxygen concentration in the layer 268 is higher than that in the conductive layer 265. The concentration of the metal MY in the layer 268 is lower than that of the metal MY in the conductive layer 265.

In the case where the layer 267 and the layer 268 are formed, the capacitor 22 includes the conductive layer 265, the layer 268 over the conductive layer 265, the insulating layer 270 over the layer 268, the layer 267 over the insulating layer 270, and the conductive layer 260 over the layer 267. The layer 267 may have conductivity or an insulating property. In the case where the layer 267 has conductivity, the layer 267 includes a region functioning as the other of the pair of electrodes of the capacitor 22. In the case where the layer 267 has an insulating property, the layer 267 includes a region functioning as a dielectric of the capacitor 22. Similarly, the layer 268 may have conductivity or an insulating property. In the case where the layer 268 has conductivity, the layer 268 includes a region functioning as one of the pair of electrodes of the capacitor 22. In the case where the layer 268 has an insulating property, the layer 268 includes a region functioning as a dielectric of the capacitor 22.

FIG. 5E is an equivalent circuit diagram of the semiconductor device 20. In FIG. 5E, one of a source and a drain of the transistor 21 is electrically connected to a wiring SL, the other of the source and the drain of the transistor 21 is electrically connected to a wiring BL, and a gate of the transistor 21 is electrically connected to one of a pair of electrodes of the capacitor 22. The other of the pair of electrodes of the capacitor 22 is electrically connected to a wiring WL. The semiconductor device 20 functions as a memory circuit. Note that FIG. 5E is an equivalent circuit diagram of the case where the capacitor 22 includes a ferroelectric.

The conductive layer 220 functions as at least part of the wiring SL. The conductive layer 240 functions as at least part of the wiring BL. The conductive layer 260 functions as at least part of the wiring WL. The conductive layer 265 has a function of the gate electrode of the transistor 21 and a function of one of the pair of electrodes of the capacitor 22. Note that the wiring SL and the wiring BL can be interchanged with each other. The conductive layer 220 may function as at least part of the wiring BL, and the conductive layer 240 may function as at least part of the wiring SL.

### Variation Example 1

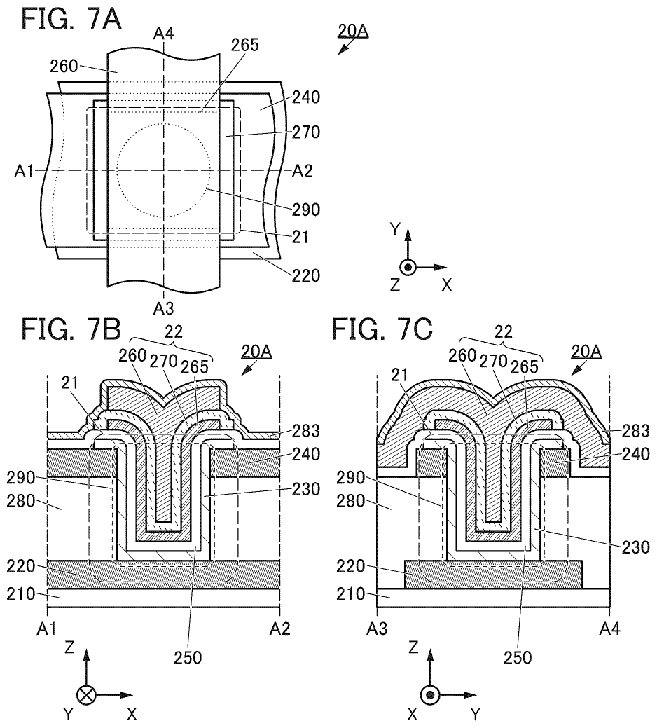

FIG. 7A to FIG. 7C illustrate a semiconductor device 20A, which is a variation example of the semiconductor device 20. FIG. 7A is a plan view of the semiconductor device 20A. FIG. 7B is a cross-sectional view of a portion indicated by the dashed-dotted line A1-A2 in FIG. 7A, which is seen from the Y direction. FIG. 7C is a cross-sectional view of a portion indicated by the dashed-dotted line A3-A4 in FIG. 7A, which is seen from the X direction. Note that for clarity of the drawing, some components are omitted in the plan view of FIG. 7A.

The semiconductor device 20A is different from the semiconductor device 20 in that the insulating layer 270 includes a region extending beyond an end portion of the conductive layer 265. As in the semiconductor device 20A, the conductive layer 265 may be covered with the insulating layer 270. Such a structure can prevent a short circuit between the conductive layer 265 and the conductive layer 260 at the end portion of the conductive layer 265. Thus, the reliability of the semiconductor device 20A can be increased.

A side surface of the capacitor 22, which includes end portions of the conductive layer 265, the insulating layer 270, and the conductive layer 260, may have a tapered shape. Such a structure can improve the coverage with the insulating layer 283. When seen from the Z direction, the end portions of the conductive layer 265, the insulating layer 270, and the conductive layer 260 are not aligned with each other; thus, the end portions of the conductive layer 265, the insulating layer 270, and the conductive layer 260 are stair-stepped, which can improve the coverage with the insulating layer 283. Thus, the reliability of the semiconductor device 20A can be increased.

### Variation Example 2

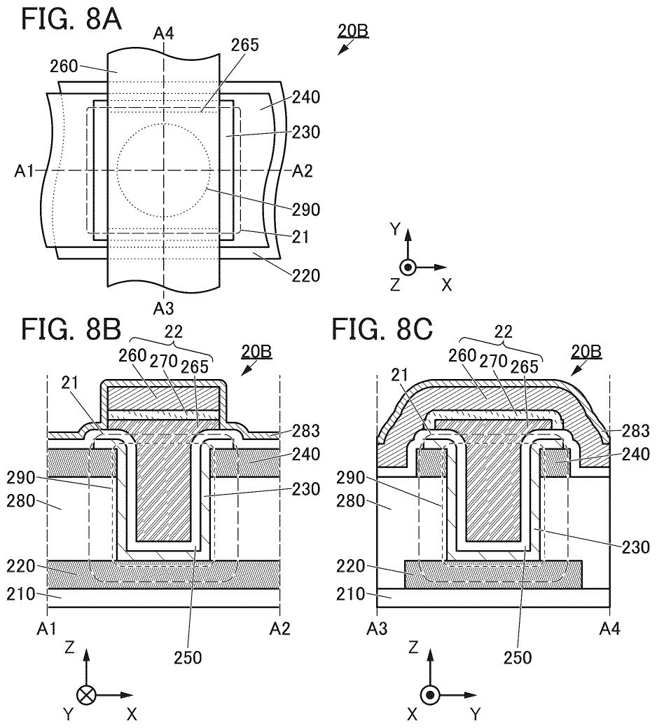

FIG. 8A to FIG. 8C illustrate a semiconductor device 20B, which is a variation example of the semiconductor device 20. FIG. 8A is a plan view of the semiconductor device 20B. FIG. 8B is a cross-sectional view of a portion indicated by the dashed-dotted line A1-A2 in FIG. 8A, which is seen from the Y direction. FIG. 8C is a cross-sectional view of a portion indicated by the dashed-dotted line A3-A4 in FIG. 8A, which is seen from the X direction. Note that for clarity of the drawing, some components are omitted in the plan view of FIG. 8A.

The semiconductor device 20B is different from the semiconductor device 20 in the structure of the capacitor 22. The semiconductor device 20B has a structure in which in the plan view, the opening portion 290 is filled with part of the conductive layer 265 covering the opening portion 290 and the semiconductor layer 230. In addition, the top surface of the conductive layer 265 is planarized. Planarization of the top surface of the conductive layer 265 can be achieved by chemical mechanical polishing (CMP) treatment or the like. Specifically, a conductive film for forming the conductive layer 265 may be formed to be rather thick over the insulating layer 250, and the surface unevenness of the conductive film may be reduced by a CMP method. After that, a resist mask is formed by a lithography method and an etching step is performed with the resist mask used as a mask, whereby the conductive layer 265 with the planarized top surface can be formed. A minute pattern can be easily formed by reducing the surface unevenness of the conductive film, which reduces the area occupied by the semiconductor device 20B. In addition, the storage density (the number of memory cells per unit area) of a memory device using the semiconductor device 20B as a memory cell can be increased.

After that, the insulating layer 270 that is a ferroelectric can be formed over the flat surface of the conductive layer 265, that is, the insulating layer 270 can be formed by a sputtering method or the like without any concern for coverage. In addition, the thickness of the insulating layer 270 can be made uniform and easily controlled. Thus, the reliability of the semiconductor device 20B can be increased.

### Variation Example 3

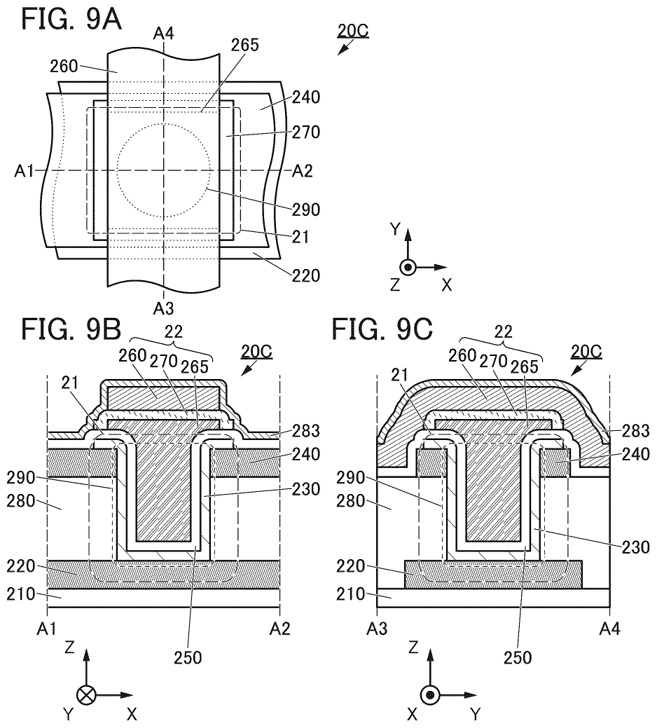

FIG. 9A to FIG. 9C illustrate a semiconductor device 20C, which is a variation example of the semiconductor device 20B. FIG. 9A is a plan view of the semiconductor device 20C.

FIG. 9B is a cross-sectional view of a portion indicated by the dashed-dotted line A1-A2 in FIG. 9A, which is seen from the Y direction. FIG. 9C is a cross-sectional view of a portion indicated by the dashed-dotted line A3-A4 in FIG. 9A, which is seen from the X direction. Note that for clarity of the drawing, some components are omitted in the plan view of FIG. 9A.

The semiconductor device 20C is different from the semiconductor device 20B in that the insulating layer 270 includes a region extending beyond an end portion of the conductive layer 265. As in the semiconductor device 20C, the conductive layer 265 may be covered with the insulating layer 270. Such a structure can prevent a short circuit between the conductive layer 265 and the conductive layer 260 at the end portion of the conductive layer 265.

### Variation Example 4

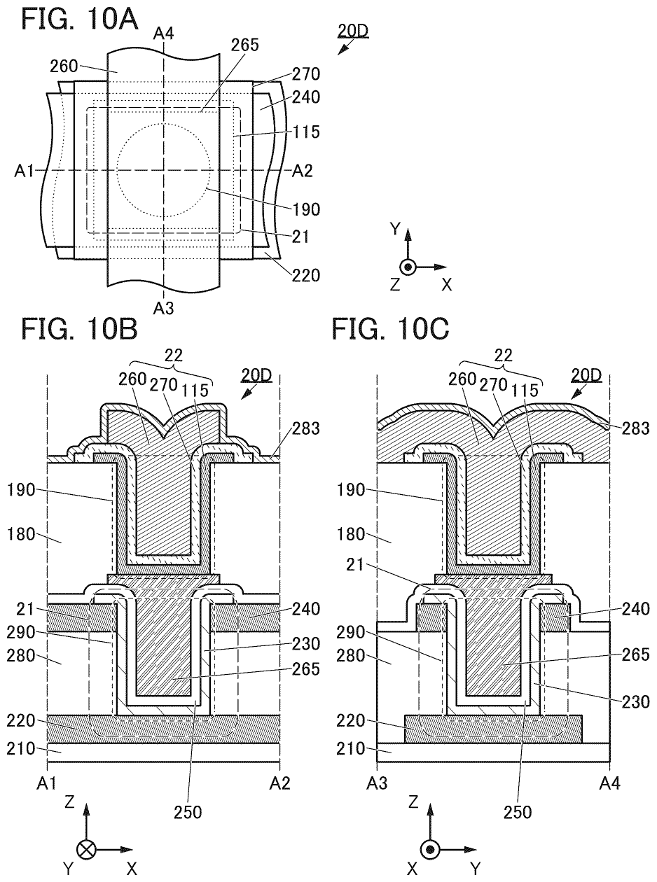

FIG. 10A to FIG. 10C illustrate a semiconductor device 20D, which is a variation example of the semiconductor device 20B. FIG. 10A is a plan view of the semiconductor device 20D. FIG. 10B is a cross-sectional view of a portion indicated by the dashed-dotted line A1-A2 in FIG. 10A, which is seen from the Y direction. FIG. 10C is a cross-sectional view of a portion indicated by the dashed-dotted line A3-A4 in FIG. 10A, which is seen from the X direction. Note that for clarity of the drawing, some components are omitted in the plan view of FIG. 10A.

The semiconductor device 20D includes an insulating layer 180 over the insulating layer 250 and the conductive layer 265. An opening portion 190 is provided in part of the insulating layer 180, which is in a region overlapping with part of the conductive layer 265. The semiconductor device 20D includes a conductive layer 115 covering the opening portion 190. The conductive layer 115 includes a region that overlaps with the conductive layer 265 and is electrically connected to the conductive layer 265 in a bottom portion of the opening portion 190. The conductive layer 115 includes a region overlapping with a side surface of the opening portion 190. That is, the conductive layer 115 includes a region in contact with a side surface of the insulating layer 180 in the opening portion 190.

The semiconductor device 20D also includes the insulating layer 270 covering the opening portion 190. The insulating layer 270 includes a region that overlaps with the conductive layer 265 with the conductive layer 115 therebetween in the bottom portion of the opening portion 190. The insulating layer 270 also includes a region that overlaps with the side surface of the insulating layer 180 with the conductive layer 115 therebetween.

The semiconductor device 20D includes the conductive layer 260 covering the opening portion 190 in the plan view. The conductive layer 260 includes a region that overlaps with the conductive layer 265 with the insulating layer 270 and the conductive layer 115 therebetween in the bottom portion of the opening portion 190. The conductive layer 260 also includes a region that overlaps with the side surface of the insulating layer 180 with the insulating layer 270 and the conductive layer 115 therebetween.

A region where the conductive layer 260 and the conductive layer 115 overlap with each other with the insulating layer 270 therebetween functions as the capacitor 22. Since the capacitor 22 of the semiconductor device 20D is provided in the opening portion 190, the capacitance value of the capacitor 22 can be increased without increase in occupation area seen from the Z direction.

The insulating layer 180 functions as an interlayer film and thus preferably has low relative permittivity. When a material with low relative permittivity is used for an interlayer film, parasitic capacitance generated between wirings can be reduced. For the insulating layer 180, a single layer or stacked layers of any of the insulating layers each containing a material with low relative permittivity described above in [Insulating layer] can be used.

As the conductive layer 115, a single layer or stacked layers of any of the conductors described above in [Conductive layer] can be used. For example, a single layer or stacked layers of a conductive material that is less likely to be oxidized, a conductive material having a function of inhibiting diffusion of oxygen, a conductive material containing oxygen, or the like is preferably used as the conductive layer 115. For example, in the case where an insulating material containing oxygen is used for the insulating layer 180, the use of titanium nitride for the conductive layer 115 can inhibit the conductive layer 115 from being oxidized by the insulating layer 180. In addition, the crystallinity of the insulating layer 270 can be improved and the ferroelectricity of the insulating layer 270 can be increased in some cases.

The conductive layer 115 may have a stacked-layer structure of a combination of a conductive material having a function of absorbing oxygen and a conductive material that is less likely to be oxidized, a conductive material having a function of inhibiting diffusion of oxygen, or a conductive material containing oxygen. For example, titanium nitride, indium tin oxide to which silicon is added, or the like may be used for a layer on the side in contact with the insulating layer 180, and tungsten, ruthenium, or the like may be used for a layer on the side in contact with the insulating layer 270. Such a structure can absorb oxygen from the insulating layer 270 and increase the oxygen vacancy concentration in the insulating layer 270. Accordingly, the remanent polarization can be increased. Note that a conductive layer containing a conductive material having a function of absorbing oxygen may be used as the conductive layer 115.

A conductive layer containing nitrogen is preferably used as one or both of the conductive layer 115 and the conductive layer 260. Such a structure can improve the rewrite endurance of the semiconductor device. That is, when a conductive layer containing nitrogen is used as the conductive layer in contact with the insulating layer 270, the reliability of the semiconductor device can be increased. Titanium nitride is particularly preferable for the conductive layer containing nitrogen.

Although the capacitor 22 in the semiconductor device 20D has a cylindrical shape, the present invention is not limited thereto. For example, the capacitor 22 may have a planar shape.

### Variation Example 5

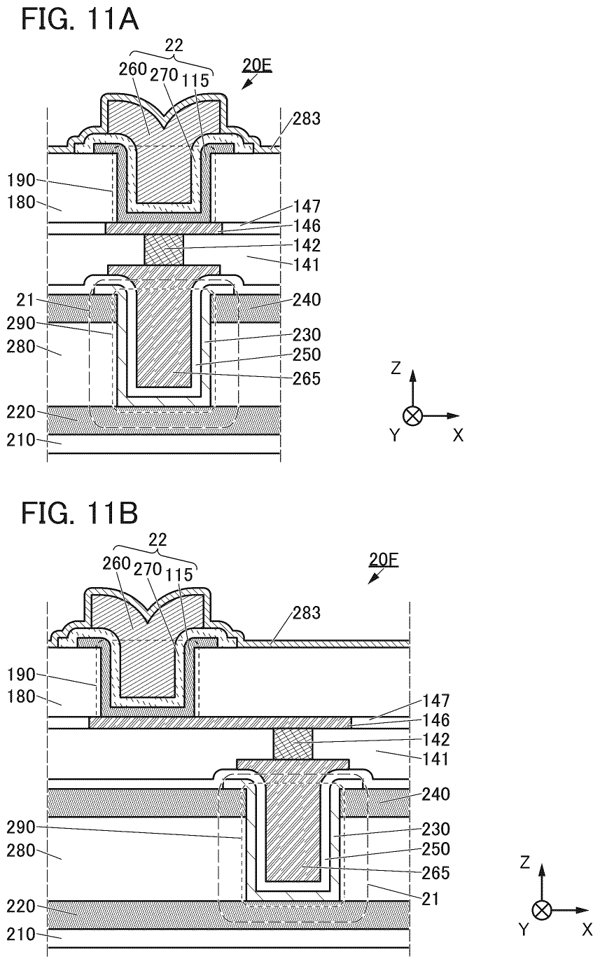

FIG. 11A illustrates a semiconductor device 20E, which is a variation example of the semiconductor device 20D. FIG. 11A is a cross-sectional view of the semiconductor device 20E, which is seen from the Y direction. FIG. 11B illustrates a semiconductor device 20F, which is a variation example of the semiconductor device 20E. FIG. 11B is a cross-sectional view of the semiconductor device 20F, which is seen from the Y direction.

The semiconductor device 20E includes an insulating layer 141 over the insulating layer 250 and the conductive layer 265. A conductive layer 142 is provided over the conductive layer 265. The conductive layer 142 is formed to be embedded in the insulating layer 141 and is electrically connected to the conductive layer 265.

The semiconductor device 20E includes an insulating layer 147 over the insulating layer 141 and a conductive layer 146 over the conductive layer 142. The conductive layer 146 is formed to be embedded in the insulating layer 147 and is electrically connected to the conductive layer 142.

The semiconductor device 20E includes an insulating layer 180 over the insulating layer 147 and the conductive layer 146. The opening portion 190 is provided in part of the insulating layer 180, which is in a region overlapping with part of the conductive layer 146. The semiconductor device 20E includes the conductive layer 115 covering the opening portion 190 when seen from the Z direction. The conductive layer 115 includes a region that overlaps with the conductive layer 146 and is electrically connected to the conductive layer 146 in a bottom portion of the opening portion 190. The conductive layer 115 includes a region overlapping with a side surface of the opening portion 190. That is, the conductive layer 115 includes a region in contact with a side surface of the insulating layer 180 in the opening portion 190.

The semiconductor device 20E includes the insulating layer 270 covering the opening portion 190 when seen from the Z direction. The insulating layer 270 includes a region that overlaps with the conductive layer 146 with the conductive layer 115 therebetween in the bottom portion of the opening portion 190. The insulating layer 270 also includes a region that overlaps with the side surface of the insulating layer 180 with the conductive layer 115 therebetween.

The semiconductor device 20E includes the conductive layer 260 covering the opening portion 190 when seen from the Z direction. The conductive layer 260 includes a region that overlaps with the conductive layer 146 with the insulating layer 270 and the conductive layer 115 therebetween in the bottom portion of the opening portion 190. The conductive layer 260 also includes a region that overlaps with the side surface of the insulating layer 180 with the insulating layer 270 and the conductive layer 115 therebetween.

Also in the semiconductor device 20E, a region where the conductive layer 260 and the conductive layer 115 overlap with each other with the insulating layer 270 therebetween functions as the capacitor 22. The conductive layer 260 functions as one of a pair of electrodes of the capacitor 22, and the conductive layer 115 functions as the other of the pair of electrodes of the capacitor 22. The conductive layer 115 and the conductive layer 265 are electrically connected to each other via the conductive layer 146 and the conductive layer 142. Since the capacitor 22 of the semiconductor device 20E is provided in the opening portion 190, the capacitance value of the capacitor 22 can be increased without increase in occupation area seen from the Z direction.

The transistor 21 and the capacitor 22 can be designed with a high degree of freedom because they are provided with the insulating layer and the conductive layer therebetween. The insulating layer 147 and the conductive layer 146 preferably have flat top surfaces. As in the semiconductor device 20F illustrated in FIG. 11B, a structure in which the capacitor 22 does not overlap with the transistor 21 may be employed depending on the purpose or the like.

The insulating layer 141 and the insulating layer 147 function as interlayer films and thus preferably have low relative permittivity. When a material with low relative permittivity is used for an interlayer film, parasitic capacitance generated between wirings can be reduced. For the insulating layer 141 and the insulating layer 147, a single layer or stacked layers of any of the insulating layers each containing a material with low relative permittivity described above in [Insulating layer] can be used.

As the conductive layer 142 and the conductive layer 146, a single layer or stacked layers of any of the conductors described above in [Conductive layer] can be used.

### [Operation Example of Semiconductor Device 20]

Next, an operation example of the semiconductor device 20 will be described. As described above, the semiconductor device 20 of one embodiment of the present invention functions as a memory cell.

### <<Hysteresis Characteristics of Ferroelectric>>

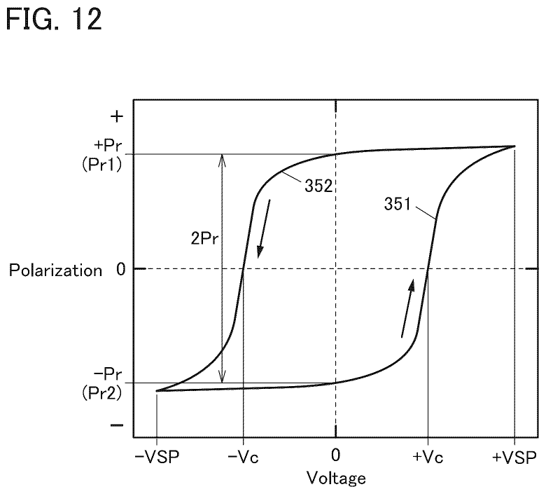

A ferroelectric has hysteresis characteristics. FIG. 12 is a graph showing an example of hysteresis characteristics of the ferroelectric. The hysteresis characteristics can be measured using a capacitor element including a ferroelectric (a ferroelectric capacitor). In FIG. 12, the horizontal axis represents voltage (electric field) applied to the ferroelectric. The voltage is a potential difference between one electrode and the other electrode of the ferroelectric capacitor. Note that the electric field strength can be obtained by dividing the potential difference by the thickness of the ferroelectric.

In FIG. 12, the vertical axis represents polarization of the ferroelectric. Positive polarization indicates that positive charge in the ferroelectric is biased toward one electrode side of the capacitor element and negative charge is biased toward the other electrode side of the capacitor element. By contrast, negative polarization indicates that negative charge in the ferroelectric is biased toward one electrode side of the capacitor element and positive charge is biased toward the other electrode side of the capacitor element.

The polarization represented by the vertical axis of the graph in FIG. 12 may be positive when negative charge is biased toward one electrode side of the capacitor element and positive charge is biased toward the other electrode side of the capacitor element, and may be negative when positive charge is biased toward one electrode side of the capacitor element and negative charge is biased toward the other electrode side of the capacitor element.

As shown in FIG. 12, the hysteresis characteristics of the ferroelectric can be represented by a curve 351 and a curve 352. Voltages at intersection points of the curve 351 and the curve 352 are referred to as a saturation polarization voltage +VSP (also referred to as “+VSP”) and a saturation polarization voltage −VSP (also referred to as “−VSP”). It can be said that +VSP and −VSP have different polarities.

When a voltage lower than or equal to −VSP is applied to the ferroelectric and then the voltage applied to the ferroelectric increases, the polarization of the ferroelectric increases along the curve 351. Meanwhile, when a voltage higher than or equal to +VSP is applied to the ferroelectric and then the voltage applied to the ferroelectric decreases, the polarization of the ferroelectric decreases along the curve 352. Note that in some cases, +VSP is referred to as a “positive saturation polarization voltage” or a “first saturation polarization voltage”, and −VSP is referred to as a “negative saturation polarization voltage” or a “second saturation polarization voltage”. The absolute value of the first saturation polarization voltage may be the same as or different from the absolute value of the second saturation polarization voltage.

The voltage at the time when the polarization of the ferroelectric changes along the curve 351 to reach 0 is referred to as a coercive voltage +Vc. The voltage at the time when the polarization of the ferroelectric changes along the curve 352 to reach 0 is referred to as a coercive voltage −Vc. The value of +Vc and the value of −Vc are each a value between +VSP and −VSP. In some cases, +Vc is referred to as a “positive coercive voltage” or a “first coercive voltage”, and −Vc is referred to as a “negative coercive voltage” or a “second coercive voltage”. The absolute value of the first coercive voltage may be the same as or different from the absolute value of the second coercive voltage.

When no voltage is applied to the ferroelectric (when the voltage is 0 V), the maximum value of polarization and the minimum value of polarization are referred to as “remanent polarization+Pr” or “remanent polarization Pr1” and “remanent polarization −Pr” or “remanent polarization Pr2”, respectively. The difference between the absolute values of the remanent polarization+Pr and the remanent polarization −Pr is referred to as “remanent polarization 2Pr”. A larger remanent polarization 2Pr increases the range of a change in the capacitance value of the ferroelectric capacitor due to polarization reversal. The remanent polarization 2Pr is preferably as large as possible.

### <<Relation Between Polarization of Ferroelectric and Id-Vg Characteristics>>

Next, the relation between the polarization of the ferroelectric included in the capacitor 22 and the Id-Vg characteristics of the transistor 21 will be described below.

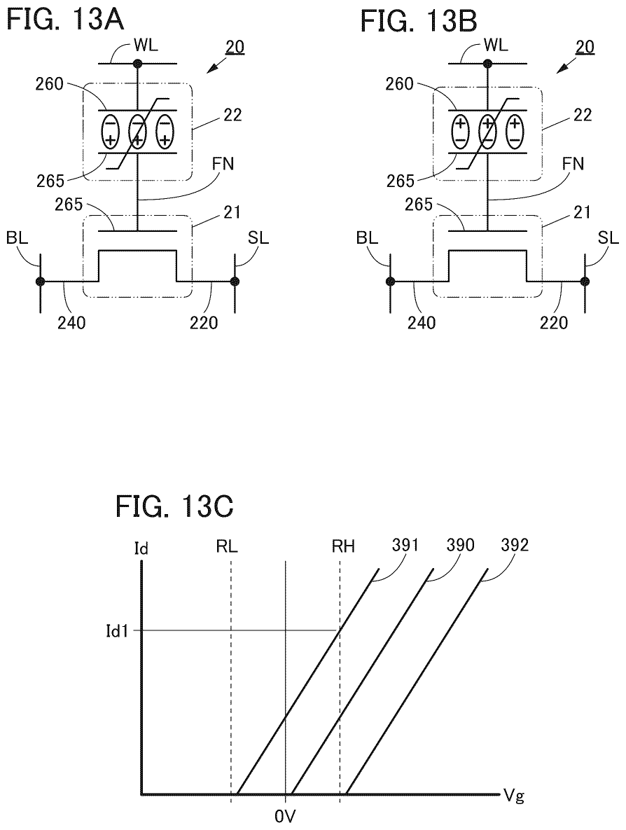

FIG. 13A and FIG. 13B are equivalent circuit diagrams of the semiconductor device 20 including the transistor 21 and the capacitor 22 that is a ferroelectric capacitor. FIG. 13A and FIG. 13B schematically illustrate the polarization of the insulating layer 270, which is a ferroelectric layer included in the capacitor 22.

FIG. 13C is a diagram showing the Id-Vg characteristics of the transistor 21 at the time when the voltage between the source and the drain (also referred to as a “drain voltage” or “Vd”) is constant. In FIG. 13C, the horizontal axis represents voltage between the source and the gate (also referred to as a “gate voltage” or “Vg”), and the vertical axis represents current flowing between the source and the drain (also referred to as a “drain current” or “Id”).

In FIG. 13C, characteristics 390 show the Id-Vg characteristics of the transistor 21 at the time when polarization is not caused in the insulating layer 270 included in the capacitor 22. In FIG. 13C, characteristics 391 show the Id-Vg characteristics at the time when the polarization of the insulating layer 270 is the remanent polarization Pr1. FIG. 13A is a schematic diagram showing the polarization of the insulating layer 270 included in the capacitor 22 in the characteristics 391.

Since the remanent polarization Pr1 is positive polarization, a positive voltage is generated at a node FN. Thus, the Id-Vg characteristics of the characteristics 390 shift in the negative direction of Vg to be the characteristics 391. That is, the threshold voltage of the transistor 21 shifts in the negative direction of Vg.

In FIG. 13C, characteristics 392 show the Id-Vg characteristics at the time when the polarization of the insulating layer 270 is the remanent polarization Pr2. FIG. 13B is a schematic diagram showing the polarization of the insulating layer 270 included in the capacitor 22 in the characteristics 392.

Since the remanent polarization Pr2 is negative polarization, a negative voltage is generated at the node FN. Thus, the Id-Vg characteristics of the characteristics 390 shift in the positive direction of Vg to be the characteristics 392. That is, the threshold voltage of the transistor 21 shifts in the positive direction of Vg.

As illustrated in FIG. 13A to FIG. 13C, the Id-Vg characteristics of the transistor 21 can be changed in accordance with the polarization of the insulating layer 270, which is a ferroelectric layer. In other words, by controlling the polarization of the insulating layer 270, the threshold voltage of the transistor 21 can be controlled. Thus, the semiconductor device 20 including the transistor 21 and the capacitor 22 can function as a memory cell that can retain binary data.

For example, in the case where binary data of data “0” or “1” is written to the semiconductor device 20 functioning as a memory cell, the polarization of the insulating layer 270 is the remanent polarization Pr1 when data “1” is written, and the polarization of the insulating layer 270 is the remanent polarization Pr2 when data “0” is written. The Id-Vg characteristics of the semiconductor device 20 to which data “1” has been written become the characteristics 391. The Id-Vg characteristics of the semiconductor device 20 to which data “0” has been written become the characteristics 392.

Next, erasing, writing, retaining, and reading operations of the semiconductor device 20 will be described.

### <<Erasing Operation>

Before data is written to the semiconductor device 20 functioning as a memory cell, data needs to be erased. In this embodiment, operation of writing data “0” to the semiconductor device 20 is performed as erasing operation. That is, the polarization of the insulating layer 270 is set to the remanent polarization Pr2.

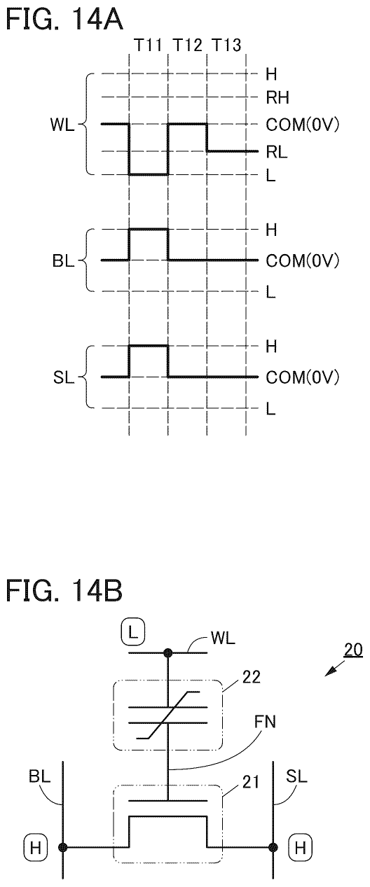

FIG. 14A is a timing chart for describing the erasing operation. FIG. 14B is a circuit diagram illustrating a state of the semiconductor device 20 in Period T11. Note that in the circuit diagram and the like, for easy understanding of the potential of a wiring or the like, a symbol showing the potential of the wiring is sometimes written adjacent to the wiring or the like. Furthermore, a symbol showing the potential of a wiring or the like whose potential has changed is sometimes denoted as an enclosed symbol.

In Period T11, a potential L is supplied to the wiring WL, and a potential H is supplied to the wiring BL and the wiring SL.

Note that a gate capacitance of the transistor 21 and the capacitor 22 are connected in series between the wiring WL and the wiring BL and between the wiring WL and the wiring SL. A voltage applied to the capacitor 22 is determined by the ratio of the gate capacitance of the transistor 21 and the capacitance of the capacitor 22. In this embodiment, the ratio of the gate capacitance of the transistor 21 and the capacitance of the capacitor 22 is 1:1. Accordingly, the potential difference between the potential H and the potential L is set to twice or more VSP. In order to change the polarization of the insulating layer 270 to the remanent polarization Pr2, the potential H is supplied to the wiring BL and the wiring SL, and the potential L is supplied to the wiring WL. The potential H is a potential higher than the potential L.

For example, in the case where a potential COM is a reference potential (0 V), the potential H is preferably higher than the potential COM and is different from the potential COM by +VSP. Similarly, the potential L is preferably lower than the potential COM and is preferably different from the potential COM by −VSP.

Under the above conditions, the potential L is supplied to the wiring WL and the potential H is supplied to the wiring BL and the wiring SL, whereby −VSP is applied to the capacitor 22. Next, in Period T12, 0 V is supplied to the wiring WL, the wiring BL, and the wiring SL. That is, the wiring WL, the wiring BL, and the wiring SL are made to have the same potential.

In Period T12, the polarization of the insulating layer 270 becomes the remanent polarization Pr2 (see FIG. 12). Since the remanent polarization Pr2 is negative polarization as described above, a negative voltage is generated at the node FN. Thus, the Id-Vg characteristics of the characteristics 390 shift in the positive direction of Vg to be the characteristics 392. That is, the threshold voltage of the transistor 21 shifts in the positive direction of Vg (see FIG. 13C). In Period T13, a potential RL is supplied to the wiring WL. The potential RL will be described in detail in the description of the retaining operation. Note that Period T12 may be omitted and Period T11 may be followed by Period T13. A negative voltage is generated at the node FN through Period T11 even when Period T12 is omitted.

### <<Writing Operation>>

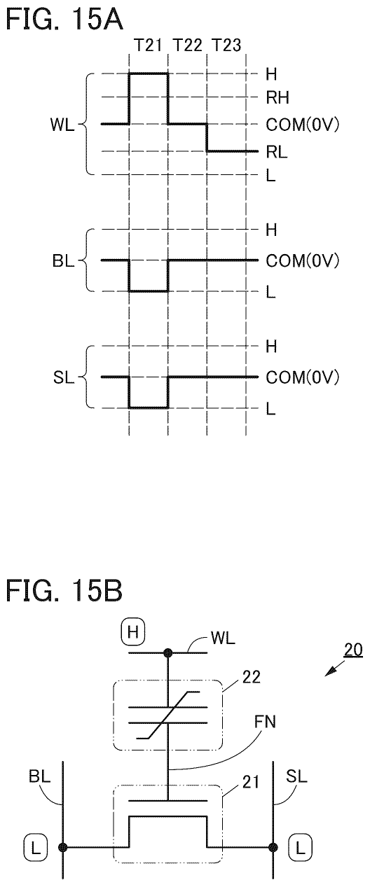

Next, operation of writing data “1” to the semiconductor device 20 functioning as a memory cell will be described. FIG. 15A is a timing chart for describing the writing operation. FIG. 15B is a circuit diagram illustrating a state of the semiconductor device 20 in Period T22.

After the erasing operation is performed in Period T11, the potential H is supplied to the wiring WL and the potential L is supplied to the wiring BL and the wiring SL in Period T21. Thus, +VSP is applied to the capacitor 22, and the polarization of the insulating layer 270 changes along the curve 351 (see FIG. 12). Then, in Period T22, 0 V is supplied to the wiring WL, the wiring BL, and the wiring SL. That is, the wiring WL, the wiring BL, and the wiring SL are made to have the same potential.

In Period T22, the polarization of the insulating layer 270 becomes the remanent polarization Pr1 (see FIG. 12). Since the remanent polarization Pr1 is positive polarization as described above, a positive voltage is generated at the node FN. Thus, the Id-Vg characteristics of the characteristics 390 shift in the negative direction of Vg to be the characteristics 391. That is, the threshold voltage of the transistor 21 shifts in the negative direction of Vg (see FIG. 13C).

In this manner, the data “1” can be written to the semiconductor device 20. Since the capacitor 22 is a ferroelectric capacitor, polarization of the insulating layer 270, which is a ferroelectric, is maintained even when power supply to the semiconductor device 20 stops. Thus, data written to the semiconductor device 20 is maintained even when power supply to the semiconductor device 20 stops. Accordingly, the semiconductor device 20 functions as a nonvolatile memory cell.

The operation of writing data “0” to the semiconductor device 20 is the same as the above-described erasing operation. Accordingly, there is no need to perform the operation of writing data “0” after the erasing operation.

### <<Retaining Operation>>

After data is written to the semiconductor device 20, the potential RL is supplied to the wiring WL in Period T23. The potential RL is a potential at which the transistor 21 is turned off even when the Id-Vg characteristics of the transistor 21 are the characteristics 391 (see FIG. 13C). Thus, the potential RL may be set to a potential lower than the threshold voltage of the characteristics 391. Moreover, in order to hardly cause a change in polarization of the insulating layer 270, the potential RL is set to a voltage with which a voltage applied to the capacitor 22 is higher than or equal to the coercive voltage −Vc.

After the writing operation, the potential of the wiring WL is preferably the potential RL until the reading operation is performed. When the potential of the wiring WL remains as the potential RL, the transistor 21 is surely brought into an off state; thus, power consumption of the semiconductor device 20 is reduced. Moreover, in the case where the semiconductor devices 20 are arranged in a matrix to form a memory cell array, interference in the reading operation of another memory cell (semiconductor device 20) can be prevented. Consequently, the memory cell array can have higher reliability.

Note that Period T22 may be omitted and Period T23 may be followed by Period T21.

### <<Reading Operation>>

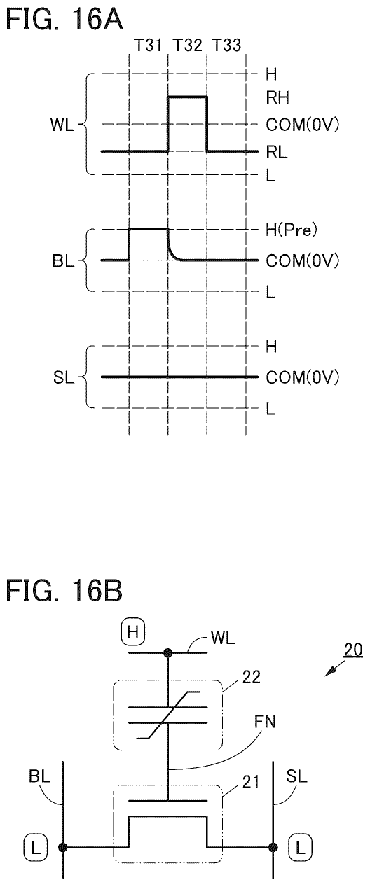

Next, operation of reading data retained in the semiconductor device 20 functioning as a memory cell will be described. FIG. 16A is a timing chart for describing the reading operation. FIG. 16B is a circuit diagram illustrating a state of the semiconductor device 20 in Period T31. In this embodiment, the reading operation of the semiconductor device 20 that retains data “1” is described.

In Period T31, the wiring BL is precharged with the potential H. That is, after the potential of the wiring BL is set to the potential H, the wiring BL is brought into a floating state (a state where electric power is supplied from nowhere). In addition, the potential COM is supplied to the wiring SL.

Next, in Period T32, a potential RH that is a reading potential is supplied to the wiring WL. The potential RH is a potential higher than or equal to the threshold voltage of the characteristics 391 and lower than the threshold voltage of the characteristics 392. Moreover, in order to hardly cause a change in polarization of the insulating layer 270, the potential RH is set to a voltage with which the voltage applied to the capacitor 22 is lower than or equal to the coercive voltage +Vc.

In the case where the data “1” is retained in the semiconductor device 20, when the potential RH is supplied to the wiring WL, the transistor 21 is turned on, and a current Idl flows between the source and the drain (see FIG. 13C). Thus, electrical continuity is established between the wiring BL and the wiring SL, and the potential of the wiring BL that is in a floating state changes toward the potential COM.

The case where the potential of the wiring BL changes after the potential RH is supplied to the wiring WL can be determined that the data “1” has been written to the semiconductor device 20. The case where it is judged that the potential of the wiring BL does not change even when the potential RH is supplied to the wiring WL can be determined that the data “0” has been written to the semiconductor device 20.

After the reading operation, the potential RL is supplied to the wiring WL in Period T33. Since the potential RH is set to a voltage with which the voltage applied to the capacitor 22 is lower than or equal to the coercive voltage +Vc, the polarization of the insulating layer 270 included in the capacitor 22 is less likely to change. Thus, non-destructive reading of the semiconductor device 20 can be achieved.

Note that the hysteresis characteristics of the ferroelectric change depending on the material, the structure, and the formation method. Accordingly, the potential RH is preferably a voltage with which the voltage applied to the capacitor 22 is less than or equal to 0.8 times, preferably less than or equal to 0.6 times the coercive voltage +Vc. Moreover, the potential RL is preferably a voltage with which the voltage applied to the capacitor 22 is greater than or equal to 0.8 times, preferably greater than or equal to 0.6 times the coercive voltage −Vc.

### <Structure Example of Semiconductor Device 30>

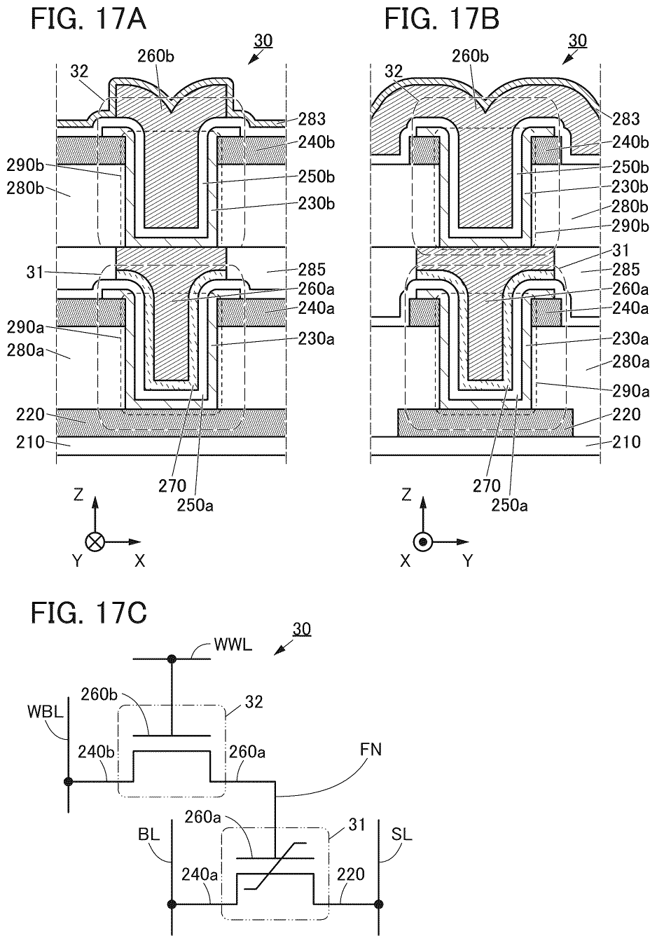

A semiconductor device 30, which is another example of the semiconductor device, will be described with reference to FIG. 17A to FIG. 17C. FIG. 17A is a cross-sectional view of the semiconductor device 30, which is seen from the Y direction, and FIG. 17B is a cross-sectional view of the semiconductor device 30, which is seen from the X direction.

The semiconductor device 30 illustrated in FIG. 17A and FIG. 17B is also a variation example of the semiconductor device 10 illustrated in FIG. 1A to FIG. 1C. The semiconductor device 30 is different from the semiconductor device 10 mainly in including a second transistor over a first transistor functioning as an FeFET. Portions different from the above description of <Structure example of semiconductor device 10> are mainly described below, the above description is referred to for the same portion, and the description of the same portions is omitted in some cases.

The semiconductor device 30 of one embodiment of the present invention includes a transistor 31 and a transistor 32 over the transistor 31. The semiconductor device 30 has a structure in which the transistor 31 and the transistor 32 are provided to overlap with each other. When the transistor 31 and the transistor 32 are provided to overlap with each other, the area occupied by the semiconductor device 30 can be reduced.

The semiconductor device 30 includes the insulating layer 210, the transistor 31 over the insulating layer 210, an insulating layer 280a over the insulating layer 210, an insulating layer 285, an insulating layer 280b over the insulating layer 285, the transistor 32, and the insulating layer 283 over the transistor 32. The insulating layer 210, the insulating layer 280a, the insulating layer 285, the insulating layer 280b, and the insulating layer 283 function as interlayer films.

The transistor 31 includes the conductive layer 220, a conductive layer 240a above the conductive layer 220, a semiconductor layer 230a over the conductive layer 220, an insulating layer 250a over the semiconductor layer 230a, the insulating layer 270 over the insulating layer 250a, and a conductive layer 260a over the insulating layer 270.

The transistor 31 has a structure similar to the above-described structure of the transistor 11. The description of the structure of the transistor 11 can be referred to for the structure of the transistor 31 by replacing the transistor 11, the conductive layer 240, the semiconductor layer 230, the insulating layer 250, and the conductive layer 260 with the transistor 31, the conductive layer 240a, the semiconductor layer 230a, the insulating layer 250a, and the conductive layer 260a, respectively, and appropriately replacing words or sentences as necessary. The transistor 31 functions as an FeFET.

The transistor 32 is provided above the insulating layer 250a. The transistor 32 includes the conductive layer 260a, a conductive layer 240b above the conductive layer 260a, a semiconductor layer 230b over the conductive layer 260a, an insulating layer 250b over the semiconductor layer 230b, and the conductive layer 260b over the insulating layer 250b.

The conductive layer 220 is provided over the insulating layer 210, the insulating layer 280a is provided over the insulating layer 210 and the conductive layer 220, and the conductive layer 240a is provided over the insulating layer 280a. The insulating layer 285 is provided over the insulating layer 250a, the insulating layer 280b is provided over the insulating layer 285 and the conductive layer 260a, and the conductive layer 240b is provided over the insulating layer 280b. The insulating layer 283 is provided over the insulating layer 250b and the conductive layer 260b.

In this specification and the like, as for components that are distinguished from each other by letters of the alphabet, the description made using reference numerals without the letters of the alphabet can be referred to in some cases. For example, for the structure of the insulating layer 280a or the insulating layer 280b, the description of the structure of the insulating layer 280 can be referred to by replacing the insulating layer 280 with the insulating layer 280a or the insulating layer 280b and appropriately replacing words or sentences as necessary.

An opening portion 290b reaching the conductive layer 260a is provided in the insulating layer 280b and the conductive layer 240b. That is, the opening portion 290b is provided in a region overlapping with part of the conductive layer 260a in a plan view. Here, a bottom portion of the opening portion 290b is the top surface of the conductive layer 260a, and a sidewall of the opening portion 290b is a side surface of the insulating layer 280b and a side surface of the conductive layer 240b. The opening portion 290b includes an opening portion included in the insulating layer 280b and an opening portion included in the conductive layer 240b. The opening portion included in the conductive layer 240b includes a region overlapping with the opening portion included in the insulating layer 280b.

At least parts of the components of the transistor 32 are positioned in the opening portion 290b. Specifically, at least part of each of the semiconductor layer 230b, the insulating layer 250b, and the conductive layer 260b is positioned in the opening portion 290b.

The semiconductor layer 230b is provided to cover the opening portion 290b, the insulating layer 250b is provided to cover the semiconductor layer 230b, and the conductive layer 260b is provided to fill a depressed portion that is defined by the insulating layer 250b and reflects the shape of the opening portion 290b. Thus, portions of the semiconductor layer 230b, the insulating layer 250b, and the conductive layer 260b that are positioned in the opening portion 290b reflect the shape of the opening portion 290b.

The semiconductor layer 230b includes a region overlapping with the bottom portion of the opening portion 290b and a region overlapping with a side surface of the opening portion 290b. In other words, the semiconductor layer 230b includes a region in contact with the side surface of the insulating layer 280b in the opening portion 290b. The semiconductor layer 230b includes a region in contact with the conductive layer 260a and a region in contact with the conductive layer 240b. In other words, part of the semiconductor layer 230b is electrically connected to the conductive layer 260a, and another part of the semiconductor layer 230b is electrically connected to the conductive layer 240b.

The top surfaces of the conductive layer 260a and the insulating layer 285 are preferably flat. Planarization of the top surfaces of the conductive layer 260a and the insulating layer 285 facilitates the subsequent steps, thereby increasing the yield of the semiconductor device.

The conductive layer 260a includes a region in contact with the semiconductor layer 230b included in the transistor 32. The conductive layer 260a has a function of a gate electrode of the transistor 31 and a function of one of a source electrode and a drain electrode of the transistor 32.

The structure of the transistor 32 is similar to the structure of the transistor 21 illustrated in FIG. 10A to FIG. 10C except for the structure of the one of the source electrode and the drain electrode. For the structure of the transistor 32, except for the structure of the one of the source electrode and the drain electrode, the description of the structure of the transistor 21 can be referred to by replacing the transistor 21, the conductive layer 240, the semiconductor layer 230, the insulating layer 250, and the conductive layer 265 with the transistor 32, the conductive layer 240b, the semiconductor layer 230b, the insulating layer 250b, and the conductive layer 260b, respectively, and appropriately replacing words or sentences as necessary.

When the transistor 31 and the transistor 32 are vertical-channel transistors, the same mask can be used for the transistor 31 and the transistor 32, so that the manufacturing cost can be reduced.

Note that since the transistor 31 and the transistor 32 are stacked, the transistor 31 and the transistor 32 may have different structures. For example, one of the transistor 31 and the transistor 32 may be a planar transistor, a staggered transistor, an inverted staggered transistor, or the like. The transistor structure may be either a top-gate structure or a bottom-gate structure. Alternatively, gates may be provided above and below a semiconductor layer where a channel is formed.

FIG. 17C is an equivalent circuit diagram of the semiconductor device 30. In FIG. 17C, one of a source and a drain of the transistor 31 is electrically connected to a wiring SL, the other of the source and the drain of the transistor 31 is electrically connected to a wiring BL. A gate of the transistor 31 and one of a source and a drain of the transistor 32 are electrically connected to a node FN. The other of the source and the drain of the transistor 32 is electrically connected to a wiring WBL, and a gate of the transistor 32 is electrically connected to a wiring WWL. The semiconductor device 30 functions as a memory circuit. Note that FIG. 17C is an equivalent circuit diagram of the case where the transistor 31 includes a ferroelectric. The semiconductor device 30 functions as a memory cell.

The conductive layer 220 functions as at least part of the wiring SL. The conductive layer 240a functions as at least part of the wiring BL. Note that the wiring SL and the wiring BL can be interchanged with each other. The conductive layer 220 may function as at least part of the wiring BL, and the conductive layer 240a may function as at least part of the wiring SL. The conductive layer 240b functions as at least part of the wiring WBL. The conductive layer 260b functions as at least part of the wiring WWL.

In the circuit structure illustrated in FIG. 17C, a potential can be supplied from the wiring WBL to the node FN through the transistor 32; thus, the operation voltage of the semiconductor device 30 required for data writing can be reduced.

### Variation Example

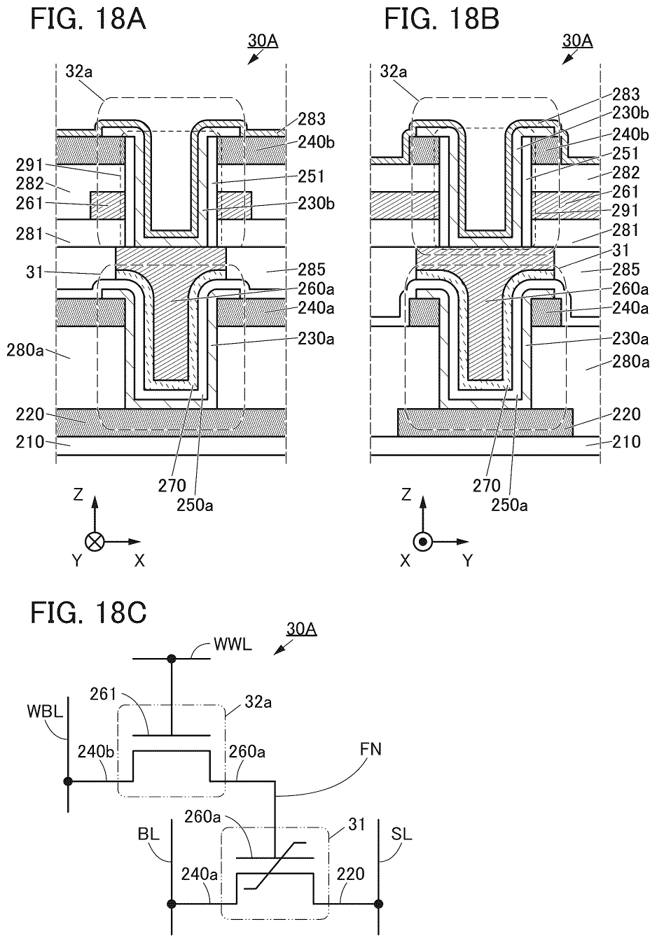

FIG. 18A and FIG. 18B illustrate a semiconductor device 30A, which is a variation example of the semiconductor device 30. FIG. 18A is a cross-sectional view of the semiconductor device 30A, which is seen from the Y direction. FIG. 18B is a cross-sectional view of the semiconductor device 30A, which is seen from the X direction.

The semiconductor device 30A is different from the semiconductor device 30 in including a transistor 32a instead of the transistor 32. Differences from the description with reference to FIG. 17A and FIG. 17B are mainly described below; the description is referred to for the same portions, and the description of the same portions is omitted in some cases.

The semiconductor device 30A includes the transistor 31 and the transistor 32a over the transistor 31. The semiconductor device 30A has a structure in which the transistor 31 and the transistor 32a are provided to overlap with each other. When the transistor 31 and the transistor 32a are provided to overlap with each other, the area occupied by the semiconductor device 30A can be reduced.

The semiconductor device 30A includes the insulating layer 210, the insulating layer 280a, the insulating layer 285, an insulating layer 281, an insulating layer 282, and an insulating layer 283. The insulating layer 210, the insulating layer 280a, the insulating layer 285, the insulating layer 281, the insulating layer 282, and the insulating layer 283 function as interlayer films. For the insulating layer 281 and the insulating layer 282, the insulator that can be used for the insulating layer 280 can be used.

The transistor 32a includes the conductive layer 260a, a conductive layer 261 above the conductive layer 260a, the conductive layer 240b above the conductive layer 261, and an insulating layer 251 and the semiconductor layer 230b over the conductive layer 260a.

The insulating layer 281 is provided over the insulating layer 285 and the conductive layer 260a, the conductive layer 261 is provided over the insulating layer 281, the insulating layer 282 is provided over the insulating layer 281 and the conductive layer 261, and the conductive layer 240b is provided over the insulating layer 282. The insulating layer 283 is provided over the conductive layer 240b and the semiconductor layer 230b.

An opening portion 291 reaching the conductive layer 260a is provided in the insulating layer 281, the conductive layer 261, the insulating layer 282, and the conductive layer 240b. That is, the opening portion 291 is provided in a region overlapping with part of the conductive layer 260a in a plan view. Here, a bottom portion of the opening portion 291 is the top surface of the conductive layer 260a, and a sidewall of the opening portion 291 is a side surface of the insulating layer 281, a side surface of the conductive layer 261, a side surface of the insulating layer 282, and a side surface of a conductive layer 240b. The opening portion 291 includes an opening portion included in the insulating layer 281, an opening portion included in the conductive layer 261, an opening portion included in the insulating layer 282, and an opening portion included in the conductive layer 240b.

At least parts of the components of the transistor 32a are positioned in the opening portion 291. Specifically, at least part of each of the insulating layer 251 and the semiconductor layer 230b is positioned in the opening portion 291. As described above, in the transistor 32, at least part of each of the semiconductor layer 230b, the insulating layer 250b, and the conductive layer 260b is positioned in the opening portion 290. Since a small number of components of the transistor 32a are provided in the opening portion 291, the opening portion 291 can have a smaller maximum width than the opening portion 290. Thus, the area occupied by the transistor 32a can be smaller than that occupied by the transistor 32. Accordingly, high integration of the semiconductor device 30A can be achieved.

The insulating layer 251 is provided in a sidewall shape in contact with the sidewall of the opening portion 291. In the opening portion 291, the insulating layer 251 includes a region in contact with the side surface of the insulating layer 281, a region in contact with the side surface of the conductive layer 261, a region in contact with the side surface of the insulating layer 282, and a region in contact with the side surface of the conductive layer 240b.

The semiconductor layer 230b is provided to cover the opening portion 291 in a plan view. The semiconductor layer 230b includes a region in contact with a side surface of the insulating layer 251 in the opening portion 291, a region in contact with the top surface of the conductive layer 260a in the opening portion 291, and a region in contact with the top surface of the conductive layer 240b. In other words, part of the semiconductor layer 230b is electrically connected to the conductive layer 260a, and another part of the semiconductor layer 230b is electrically connected to the conductive layer 240b. Note that the semiconductor layer 230b may be provided to fill the opening portion 191.

The conductive layer 260a includes a region functioning as one of a source electrode and a drain electrode of the transistor 32a. The conductive layer 240b includes a region functioning as the other of the source electrode and the drain electrode of the transistor 32a. For example, in the case where the conductive layer 260a includes a region functioning as the drain electrode of the transistor 32a, the conductive layer 240b includes a region functioning as the source electrode of the transistor 32a.

The semiconductor layer 230b includes a region functioning as a semiconductor layer where a channel of the transistor 32a is formed. The conductive layer 251 includes a region functioning as a gate insulating layer of the transistor 32a. The channel of the transistor 32a is formed in the semiconductor layer 230b between a region of the semiconductor layer 230b that is in contact with the conductive layer 260a and a region of the semiconductor layer 230b that is in contact with the conductive layer 240b. In other words, the transistor 32a is provided in a region including the opening portion 291.

As the insulating layer 251, the insulator that can be used for the insulating layer 250 can be used. As the conductive layer 261, the conductor that can be used for the conductive layer 260 can be used.

FIG. 18C is an equivalent circuit diagram of the semiconductor device 30A. The equivalent circuit of the semiconductor device 30A illustrated in FIG. 18C is similar to the equivalent circuit of the semiconductor device 30 illustrated in FIG. 17C. For the equivalent circuit of the semiconductor device 30A, the description of the equivalent circuit of the semiconductor device 30 can be referred to by replacing the transistor 32 and the conductive layer 260b with the transistor 32a and the conductive layer 261, respectively, and appropriately replacing words or sentences as necessary.

### <Structure Example of Semiconductor Device 40>

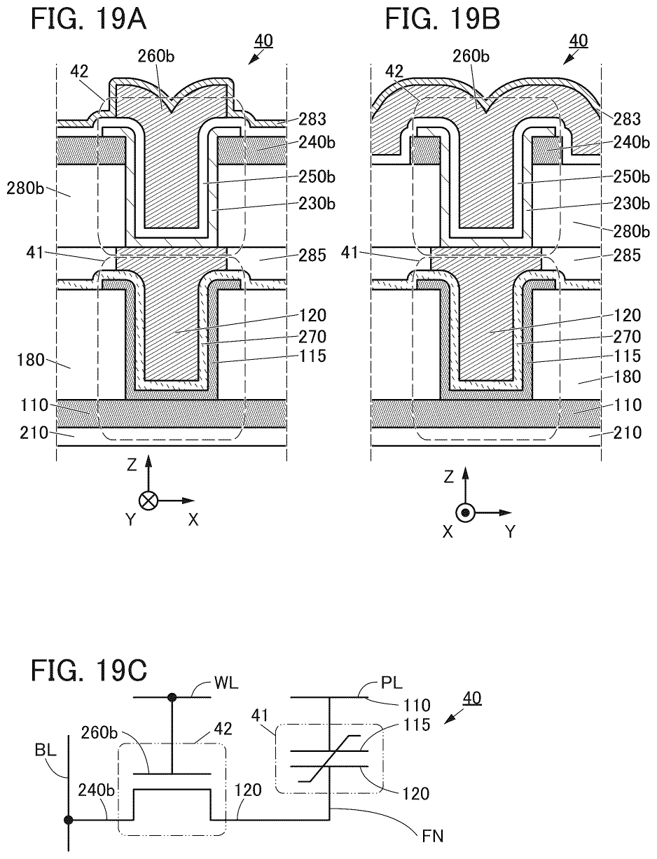

A semiconductor device 40, which is another example of the semiconductor device, will be described with reference to FIG. 19A to FIG. 19C. FIG. 19A is a cross-sectional view of the semiconductor device 40, which is seen from the Y direction, and FIG. 19B is a cross-sectional view of the semiconductor device 40, which is seen from the X direction.

Note that in the semiconductor device illustrated in FIG. 19A and FIG. 19B, components having the same functions as the components included in the semiconductor device described in <Structure example of semiconductor device 10> or <Structure example of semiconductor device 30> are denoted by the same reference numerals.

The semiconductor device 40 of one embodiment of the present invention includes a capacitor 41 and a transistor 42 over the capacitor 41. The semiconductor device 40 has a structure in which the capacitor 41 and the transistor 42 are provided to overlap with each other. When the capacitor 41 and the transistor 42 are provided to overlap with each other, the area occupied by the semiconductor device 40 can be reduced.

The semiconductor device 40 includes the insulating layer 210, the conductive layer 110 over the insulating layer 210, the insulating layer 180 over the conductive layer 110, the capacitor 41 over the conductive layer 110, the insulating layer 285, the insulating layer 280b over the insulating layer 285, the transistor 42, and the insulating layer 283 over the transistor 42. The insulating layer 210, the insulating layer 180, the insulating layer 285, the insulating layer 280b, and the insulating layer 283 function as interlayer films. In the semiconductor device 40, part of the capacitor 41 is provided in an opening portion included in the insulating layer 180.

The capacitor 41 includes the conductive layer 115, the insulating layer 270 over the conductive layer 115, and the conductive layer 120 over the insulating layer 270. At least part of the conductive layer 115 functions as one of a pair of electrodes of the capacitor 41, at least part of the conductive layer 120 functions as the other of the pair of electrodes of the capacitor 41, and at least part of the insulating layer 270 functions as a dielectric of the capacitor 41. In other words, a region where the conductive layer 115 and the conductive layer 120 overlap with each other with the insulating layer 270 therebetween functions as the capacitor 41.

The conductive layer 115 is provided over the conductive layer 110 and includes a region in contact with the top surface of the conductive layer 110. In FIG. 19A and FIG. 19B, the conductive layer 110 is provided in a planar shape. Note that the conductive layer 110 may be provided in a band shape to extend in the X direction or may be provided in a band shape to extend in the Y direction.

The conductive layer 120 has a function of the other of the pair of electrodes of the capacitor 41 and a function of one of a source electrode and a drain electrode of the transistor 42. The conductive layer 120 is divided in the X direction and the Y direction.

The top surfaces of the conductive layer 120 and the insulating layer 285 are preferably flat. Planarization of the top surfaces of the conductive layer 120 and the insulating layer 285 facilitates the subsequent steps, thereby increasing the yield of the semiconductor device.

The structure of the capacitor 41 is similar to the structure of the capacitor 22 illustrated in FIG. 10A to FIG. 10C except for the structure of the other of the pair of electrodes. For the structure of the capacitor 41, except for the structure of the other of the pair of electrodes, the description of the structure of the capacitor 22 can be referred to by replacing the capacitor 22 and the conductive layer 260 with the capacitor 41 and the conductive layer 120, respectively, and appropriately replacing words or sentences as necessary.

A material that can have ferroelectricity is used for the insulating layer 270. In this case, the capacitor 41 functions as a ferroelectric capacitor.

In FIG. 19A and FIG. 19B, the insulating layer 270 is provided in a planar shape. Such a structure can eliminate the process for processing the insulating layer 270, thereby reducing the manufacturing cost of the semiconductor device. Note that as illustrated in FIG. 10B and FIG. 10C, the insulating layer 270 may be divided in the X direction and the Y direction. Such a structure can increase the reliability of the semiconductor device 40.

Although the capacitor 41 in the semiconductor device 40 has a cylindrical shape, the present invention is not limited thereto. For example, the capacitor 41 may have a planar shape.

The transistor 42 has a structure similar to the above-described structure of the transistor 32. For the structure of the transistor 42, <Structure example of semiconductor device 30> described above can be referred to.

The semiconductor device 40 may include the transistor 32a illustrated in FIG. 18A and FIG. 18B instead of the transistor 42. As described above, the area occupied by the transistor 32a can be smaller than that occupied by the transistor 42. Accordingly, high integration of the semiconductor device 40 can be achieved.

FIG. 19C is an equivalent circuit diagram of the semiconductor device 40. In FIG. 19C, one of a pair of electrodes of the capacitor 41 is electrically connected to a wiring WL. The other of the pair of electrodes of the capacitor 41 and one of a source and a drain of the transistor 42 are electrically connected to a node FN. The other of the source and the drain of the transistor 42 is electrically connected to a wiring WBL, and a gate of the transistor 42 is electrically connected to a wiring WWL. The semiconductor device 40 functions as a memory circuit. Note that FIG. 19C is an equivalent circuit diagram of the case where the capacitor 41 includes a ferroelectric.

The conductive layer 110 functions as at least part of the wiring WL. The conductive layer 240b functions as at least part of the wiring WBL, and the conductive layer 260b functions as at least part of the wiring WWL.

The wiring WL has a function of a word line, and the on state and off state of the transistor 42 can be controlled by controlling the potential of the wiring WL. For example, in the case where the transistor 42 is an n-channel transistor, the potential of the wiring WL is set to a high potential so that the transistor 42 can be turned on, while the potential of the wiring WL is set to a low potential so that the transistor 42 can be turned off.

The wiring BL has a function of a bit line, and the potential of the wiring BL is supplied to the one of the pair of electrodes of the capacitor 41 when the transistor 42 is in an on state.

The wiring PL has a function of a plate line. A potential is supplied to the other of the pair of electrodes of the capacitor 41 through the wiring PL.

The semiconductor device 40 illustrated in the equivalent circuit diagram of FIG. 19C is “1Tr1FE” memory cell including one transistor and one ferroelectric capacitor. The semiconductor device 40 including a ferroelectric in the capacitor 41 functions as a nonvolatile memory element that can retain data written therein even when power supply is stopped. A nonvolatile memory element with such a structure is referred to as an “FeRAM” in some cases.

A DRAM (Dynamic Random Access Memory) requires regular refresh operation and thus increases power consumption. The semiconductor device 40 including a ferroelectric in the capacitor 41 does not require refresh operation and thus can have low power consumption.

### <Structure Example of Semiconductor Device 50>

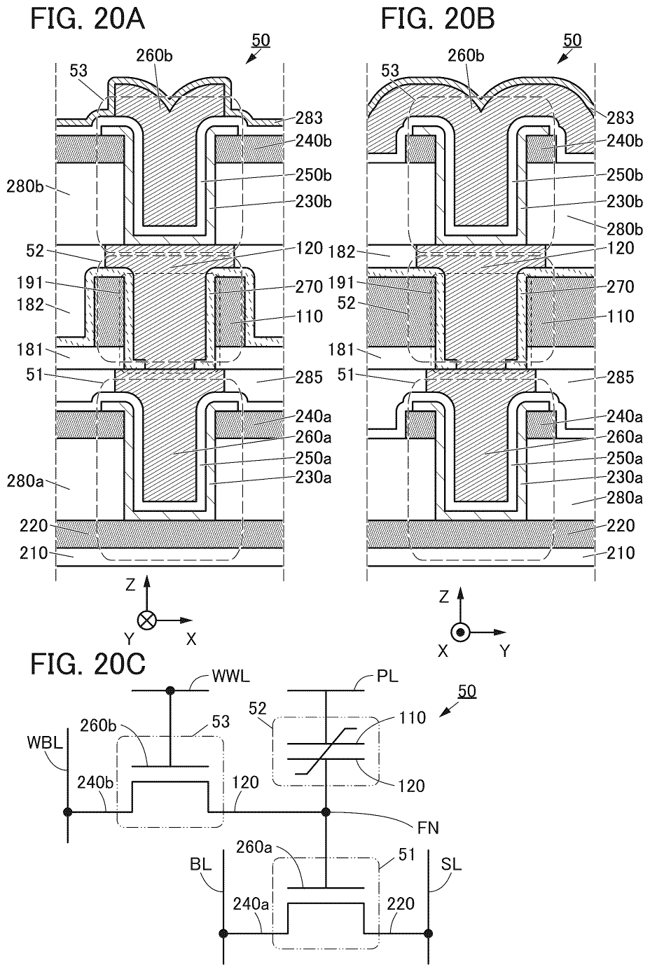

A semiconductor device 50, which is another example of the semiconductor device, will be described with reference to FIG. 20A to FIG. 20C. FIG. 20A is a cross-sectional view of the semiconductor device 50, which is seen from the Y direction, and FIG. 20B is a cross-sectional view of the semiconductor device 50, which is seen from the X direction.

Note that in the semiconductor device illustrated in FIG. 20A and FIG. 20B, components having the same functions as the components included in the semiconductor device described in <Structure example of semiconductor device 10>, <Structure example of semiconductor device 30>, or <Structure example of semiconductor device 40> are denoted by the same reference numerals.

The semiconductor device 50 of one embodiment of the present invention includes a transistor 51, a capacitor 52 over the transistor 51, a transistor 53 over the capacitor 52. The semiconductor device 50 has a structure in which the transistor 51, the capacitor 52, and the transistor 53 are provided to overlap with each other. When the transistor 51, the capacitor 52, and the transistor 53 are provided to overlap with each other, the area occupied by the semiconductor device 50 can be reduced.

The semiconductor device 50 includes the insulating layer 210, the insulating layer 280a, the insulating layer 285, an insulating layer 181, an insulating layer 182, the insulating layer 280b, and the insulating layer 283. The insulating layer 210, the insulating layer 280a, the insulating layer 285, the insulating layer 181, the insulating layer 182, the insulating layer 280b, and the insulating layer 283 function as interlayer films.

The transistor 51 has a structure similar to that of the transistor 21 illustrated in FIG. 10A to FIG. 10C. The description of the structure of the transistor 21 can be referred to for the structure of the transistor 51 by replacing the transistor 21, the conductive layer 240, the semiconductor layer 230, the insulating layer 250, and the conductive layer 265 with the transistor 51, the conductive layer 240a, the semiconductor layer 230a, the insulating layer 250a, and the conductive layer 260a, respectively, and appropriately replacing words or sentences as necessary.

The capacitor 52 includes the conductive layer 110, the insulating layer 270 over the conductive layer 110, and the conductive layer 120 over the insulating layer 270. At least part of the conductive layer 110 functions as one of a pair of electrodes of the capacitor 52, at least part of the conductive layer 120 functions as the other of the pair of electrodes of the capacitor 52, and at least part of the insulating layer 270 functions as a dielectric of the capacitor 52. In other words, a region where the conductive layer 110 and the conductive layer 120 overlap with each other with the insulating layer 270 therebetween functions as the capacitor 52.

The conductive layer 110 is provided over the insulating layer 181. The opening portion 191 reaching the conductive layer 260a is provided in the insulating layer 181 and the conductive layer 110. That is, the opening portion 191 is provided in a region overlapping with part of the conductive layer 260a in a plan view. Here, a bottom portion of the opening portion 191 is the top surface of the conductive layer 260a, and a sidewall of the opening portion 191 is a side surface of the insulating layer 181 and a side surface of the conductive layer 110. The opening portion 191 includes an opening portion included in the insulating layer 181 and an opening portion included in the conductive layer 110. The opening portion included in the conductive layer 110 includes a region overlapping with the opening portion included in the insulating layer 181.

The insulating layer 270 is provided to cover the opening portion 191. In a bottom portion of the opening portion 191, an opening portion reaching the conductive layer 260a is provided in the insulating layer 270. The conductive layer 120 is provided to fill the opening portion 191 and is in contact with the conductive layer 260a in the bottom portion of the opening portion 191. The conductive layer 120 functioning as the other of the pair of electrodes of the capacitor 52 is divided in the X direction and the Y direction. The insulating layer 182 is provided over the insulating layer 270 outside the opening portion 191.

FIG. 20A illustrates a structure in which an end portion of the conductive layer 120 is positioned inward from an end portion of the conductive layer 110. Note that the present invention is not limited thereto. For example, the conductive layer 120 may include a region extending beyond the end portion of the conductive layer 110. In that case, part of the conductive layer 120 may include a region not overlapping with the conductive layer 110. With such a structure, the conductive layer 110 and the conductive layer 120 can have regions overlapping with each other with the insulating layer 270 therebetween also in a region outside the conductive layer 110. Thus, the capacitance value of the capacitor 52 can be increased.

A material that can have ferroelectricity is used for the insulating layer 270. In this case, the capacitor 52 functions as a ferroelectric capacitor.

In FIG. 20A and FIG. 20B, the insulating layer 270 is provided in a planar shape. Such a structure can eliminate the process for processing the insulating layer 270, thereby reducing the manufacturing cost of the semiconductor device. Note that as illustrated in FIG. 10B and FIG. 10C, the insulating layer 270 may be divided in the X direction and the Y direction. Such a structure can increase the reliability of the semiconductor device 50.

The transistor 53 has a structure similar to the above-described structure of the transistor 32. For the structure of the transistor 53, <Structure example of semiconductor device 30> described above can be referred to.

The semiconductor device 50 may include the transistor 32a illustrated in FIG. 18A and FIG. 18B instead of the transistor 53. As described above, the area occupied by the transistor 32a can be smaller than that occupied by the transistor 42. Accordingly, high integration of the semiconductor device 50 can be achieved.

FIG. 20C is an equivalent circuit diagram of the semiconductor device 50. In FIG. 20C, one of a source and a drain of the transistor 51 is electrically connected to a wiring SL, and the other of the source and the drain of the transistor 51 is electrically connected to a wiring BL. A gate of the transistor 51, one of a pair of the electrodes of the capacitor 52, and one of a source and a drain of the transistor 53 are electrically connected to a node FN. The other of the pair of electrodes of the capacitor 41 is electrically connected to a wiring WL. The other of the source and the drain of the transistor 53 is electrically connected to a wiring WBL, and a gate of the transistor 53 is electrically connected to a wiring WWL. The semiconductor device 50 functions as a memory circuit. Note that FIG. 20C is an equivalent circuit diagram of the case where the capacitor 52 includes a ferroelectric.

The conductive layer 220 functions as at least part of the wiring SL. The conductive layer 240a functions as at least part of the wiring BL. Note that the wiring SL and the wiring BL can be interchanged with each other. The conductive layer 220 may function as at least part of the wiring BL, and the conductive layer 240a may function as at least part of the wiring SL.

The conductive layer 110 functions as at least part of the wiring WL. The conductive layer 240b functions as at least part of the wiring WBL, and the conductive layer 260b functions as at least part of the wiring WWL.

The semiconductor device 50 illustrated in the equivalent circuit diagram of FIG. 20C is “2Tr1FE” memory cell including two transistors and one ferroelectric capacitor. In the circuit structure illustrated in FIG. 20C, a potential can be supplied from the wiring WBL to the node FN through the transistor 53; thus, the operation voltage of the semiconductor device 50 required for data writing can be reduced.

This embodiment can be combined with any of the other embodiments as appropriate. In this specification, in the case where a plurality of structure examples are described in one embodiment, the structure examples can be combined as appropriate.

### Embodiment 2

In this embodiment, an oxide semiconductor that can be used in the OS transistor described in the above embodiment will be described.

As a metal oxide used in the OS transistor, the metal oxide described in the above embodiment can be used. Hereinafter, an In—Ga—Zn oxide is described as an example of the metal oxide

### <Classification of Crystal Structure>

Examples of crystal structures of an oxide semiconductor include amorphous (including completely amorphous), CAAC (c-axis-aligned crystalline), nc (nanocrystalline), CAC (cloud-aligned composite), single crystal, and polycrystalline structures.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

The crystal structure of a film or a substrate can be evaluated with a diffraction pattern observed by a nanobeam electron diffraction (NBED) method (such a pattern is also referred to as a nanobeam electron diffraction pattern). For example, a halo pattern is observed in the diffraction pattern of a quartz glass substrate, which indicates that quartz glass is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### [Structure of Oxide Semiconductor]

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

In the case of In—Ga—Zn oxide, the CAAC-OS tends to have a layered crystal structure (also referred to as a layered structure) in which a layer including indium (In) and oxygen (hereinafter, an In layer) and a layer including gallium (Ga), zinc (Zn), and oxygen (hereinafter, a (Ga,Zn) layer) are stacked. Note that indium and gallium can be replaced with each other. Therefore, indium may be included in the (Ga,Zn) layer. In addition, gallium may be included in the In layer. Note that zinc may be included in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably included to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be reduced by entry of impurities, formation of defects, or the like, the CAAC-OS can also be regarded as an oxide semiconductor that has small amounts of impurities and defects (e.g., oxygen vacancies). Thus, the physical properties of an oxide semiconductor including the CAAC-OS are stable. Therefore, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### [Structure of Oxide Semiconductor]

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region including indium oxide, indium zinc oxide, or the like as its main component. The second region is a region including gallium oxide, gallium zinc oxide, or the like as its main component. That is, the first region can be rephrased as a region including In as its main component. The second region can be rephrased as a region including Ga as its main component.

Note that a clear boundary between the first region and the second region cannot be observed in some cases.

In addition, in a material composition of a CAC-OS in In—Ga—Zn oxide that includes In, Ga, Zn, and O, there are regions including Ga as a main component in part of the CAC-OS and regions including In as a main component in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated intentionally, for example. In addition, in the case of forming the CAC-OS by a sputtering method, one or more selected from an inert gas (typically, argon), an oxygen gas, and a nitrogen gas are used as a film formation gas. The proportion of the flow rate of an oxygen gas in the total flow rate of the film formation gas during film formation is preferably as low as possible. For example, the proportion of the flow rate of an oxygen gas in the total flow rate of the film formation gas during film formation is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region including In as its main component (the first region) and the region including Ga as its main component (the second region) are unevenly distributed and mixed.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, a leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (u), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Impurity>

Here, the influence of each impurity in the oxide semiconductor is described.

When silicon or carbon, which is one of Group 14 elements, is contained in the oxide semiconductor, defect states are formed in the oxide semiconductor. Therefore, in the case where the oxide semiconductor is used for a semiconductor layer of a normally-off transistor, the concentration of silicon or carbon in the oxide semiconductor (the concentration obtained by secondary ion mass spectrometry (SIMS)) is lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a normally-on transistor is easily obtained with the use of the oxide semiconductor containing an alkali metal or an alkaline earth metal. Meanwhile, when the oxide semiconductor is used for a semiconductor layer of a normally-off transistor, the concentration of an alkali metal or an alkaline earth metal in the oxide semiconductor, which is obtained by SIMS, is lower than or equal to 1× 10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, when an oxide semiconductor containing nitrogen is used for a semiconductor, a normally-on transistor is easily obtained. Meanwhile, when the oxide semiconductor is used for a semiconductor layer of a normally-off transistor, the concentration of nitrogen in the oxide semiconductor, which is obtained by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Accordingly, when an oxide semiconductor containing hydrogen is used, a normally-on transistor is easily obtained. Meanwhile, when the oxide semiconductor is used for a semiconductor layer of a normally-off transistor, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, the transistor can have stable electrical characteristics.

### <Transistor Including Metal Oxide>

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor having a low carrier concentration is preferably used for a channel formation region of a transistor. For example, the carrier concentration of an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, further preferably lower than or equal to 1×10¹³ cm⁻³, further preferably lower than or equal to 1×10¹¹ cm⁻³, further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film preferably is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a wider band gap than silicon, the off-state current (also referred to as Ioff) of the transistor can be reduced.

In a Si transistor, a short-channel effect (also referred to as SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus, can have an inhibited short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value refers to the amount of change in a gate voltage which makes the drain current change by one digit in a subthreshold region at a constant drain voltage.

The characteristic length is widely used as an indicator of resistance to a short-channel effect. The characteristic length is an indicator of curving of a potential in a channel formation region. The smaller the characteristic length is, the more sharply the potential rises; thus, a smaller characteristic length indicates higher resistance to a short-channel effect.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above structure enables favorable electrical characteristics even when the OS transistor is miniaturized or highly integrated. For example, the semiconductor device can have favorable electrical characteristics even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

A miniaturized OS transistor can have improved high frequency characteristics. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

This embodiment can be combined as appropriate with any of the other embodiments and the like described in this specification.

### Embodiment 3

In this embodiment, a semiconductor device 900 of one embodiment of the present invention will be described in this embodiment. The semiconductor device 900 can function as a memory device.

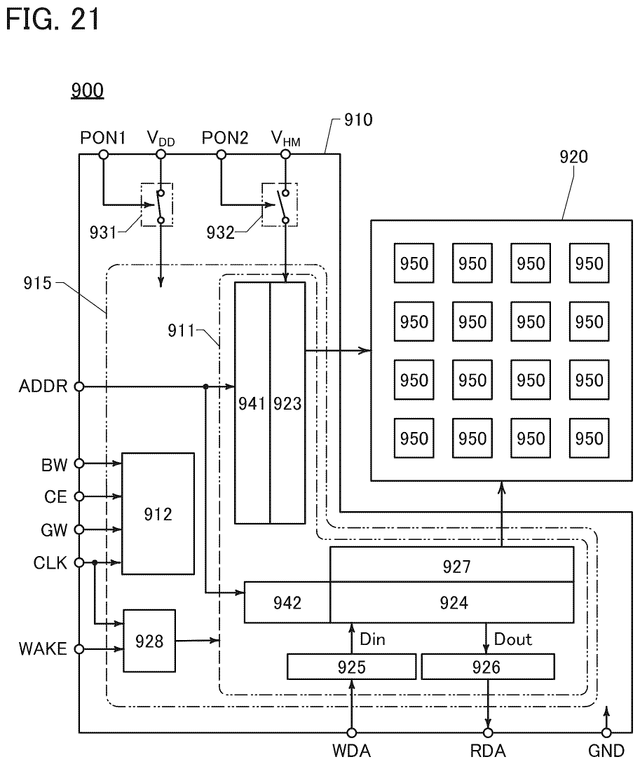

FIG. 21 is a block diagram illustrating a structure example of the semiconductor device 900. The semiconductor device 900 illustrated in FIG. 21 includes a driver circuit 910 and a memory array 920. The memory array 920 includes one or more memory cells 950. FIG. 21 illustrates an example in which the memory array 920 includes a plurality of memory cells 950 arranged in a matrix.

The semiconductor device (the semiconductor device 10, the semiconductor device 20, the semiconductor device 20A, the semiconductor device 20B, the semiconductor device 20C, the semiconductor device 20D, the semiconductor device 20E, the semiconductor device 20F, the semiconductor device 30, the semiconductor device 30A, the semiconductor device 40, or the semiconductor device 50) described as examples in the above embodiment can be used in the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for performing writing and reading of data to/from the memory cells 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cells 950, a function of reading data from the memory cells 950, a function of retaining the read data, and the like.

The input circuit 925 has a function of retaining the signal WDA. Data retained by the input circuit 925 is output to the column driver 924. Data output from the input circuit 925 is data (Din) to be written to the memory cells 950. Data (Dout) read from the memory cells 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling supply of VDD to the peripheral circuit 915. The PSW 932 has a function of controlling supply of VHM to the row driver 923. Here, in the semiconductor device 900, a high power supply potential is VDD and a low power supply potential is GND (a ground potential). In addition, VHM is a high power supply potential used to set a word line at a high level and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 21 but can be more than one. In that case, a power switch is provided for each power domain.

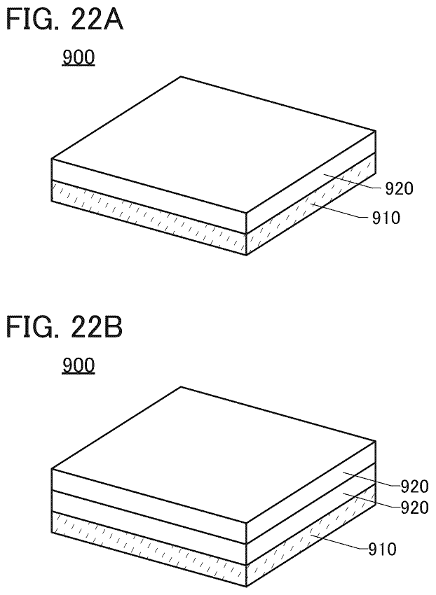

The driver circuit 910 and the memory array 920 that are included in the semiconductor device 900 may be provided on the same plane. As illustrated in FIG. 22A, the driver circuit 910 and the memory array 920 may be provided to overlap with each other. When the driver circuit 910 and the memory array 920 are provided to overlap with each other, the signal transmission distance can be shortened. Alternatively, a plurality of memory arrays 920 may be provided over the driver circuit 910 as illustrated in FIG. 22B.

When an OS transistor is used as the transistor included in the memory array 920, the transistor can be formed in a BEOL (Back end of line) process for forming a wiring of the semiconductor device 900. In the case where a Si transistor is used for the driver circuit 910 provided below the memory array 920, application of BEOL-Tr technology (technology for forming an OS transistor directly above a Si transistor) enables the semiconductor device 900 to be miniaturized.

Next, an example of an arithmetic processing device that can include the semiconductor device such as the above-described memory device will be described.

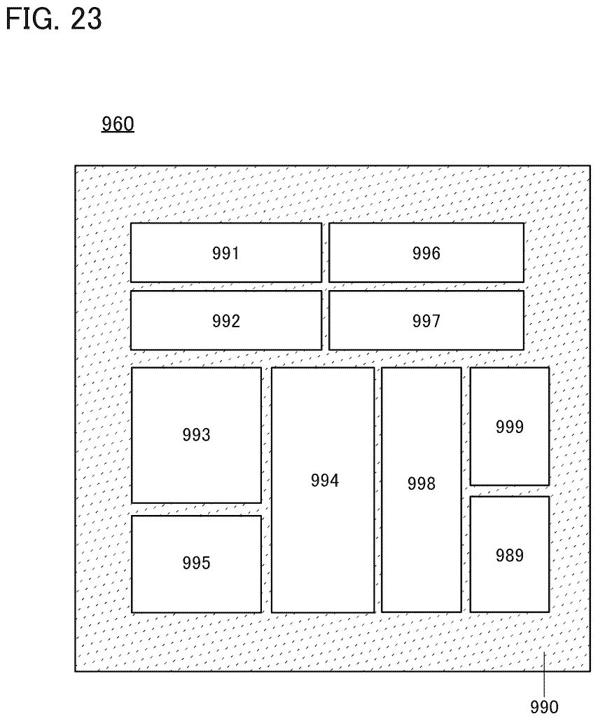

FIG. 23 is a block diagram of an arithmetic device 960. The arithmetic device 960 illustrated in FIG. 23 can be used for a CPU (Central Processing Unit), for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or a NPU (Neural Processing Unit).

The arithmetic device 960 illustrated in FIG. 23 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device may include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic device 960 illustrated in FIG. 23 is just an example with a simplified structure, and the actual arithmetic device 960 has a variety of structures depending on the application. For example, what is called a multicore structure is preferably employed in which a plurality of cores each including the arithmetic device 960 in FIG. 23 operate in parallel. The larger number of cores can further enhance the arithmetic performance. The number of cores is preferably larger; for example, the number is preferably 2, further preferably 4, still further preferably 8, still further preferably 12, yet still further preferably 16 or more. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction that is input to the arithmetic device 960 through the bus interface 998 is input to the instruction decoder 993 and decoded therein, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges and processes an interrupt request from an external input/output device, a peripheral circuit, or the like on the basis of its priority, a mask state, or the like. The register controller 997 generates an address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 illustrated in FIG. 23, the register controller 997 selects a retention operation in the register 996 in accordance with an instruction from the ALU 991. That is, the register controller 997 selects whether data is retained by a flip-flop or by a capacitor in a memory cell included in the register 996. When data retention by the flip-flop is selected, a power supply potential is supplied to the memory cell in the register 996. When data retention by the capacitor is selected, the data is rewritten into the capacitor, and supply of the power supply potential to the memory cell in the register 996 can be stopped.

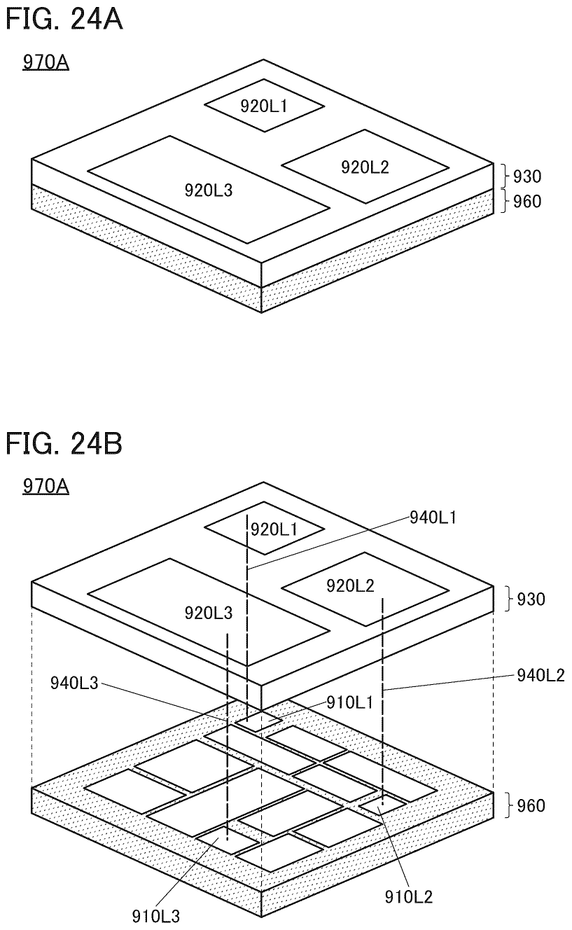

The memory array 920 and the arithmetic device 960 can be provided to overlap with each other. FIG. 24A and FIG. 24B are perspective views of a semiconductor device 970A.

The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 24B.

Providing the layer 930 including the memory arrays and the arithmetic device 960 to overlap with each other can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory array 920L1, the memory array 920L2, and the memory array 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 24B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 included in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

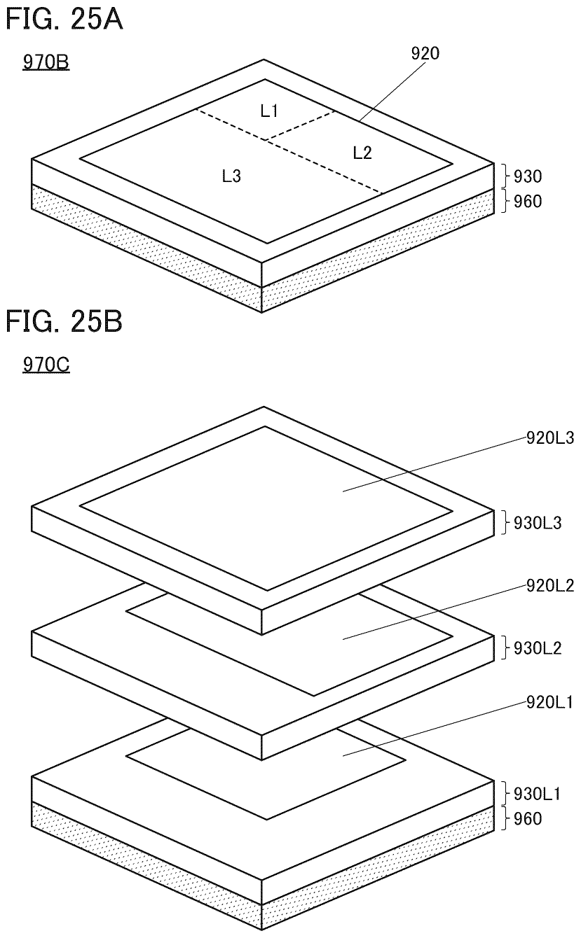

The layer 930 including one memory array 920 may be provided to overlap with the arithmetic device 960. FIG. 25A is a perspective view of a semiconductor device 970B.

In the semiconductor device 970B, one memory array 920 can be divided into a plurality of areas having different functions. FIG. 25A illustrates an example in which a region L1 is used as the L1 cache, a region L2 is used as the L2 cache, and a region L3 is used as the L3 cache.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 25B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined as appropriate with any of the other embodiments in this specification.

### Embodiment 4

In this embodiment, application examples of the memory device of one embodiment of the present invention will be described.

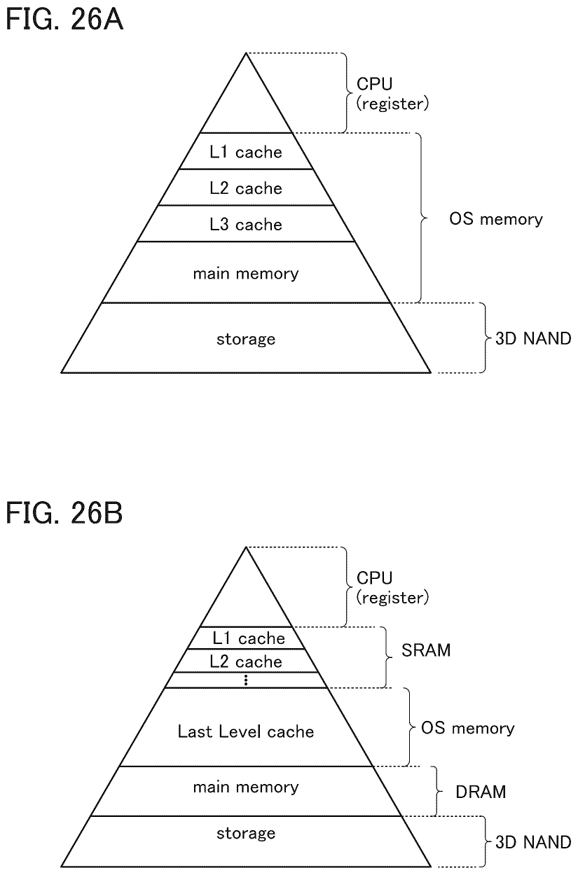

In general, a variety of memory devices are used in semiconductor devices such as computers in accordance with the intended use. FIG. 26A shows the hierarchy of various memory devices used in a semiconductor device. The memory devices at the upper levels require a higher operating speed, whereas the memory devices at the lower levels require a larger storage capacity and a higher storage density. FIG. 26A shows, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing unit such as a CPU is used for temporary storage of arithmetic operation results, for example, and thus is frequently accessed by the arithmetic processing unit. Accordingly, high operation speed is required rather than storage capacity. In addition, the register also has a function of retaining settings information of the arithmetic processing unit, for example.

The cache has a function of duplicating and retaining part of data retained in a main memory. Duplicating frequently used data and retaining the duplicated data in the cache facilitates rapid data access. The cache requires a smaller storage capacity than the main memory but requires higher operation speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and programs used in an arithmetic processing device, for example. Therefore, the storage needs to have high memory capacity and high storage density rather than operation speed. For example, a high-capacity nonvolatile memory device such as a 3D NAND can be used.

The memory device including an oxide semiconductor (OS memory) of one embodiment of the present invention operates high speed and can retain data for a long time. Thus, as illustrated in FIG. 26A, the memory device of one embodiment of the present invention can be suitably used for devices at both the level including the cache and the level including the main memory. The memory device of one embodiment of the present invention can be favorably used at the level including the storage.

FIG. 26B illustrates an example in which an SRAM is used as one of the caches and the OS memory of one embodiment of the present invention is used as the other cache.

The lowest-level cache can be referred to as an LLC (Last Level Cache). The LLC does not require higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as an FLC (Final Level Cache).

For example, as illustrated in FIG. 26B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 26B.

Note that this embodiment can be combined as appropriate with any of the other embodiments in this specification.

### Embodiment 5

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

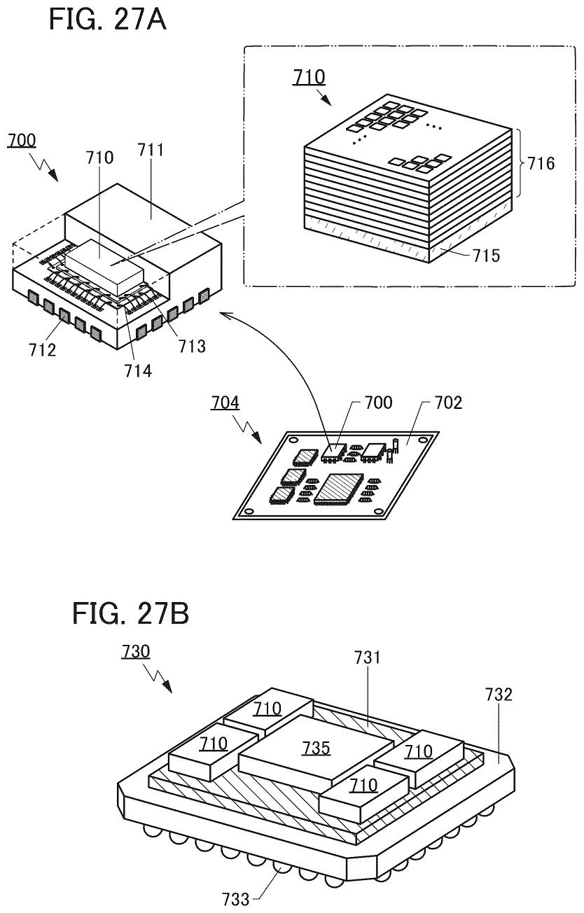

FIG. 27A is a perspective view of a substrate (a circuit board 704) on which an electronic component 700 is mounted. The electronic component 700 illustrated in FIG. 27A includes a semiconductor device 710 in a mold 711. Some components are omitted in FIG. 27A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 27B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 27B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

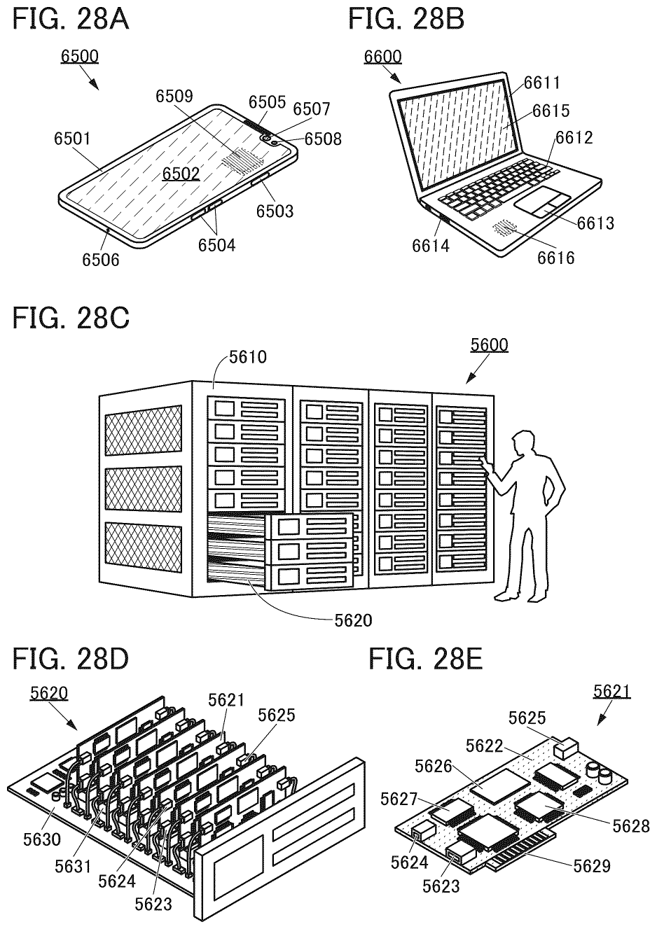

Next, a perspective view of an electronic device 6500 is illustrated in FIG. 28A. An electronic device 6500 illustrated in FIG. 28A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like, for example.

An electronic device 6600 illustrated in FIG. 28B is an information terminal that can be used as a laptop computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 28C is a perspective view of a large computer 5600. In the large computer 5600 illustrated in FIG. 28C, a plurality of rack mount computers 5620 are stored in a rack 5610. Note that the large computer 5600 may be referred to as a supercomputer.

The computer 5620 can have a structure illustrated in a perspective view of FIG. 28D, for example. In FIG. 28D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 28E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 28E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

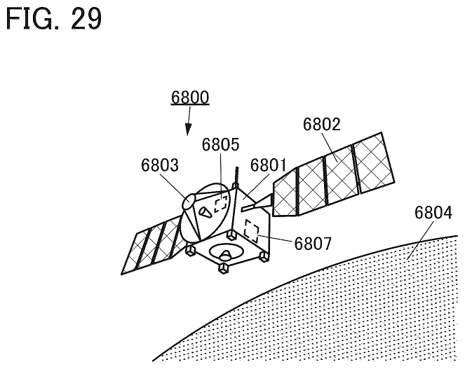

FIG. 29 illustrates an artificial satellite 6800 as an example of a device for space. The artificial satellite 6800 includes a body 6801, a solar panel 6802, an antenna 6803, a secondary battery 6805, and a control device 6807. In FIG. 29, a planet 6804 in outer space is illustrated as an example. Note that outer space refers to, for example, space at an altitude greater than or equal to 100 km, and outer space in this specification can include thermosphere, mesosphere, and stratosphere.

Although not illustrated in FIG. 29, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for a device for space, such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The long-term management of data needs an increase in building size for, for example, setting a storage and a server for storing an enormous amount of data, ensuring stable power supply for data retention, and ensuring cooling equipment for data retention.

With use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

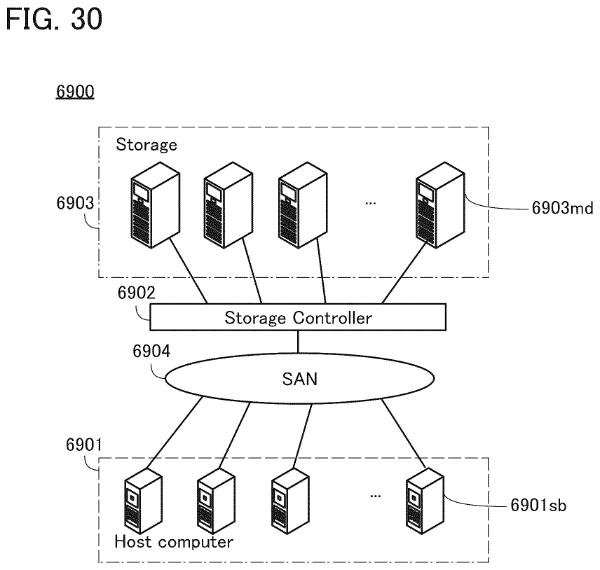

FIG. 30 illustrates a storage system applicable to a data center. A storage system 6900 illustrated in FIG. 30 includes a plurality of servers 6901sb as a host 6901 (indicated as “Host Computer” in the diagram). The storage system 6900 includes a plurality of memory devices 6903md as a storage 6903 (indicated as “Storage” in the diagram). In the illustrated mode, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer that accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage 6903. In the storage system, in order to solve the problem of low access speed of the storage 6903, a cache memory is normally provided in the storage to shorten the time required for data storage and output.

The above-described cache memory is used in the storage control circuit 6902 and the storage 6903. Data transmitted between the host 6901 and the storage 6903 is stored in the cache memory in the storage control circuit 6902 and the storage 6903 and then output to the host 6901 or the storage 6903

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. The semiconductor device of one embodiment of the present invention can be effectively used as one of the global warming countermeasures because of its low power consumption.

This embodiment can be implemented in an appropriate combination with the structures described in the other embodiments.

### Example

In this example, measurement results of polarization (P)-voltage (V) characteristics, rewrite endurance, and I-V characteristics of samples each including an insulator formed using a material that can have ferroelectricity will be described. The analysis results of the compositions of the samples including the insulators will also be described.

### [Sample Fabrication 1]

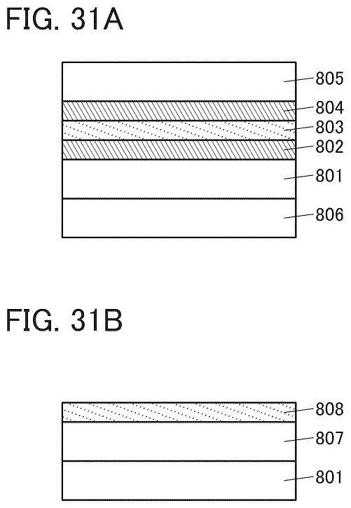

First, seven samples (Sample 800, Sample 810A to Sample 810C, and Sample 820A to Sample 820C) were fabricated. FIG. 31A is a cross-sectional view of each sample. As illustrated in FIG. 31A, each sample includes a layer 801, a layer 802 over the layer 801, a layer 803 over the layer 802, a layer 804 over the layer 803, and a layer 805 over the layer 804. Each sample also includes a layer 806 under the layer 805.

Methods for fabricating the seven samples are described below. Note that the seven samples have the same structure except for the material used to form the layer 803.

First, a silicon substrate was prepared as the layer 801.

Next, as the layer 802, a 30-nm-thick titanium nitride film was deposited by a reactive sputtering method using a titanium target and a nitrogen (N₂) gas. In the deposition of the titanium nitride film, a nitrogen (N₂) gas at a flow rate of 50 sccm was used as a deposition gas, the pressure was 0.2 Pa, the substrate temperature was room temperature, and the direct current (DC) power was 4 kW.

Next, as the layer 803, a 10-nm-thick metal oxide film was deposited by an ALD method. A hafnium zirconium oxide film was deposited as the layer 803 in Sample 800; a hafnium zirconium oxide film to which lanthanum was added was deposited as the layer 803 in Sample 810A to Sample 810C. In Sample 820A to Sample 820C, a hafnium zirconium oxide film to which yttrium was added was deposited as the layer 803.

For all the seven samples, tetrakis(ethylmethylamide) hafnium (TEMAHf) was used as a precursor containing hafnium, tetrakis(ethylmethylamide) zirconium (TEMAZr) was used as a precursor containing zirconium, and ozone (O₃) was used as an oxidizer. The deposition temperature was 250° C. A lanthanum organometallic compound was used as a precursor containing lanthanum for all of Sample 810A to Sample 810C. An yttrium organometallic compound was used as a precursor containing yttrium for all of Sample 820A to Sample 820C.

As one cycle of the thermal ALD for the hafnium zirconium oxide (referred to as HfZrOx cycle), a precursor containing hafnium was introduced for 0.5 seconds, purging was performed for 6 seconds, ozone was introduced for 4 seconds, purging was performed for 3 seconds, a precursor containing zirconium was introduced for 0.5 seconds, purging was performed for 6 seconds, ozone was introduced for 4 seconds, and purging was performed for 3 seconds. As one cycle of the thermal ALD for the lanthanum oxide (referred to as LaOx cycle), a precursor containing lanthanum was introduced for 6 seconds, purging was performed for 6 seconds, ozone was introduced for 1 second, and purging was performed for 3 seconds. As one cycle of the thermal ALD for the yttrium oxide (referred to as YOx cycle), a precursor containing yttrium was introduced for 2 seconds, purging was performed for 6 seconds, ozone was introduced for 1 second, and purging was performed for 3 seconds.

For Sample 800, the HfZrOx cycle was repeated until a desired thickness was reached. For Sample 810A, treatment in which the HfZrOx cycle was performed 16 times and then the LaOx cycle was performed once was repeated until a desired thickness was reached. For Sample 810B, treatment in which the HfZrOx cycle was performed 8 times and then the LaOx cycle was performed once was repeated until a desired thickness was reached. For Sample 810C, treatment in which the HfZrOx cycle was performed 4 times and then the LaOx cycle was performed once was repeated until a desired thickness was reached. For Sample 820A, treatment in which the HfZrOx cycle was performed 24 times and then the YOx cycle was performed once was repeated until a desired thickness was reached. For Sample 820B, treatment in which the HfZrOx cycle was performed 16 times and then the YOx cycle was performed once was repeated until a desired thickness was reached. For Sample 820C, treatment in which the HfZrOx cycle was performed 12 times and then the YOx cycle was performed once was repeated until a desired thickness was obtained.

Next, as the layer 804, a 30-nm-thick titanium nitride film was deposited by a reactive sputtering method using a titanium target and a nitrogen (N₂) gas. The deposition conditions for the layer 804 were the same as those for the layer 802.

After the layer 804 was formed, heat treatment was performed at 450° C. for 60 seconds with an RTA (Rapid Thermal Anneal) apparatus. The heat treatment was performed in a nitrogen atmosphere.

Next, as the layer 805, a 200-nm-thick aluminum film was deposited by a sputtering method. Then, as the layer 806, a 400-nm-thick aluminum film was deposited by a sputtering method.

As described above, the seven samples (Sample 800, Sample 810A to Sample 810C, and Sample 820A to Sample 820C) were fabricated.

### <P-V Characteristics and Rewrite Endurance>

A triangular wave was applied between the layer 806 and the layer 805 in each of the seven samples (Sample 800, Sample 810A to Sample 810C, and Sample 820A to Sample 820C), and a change in spontaneous polarization (P-V characteristics) of the layer 804 was measured. The applied triangular wave had a frequency of 1 kHz and a voltage ranging from −2.5 V to +2.5 V.

As to the rewrite endurance, assuming application of a trapezoidal wave for one period to be one cycle, the trapezoidal wave was repeatedly applied until the number of cycles reached a predetermined number; the P-V characteristics were measured after every predetermined number of cycles; and the minimum polarization and the maximum polarization at a voltage of 0 V were obtained. The trapezoidal wave to be applied had a frequency of 100 kHz and a voltage of +2.5 V. The upper limit of the number of cycles was 1×10¹⁰. The difference between the minimum polarization and the maximum polarization at a voltage of 0 V after a certain number of cycles is referred to as 2Pr.

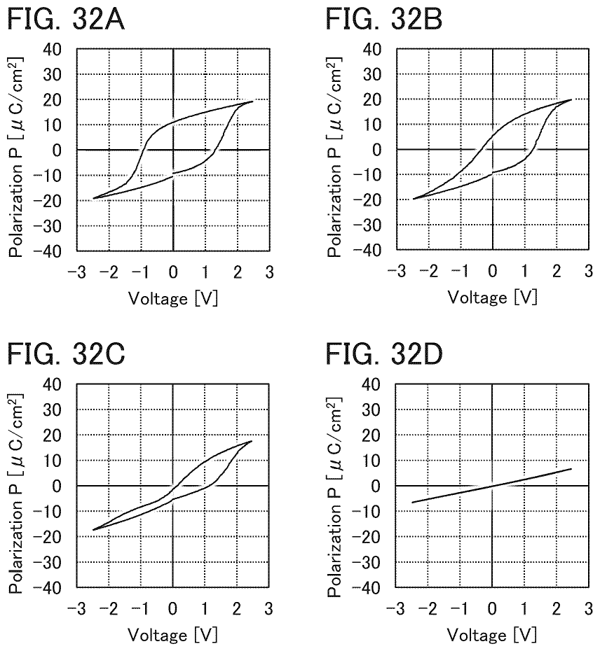

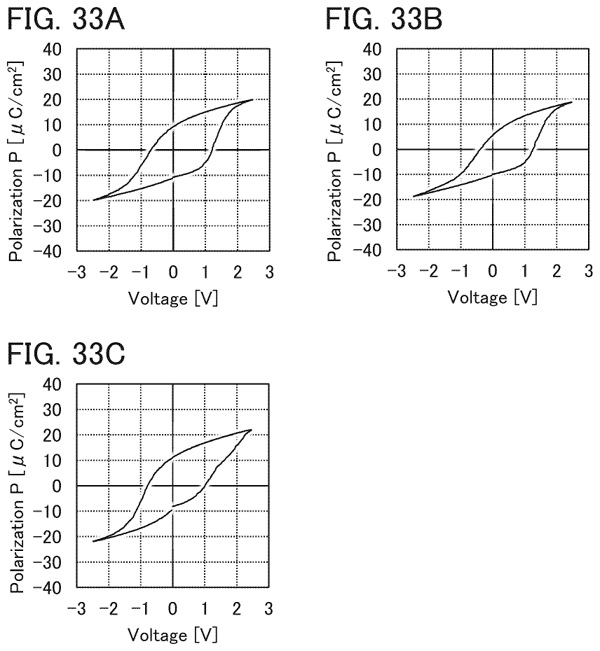

FIG. 32A to FIG. 32D and FIG. 33A to FIG. 33C show the measurement results of the P-V characteristics of the seven samples. FIG. 32A to FIG. 32D and FIG. 33A to FIG. 33C show the results of the P-V characteristics measured when the number of cycles reached 1×10⁴. In FIG. 32A to FIG. 32D and FIG. 33A to FIG. 33C, the vertical axis represents the polarization P [μC/cm²] and the horizontal axis represents the voltage [V]. FIG. 32A shows the results of Sample 800, FIG. 32B shows the results of Sample 810A, FIG. 32C shows the results of Sample 810B, and FIG. 32D shows the results of Sample 810C. FIG. 33A shows the results of Sample 820A, FIG. 33B shows the results of Sample 820B, and FIG. 33C shows the results of Sample 820C.

According to FIG. 32A to FIG. 32D, Sample 800 and Sample 810A exhibited hysteresis characteristics. Meanwhile, Sample 810B exhibited no clear hysteresis characteristics, and Sample 810C exhibited no hysteresis characteristics. Specifically, 2Pr at the time when the number of cycles reached 1×10⁴ was 20.2 μC/cm₂ in Sample 800, 14.6 μC/cm² in Sample 810A, and 2.5 μC/cm² in Sample 810B.

According to FIG. 33A to FIG. 33C, Sample 820A to Sample 820C exhibited hysteresis characteristics. Specifically, 2Pr at the time when the number of cycles reached 1×10⁴ was 22.7 μC/cm² in Sample 820A, 18.4 μC/cm² in Sample 820B, and 22.1 μC/cm² in Sample 820C.

The above results demonstrate that the hafnium zirconium oxide to which lanthanum was added and the hafnium zirconium oxide to which yttrium was added can have ferroelectricity. The above results also demonstrate that there is a preferred range of the amount of lanthanum added to the hafnium zirconium oxide.

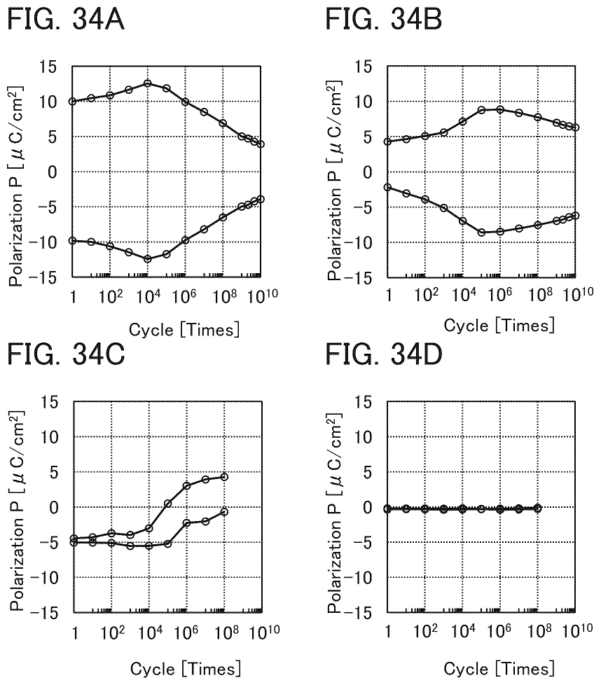

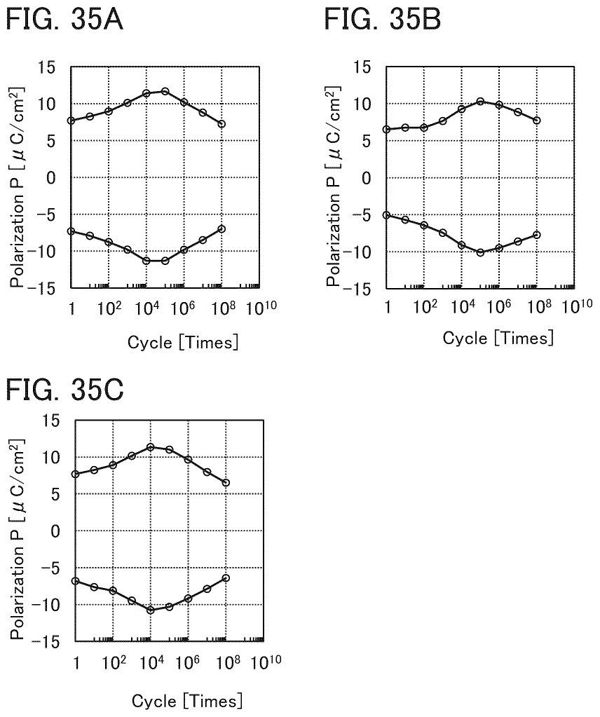

FIG. 34A to FIG. 34D and FIG. 35A to FIG. 35C show the results of the rewrite endurance of the seven samples. Note that in FIG. 34A to FIG. 34D and FIG. 35A to FIG. 35C, the vertical axis represents polarization P [μC/cm²] at a voltage of 0 V, and the horizontal axis represents the number of cycles (Cycle) [times]. FIG. 34A shows the results of Sample 800, FIG. 34B shows the results of Sample 810A, FIG. 34C shows the results of Sample 810B, and FIG. 34D shows the results of Sample 810C. FIG. 35A shows the results of Sample 820A, FIG. 35B shows the results of Sample 820B, and FIG. 35C shows the results of Sample 820C. FIG. 35A to FIG. 35C show the results up to and including 1×10⁸ cycles.

According to FIG. 34A to FIG. 34D, dielectric breakdown did not occur in each of Sample 800 and Sample 810A until the number of cycles reached 1×10¹⁰. Note that 2Pr at the time when the number of cycles reached 1×10¹⁰ was larger in Sample 810A than in Sample 800. In other words, it was found that addition of lanthanum can increase 2Pr at the time of 1×10¹⁰ cycles. It was also found that there is a preferred range of the amount of lanthanum added to the hafnium zirconium oxide.

According to FIG. 34A and FIG. 34B, wakeup and fatigue were observed in Sample 800 and Sample 810A. Note that wakeup refers to a stage in which the amount of polarization charge increases or 2Pr increases, and fatigue refers to a stage in which the amount of polarization charge decreases or 2Pr decreases. The change from wakeup to fatigue of Sample 800 was observed at around 1×10⁴ cycles and that of Sample 810A was observed at around 1×10⁵ cycles. Based on 2Pr at the number of cycles at which the change from wakeup to fatigue was observed, 2Pr at the time when the number of cycles reached 1×10¹⁰ of Sample 800 was approximately 31% and that of Sample 810A was approximately 72%. Thus, fatigue was suppressed more in Sample 810A than in Sample 800. Therefore, it was found that addition of lanthanum to the hafnium zirconium oxide inhibits fatigue.

According to FIG. 35A to FIG. 35C, dielectric breakdown did not occur in each of Sample 820A to Sample 820C until the number of cycles reached 1×10⁸.

### <I-V Characteristics>

The I-V characteristics of the seven samples (Sample 800, Sample 810A to Sample 810C, and Sample 820A to Sample 820C) were measured. This example assumes that the layer 803 is broken when current higher than or equal to 1.0×10⁻⁶ A flows and the volage at this time is dielectric breakdown voltage.

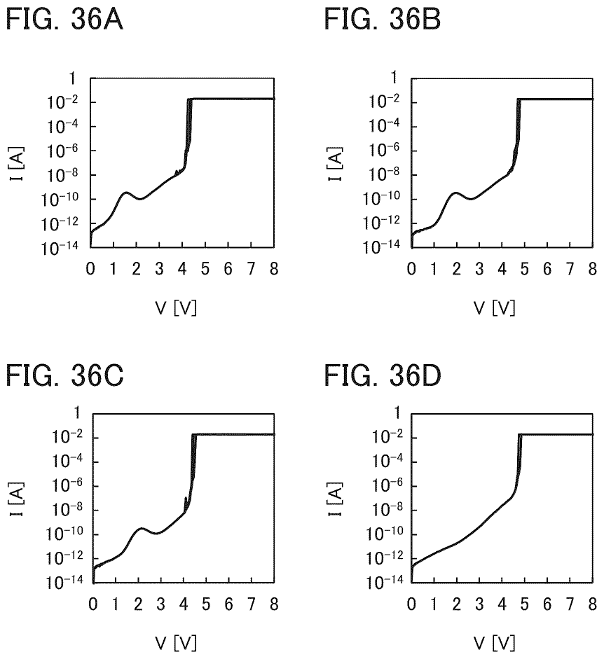

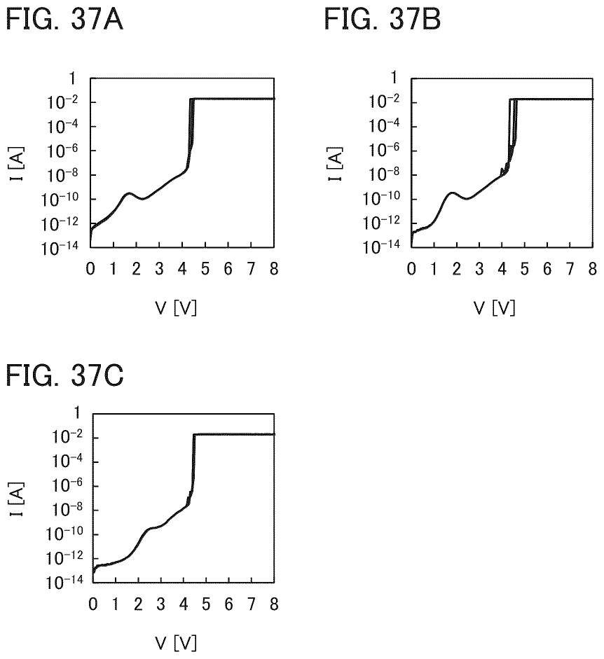

FIG. 36A to FIG. 36D and FIG. 37A to FIG. 37C show the measurement results of the I-V characteristics of the seven samples. In FIG. 36A to FIG. 36D and FIG. 37A to FIG. 37C, the vertical axis represents the current I [A] and the horizontal axis represents the voltage V [V]. FIG. 36A shows the results of Sample 800, FIG. 36B shows the results of Sample 810A, FIG. 36C shows the results of Sample 810B, and FIG. 36D shows the results of Sample 810C. FIG. 37A shows the results of Sample 820A, FIG. 37B shows the results of Sample 820B, and FIG. 37C shows the results of Sample 820C.

According to FIG. 36A to FIG. 36D, the dielectric breakdown voltage was 4.3 V in Sample 800, 4.7 V in Sample 810A, 4.5 V in Sample 810B, and 4.8 V in Sample 810C. In other words, it was found that addition of lanthanum to the hafnium zirconium oxide increases the dielectric breakdown voltage and enables high breakdown voltage.

According to FIG. 37A to FIG. 37C, the dielectric breakdown voltage was 4.3 V in Sample 820A, 4.3 V in Sample 820B, and 4.4 V in Sample 820C.

### [Sample Fabrication 2]

Next, three samples (Sample 830A to Sample 830C) were fabricated. FIG. 31A can be referred to for the cross-sectional view of each sample. The layer 801, the layer 805, and the layer 806 included in Sample 830A to Sample 830C have the same structures as those included in Sample 800. Differences from Sample 800 are mainly described below, and the description of the same portion is omitted in some cases.

As the layer 802 and the layer 804 of Sample 830A, a 30-nm-thick titanium nitride film was deposited. The deposition conditions for the layer 802 and the layer 804 of Sample 830A were the same as those for the layer 802 of Sample 800.

Next, as the layer 802 and the layer 804 of Sample 830B, a 30-nm-thick tantalum nitride film was deposited by a reactive sputtering method using a tantalum target and a nitrogen (N₂) gas. In the deposition of the tantalum nitride film, a mixed gas of an argon gas at a flow rate of 50 sccm and a nitrogen (N₂) gas at a flow rate of 10 sccm was used as a deposition gas, the pressure was 0.6 Pa, the substrate temperature was room temperature, and the DC power was 1 kW.

As the layer 802 and the layer 804 of Sample 830C, a 30-nm-thick tungsten film was deposited by a sputtering method. In the deposition of tungsten, a tungsten target was used, an argon gas at a flow rate of 50 sccm was used as a deposition gas, the pressure was 0.4 Pa, the substrate temperature was 130° C., and the DC power was 1 kW.

As the layer 803 of each of Sample 830A to Sample 830C, a 12-nm-thick hafnium zirconium oxide film was deposited by an ALD method. The deposition conditions for the layer 803 of Sample 830A to Sample 830C were the same as those for the layer 803 of Sample 800.

The conditions for heat treatment performed after the formation of the layer 804 were the same as those for Sample 800.

As described above, Sample 830A to Sample 830C were fabricated.

### <P-V Characteristics and Rewrite Endurance>

Each of the three samples (Sample 830A to Sample 830C) were subjected to measurement of a change in spontaneous polarization (P-V characteristics) of the layer 804 and evaluation of rewrite endurance. Note that the conditions for measuring the P-V characteristics were the same as the above-described conditions. In the evaluation of the rewrite endurance, the upper limit of the number of cycles was 1×10⁸. Note that the conditions other than the upper limit of the number of cycles were the same as the above-described conditions.

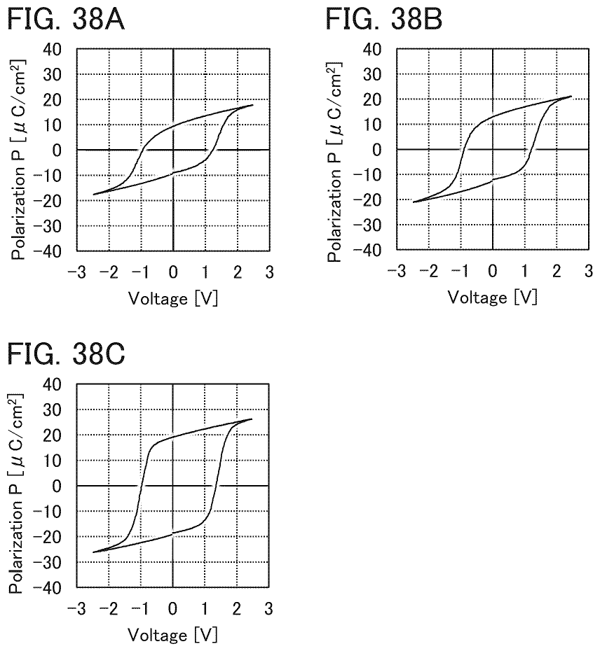

FIG. 38A to FIG. 38C show the measurement results of the P-V characteristics of the three samples. FIG. 38A to FIG. 38C show the results of the P-V characteristics measured when the number of cycles reached 1×10⁴. In FIG. 38A to FIG. 38C, the vertical axis represents the polarization P [μC/cm²] and the horizontal axis represents the voltage [V]. FIG. 38A shows the results of Sample 830A, FIG. 38B shows the results of Sample 830B, and FIG. 38C shows the results of Sample 830C.

According to FIG. 38A to FIG. 38C, Sample 830A to Sample 830C each exhibited hysteresis characteristics. In addition, differences in polarization values were observed depending on the materials used for the layer 802 and the layer 804. Specifically, 2Pr at the time when the number of cycles reached 1×10⁴ was 18.3 μC/cm² in Sample 830A, 25.0 μC/cm² in Sample 830B, and 37.6 μC/cm² in Sample 830C. It was thus found that the use of tungsten for the layer 802 and the layer 804 can increase spontaneous polarization as compared with the case where titanium nitride or tantalum nitride is used for the layer 802 and the layer 804. That is, it was suggested that the use of a conductive layer not containing nitrogen as the layer 802 and the layer 804 can increase spontaneous polarization as compared with the case where a conductive layer containing nitrogen is used as the layer 802 and the layer 804.

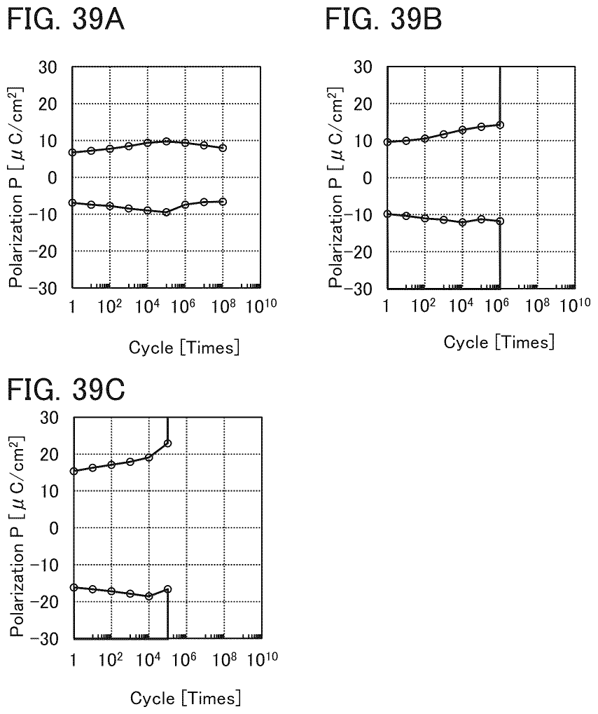

FIG. 39A to FIG. 39C show the results of the rewrite endurance of the three samples. Note that in FIG. 39A to FIG. 39C, the vertical axis represents polarization P [μC/cm²] at a voltage of 0 V, and the horizontal axis represents the number of cycles (Cycle) [times]. FIG. 39A shows the results of Sample 830A, FIG. 39B shows the results of Sample 830B, FIG. 39C shows the results of Sample 830C.

According to FIG. 39A to FIG. 39C, dielectric breakdown did not occur in Sample 830A until the number of cycles reached 1×10⁸. Meanwhile, dielectric breakdown occurred in Sample 830B when the number of cycles reached 1×10⁶, and dielectric breakdown occurred in Sample 830C when the number of cycles reached 1×10⁵. The results show that the use of a conductive layer containing nitrogen as the layer 802 and the layer 804 can improve the rewrite endurance of a semiconductor device. It was thus suggested that the use of a conductive layer containing nitrogen as a conductive layer in contact with a ferroelectric can improve the reliability of a semiconductor device. It was found that titanium nitride is particularly preferable for the conductive layer containing nitrogen.

### <I-V Characteristics>

The I-V characteristics of the three samples (Sample 830A to Sample 830C) were measured.

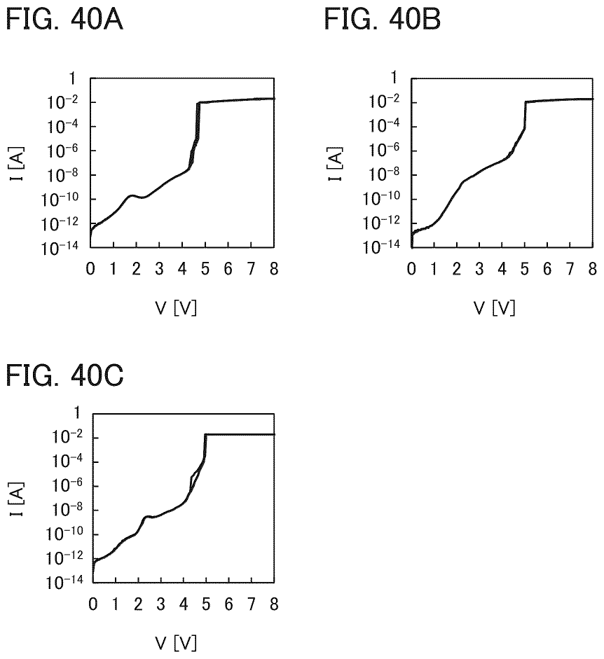

FIG. 40A to FIG. 40C show the measurement results of the I-V characteristics of the three samples. In FIG. 40A to FIG. 40C, the vertical axis represents the current I [A] and the horizontal axis represents the voltage V [V]. FIG. 40A shows the results of Sample 830A, FIG. 40B shows the results of Sample 830B, and FIG. 40C shows the results of Sample 830C.

According to FIG. 40A to FIG. 40C, the amount of leakage current at a voltage of 3 V was 0.9 nA in Sample 830A, 18.8 nA in Sample 830B, and 4.3 nA in Sample 830C. That is, the amount of leakage current at a voltage of 3 V was the smallest in Sample 830A, the second smallest in Sample 830C, and the largest in Sample 830B.

### [Sample Fabrication 3]

Next, one sample (Sample 831) was fabricated. FIG. 31A can be referred to for the cross-sectional view of Sample 831. The layer 801, the layer 805, and the layer 806 included in Sample 831 have the same structures as those included in Sample 800. Differences from Sample 800 are mainly described below, and the description of the same portion is omitted in some cases.

As the layer 802 of Sample 831, a 30-nm-thick tungsten film was deposited by a sputtering method. In the deposition of tungsten, a tungsten target was used, an argon gas at a flow rate of 100 sccm was used as a deposition gas, the pressure was 1.9 Pa, the substrate temperature was 50° C., and the DC power was 0.5 kW.

As the layer 803 of Sample 831, a 10-nm-thick hafnium zirconium oxide film to which yttrium was added was deposited by an ALD method. The deposition conditions for the layer 803 of Sample 831 were the same as those for the layer 803 of Sample 820B.

As the layer 804 of Sample 831, a 30-nm-thick titanium nitride film was deposited. The deposition conditions for the layer 804 of Sample 831 were the same as those for the layer 802 of Sample 800.

The conditions for heat treatment performed after the formation of the layer 804 of Sample 831 were the same as those for Sample 800.

As described above, Sample 831 was fabricated.

### <P-V Characteristics and Rewrite Endurance>

Sample 831 was subjected to measurement of a change in spontaneous polarization (P-V characteristics) of the layer 804 and evaluation of rewrite endurance. Note that the conditions for measuring the P-V characteristics were the same as the above-described conditions. In the evaluation of the rewrite endurance, the upper limit of the number of cycles was 1×10⁸. Note that the conditions other than the upper limit of the number of cycles were the same as the above-described conditions.

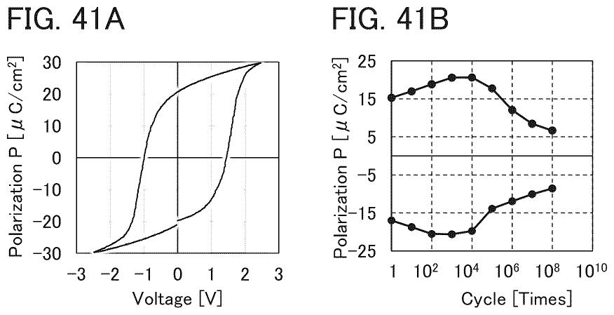

FIG. 41A shows the measurement results of the P-V characteristics of Sample 831. FIG. 41A shows the results of the P-V characteristics measured when the number of cycles reached 1×10⁴. In FIG. 41A, the vertical axis represents the polarization P [μC/cm²] and the horizontal axis represents the voltage [V].

According to FIG. 41A, Sample 831 exhibited hysteresis characteristics. In addition, 2Pr at the time when the number of cycles reached 1×10⁴ was 40.4 μC/cm². It was thus found that the use of tungsten for the layer 802 and the use of titanium nitride for the layer 804 can increase spontaneous polarization. That is, it was suggested that the use of a conductive layer containing nitrogen as one of the layer 802 and the layer 804 and the use of a conductive layer not containing nitrogen as the other of the layer 802 and the layer 804 can increase spontaneous polarization.

FIG. 41B shows the results of the rewrite endurance of Sample 831. Note that in FIG. 41B, the vertical axis represents polarization P [μC/cm²] at a voltage of 0 V, and the horizontal axis represents the number of cycles (Cycle) [times].

According to FIG. 41B, dielectric breakdown did not occur in Sample 831 until the number of cycles reached 1×10⁸. The results show that the use of a conductive layer containing nitrogen as one of the layer 802 and the layer 804 and the use of a conductive layer not containing nitrogen as the other of the layer 802 and the layer 804 can improve the rewrite endurance of a semiconductor device. It was thus suggested that the use of a conductive layer containing nitrogen as a conductive layer in contact with a ferroelectric can improve the reliability of a semiconductor device. It was found that titanium nitride is particularly preferable for the conductive layer containing nitrogen.

### [Sample Fabrication 4]

To analyze the composition of the above metal oxide films, seven samples (Sample 840, Sample 850A to Sample 850C, and Sample 860A to Sample 860C) were fabricated. FIG. 31B is a cross-sectional view of each sample. As illustrated in FIG. 31B, each sample includes the layer 801, a layer 807, and a layer 808 over the layer 807. The layer 801 has the same structure as that in Sample 800. Differences from Sample 800 are mainly described below, and the description of the same portion is omitted in some cases.

For all the seven samples, a silicon substrate prepared as the layer 801 was thermally oxidized to form a silicon oxide film with a target thickness of 100 nm on the surface of the layer 801. The silicon oxide film was used as the layer 807.

As the layer 808, a 20-nm-thick metal oxide film was deposited by an ALD method. For a method for forming the layer 808 included in Sample 840, the method for forming the layer 803 included in Sample 800 can be referred to. For methods for forming the layer 808 included in Sample 850A, the layer 808 included in Sample 850B, and the layer 808 included in Sample 850C, the methods for forming the layer 803 included in Sample 810A, the layer 803 included in Sample 810B, and the layer 803 included in Sample 810C can be referred to, respectively. For methods for forming the layer 808 included in Sample 860A, the layer 808 included in Sample 860B, and the layer 808 included in Sample 860C, the methods for forming the layer 803 included in Sample 820A, the layer 803 included in Sample 820B, and the layer 803 included in Sample 820C can be referred to, respectively.

As described above, the seven samples (Sample 840, Sample 850A to Sample 850C, and Sample 860A to Sample 860C) were fabricated.

### <XPS Analysis>

The metal oxide film included in each of the seven samples (Sample 840, Sample 850A to Sample 850C, and Sample 860A to Sample 860C) was analyzed by X-ray photoelectron spectroscopy (XPS). For the XPS analysis, Quantera II produced by PHI, Inc. was used. Monochromatic Al Kα ray (1486.6 eV) was used as an X-ray source. A detection area was set to 100 μmφ. An extraction angle was set to 90°. The detection depth is estimated to be approximately 8 nm.

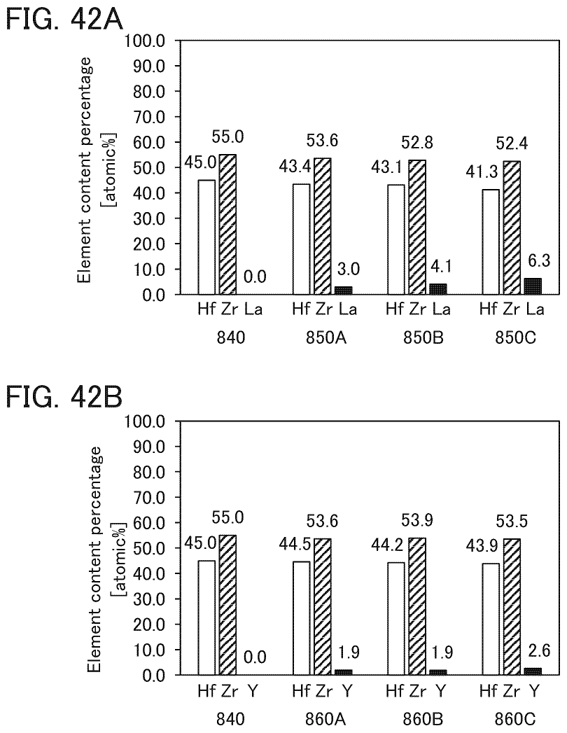

FIG. 42A and FIG. 42B show the XPS analysis results of the metal oxide film included in each of the seven samples. In FIG. 42A and FIG. 42B, the vertical axis represents the element content percentage, and the horizontal axis represents the sample name and the element. FIG. 42A shows the results of Sample 800 and Sample 850A to Sample 850C, and FIG. 42B shows the results of Sample 860A to Sample 860C. In FIG. 42A and FIG. 42B, the white bar graph represents the content percentage of hafnium, and the shaded bar graph represents the content percentage of zirconium. In FIG. 42A, the black bar graph represents the content percentage of lanthanum. In FIG. 42B, the black bar graph represents the content percentage of yttrium.

Note that in each of Sample 850A to Sample 850C, the content percentage of hafnium, the content percentage of zirconium, and the content percentage of lanthanum were calculated so that the sum of the content percentage of hafnium, the content percentage of zirconium, and the content percentage of lanthanum was 100 atomic %. In each of Sample 860A to Sample 860C, the content percentage of hafnium, the content percentage of zirconium, and the content percentage of yttrium were calculated so that the sum of the content percentage of hafnium, the content percentage of zirconium, and the content percentage of yttrium was 100 atomic %.

As shown in FIG. 42A, the content percentage of lanthanum was 3.0 atomic % in Sample 850A, 4.1 atomic % in Sample 850B, and 6.3 atomic % in Sample 850C.

As shown in FIG. 42B, the content percentage of yttrium was 1.9 atomic % in Sample 860A, 1.9 atomic % in Sample 860B, and 2.6 atomic % in Sample 860C.

The above results demonstrate that in order to increase spontaneous polarization, a conductive layer not containing nitrogen is preferably used as an electrode and that tungsten is preferably used. The above results also demonstrate that hafnium zirconium oxide to which lanthanum is added is preferably used to inhibit fatigue. Thus, it was found that in a ferroelectric capacitor, tungsten is preferably used as an electrode and hafnium zirconium to which lanthanum is added is preferably used as a dielectric.

It was found that the content percentage of lanthanum in a metal oxide film containing hafnium, zirconium, and lanthanum is preferably higher than or equal to 0.1 atomic % and 4.0 atomic %, further preferably higher than or equal to 1.0 atomic % and 4.0 atomic %. It was also found that the content percentage of yttrium in a metal oxide film containing hafnium, zirconium, and yttrium is preferably higher than or equal to 0.1 atomic % and 3.0 atomic %, further preferably higher than or equal to 1.0 atomic % and 3.0 atomic %.

Note that the constituent materials, composition, and thickness of the insulating layer 270 and the constituent materials, composition, thickness, and the like of a conductive layer in contact with the insulating layer 270 are preferably set as appropriate in accordance with the characteristics required for a semiconductor device. For example, in the case of a semiconductor device with high rewrite endurance, hafnium zirconium oxide to which lanthanum is added or hafnium zirconium oxide to which yttrium is added can be used as a ferroelectric, and titanium nitride can be used as a conductive layer in contact with the ferroelectric.

### REFERENCE NUMERALS

BL: wiring, FN: node, PL: wiring, SL: wiring, WBL: wiring, WL: wiring, WWL: wiring, 10: semiconductor device, 11: transistor, 20A: semiconductor device, 20B: semiconductor device, 20C: semiconductor device, 20D: semiconductor device, 20E: semiconductor device, 20F: semiconductor device, 20: semiconductor device, 21: transistor, 22: capacitor, 30A: semiconductor device, 30: semiconductor device, 31: transistor, 32a: transistor, 32: transistor, 40: semiconductor device, 41: capacitor, 42: transistor, 50: semiconductor device, 51: transistor, 52: capacitor, 53: transistor, 110: conductive layer, 115: conductive layer, 120: conductive layer, 141: insulating layer, 142: conductive layer, 146: conductive layer, 147: insulating layer, 180: insulating layer, 181: insulating layer, 182: insulating layer, 190: opening portion, 191: opening portion, 210: insulating layer, 212: insulating layer, 220: conductive layer, 230a: semiconductor layer, 230b: semiconductor layer, 230: semiconductor layer, 240a: conductive layer, 240b: conductive layer, 240: conductive layer, 250_1: insulating layer, 250_2: insulating layer, 250a: insulating layer, 250b: insulating layer, 250: insulating layer, 251: insulating layer, 260a: conductive layer, 260b: conductive layer, 260: conductive layer, 261: conductive layer, 265: conductive layer, 267: layer, 268: layer, 270: insulating layer, 280_1: insulating layer, 280_2: insulating layer, 280_3: insulating layer, 280a: insulating layer, 280b: insulating layer, 280: insulating layer, 281: insulating layer, 282: insulating layer, 283: insulating layer, 285: insulating layer, 290b: opening portion, 290: opening portion, 291: opening portion, 351: curve, 352: curve, 390: characteristics, 391: characteristics, 392: characteristics, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 800: sample, 801: layer, 802: layer, 803: layer, 804: layer, 805: layer, 806: layer, 807: layer, 808: layer, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial 10 satellite, 6801: body, 6802: solar panel, 6803: antenna, 6804: planet, 6805: secondary battery, 6807: control device, 6900: storage system, 6901sb: server, 6901: host, 6902: storage control circuit, 6903md: memory device, 6903: storage

1. A semiconductor device comprising:
a first conductive layer;
a first insulating layer over the first conductive layer;
a second conductive layer over the first insulating layer;
a first semiconductor layer;
a second insulating layer over the first semiconductor layer;
a third insulating layer over the second insulating layer; and
a third conductive layer over the third insulating layer,
wherein an opening portion reaching the first conductive layer is provided in the first insulating layer and the second conductive layer,
wherein at least a part of the first semiconductor layer is positioned in the opening portion,
wherein in the opening portion, the first semiconductor layer comprises a region in contact with a top surface of the first conductive layer, a region in contact with a side surface of the first insulating layer, and a region in contact with a side surface of the second conductive layer,
wherein the third insulating layer has ferroelectricity,
wherein the third insulating layer comprises hafnium, zirconium, at least one of Group 3 elements in the periodic table, and oxygen, and
wherein a content percentage of the at least one of the Group 3 elements in the periodic table in the third insulating layer is higher than or equal to 0.1 atomic % and lower than or equal to 5 atomic %.

2. The semiconductor device according to claim 1,
wherein the at least one of the Group 3 elements in the periodic table is one or both of lanthanum and yttrium.

3. The semiconductor device according to claim 1,
wherein the second insulating layer comprises aluminum and oxygen.

4. The semiconductor device according to claim 1,
wherein the third conductive layer comprises a region having a nitrogen concentration lower than or equal to 1 atomic %.

5. The semiconductor device according to claim 4,
wherein the third conductive layer comprises tungsten or ruthenium.

6. The semiconductor device according to claim 1, further comprising:
a first layer between the third insulating layer and the third conductive layer,
wherein the first layer comprises a metal included in the third conductive layer and oxygen.

7. The semiconductor device according to claim 1, further comprising a fourth conductive layer between the second insulating layer and the third insulating layer.

8. The semiconductor device according to claim 1, further comprising:
a transistor above the second insulating layer,
wherein the third conductive layer comprises a region in contact with a second semiconductor layer included in the transistor.

9. The semiconductor device according to claim 1,
wherein the first semiconductor layer comprises one or both of indium and zinc.

10. A semiconductor device comprising:
a transistor and a capacitor,
wherein the capacitor comprises a first conductive layer, a first insulating layer over the first conductive layer, and a second conductive layer over the first insulating layer,
wherein the first insulating layer has ferroelectricity,
wherein the first insulating layer comprises hafnium, zirconium, at least one of Group 3 elements in the periodic table, and oxygen,
wherein a content percentage of the at least one of the Group 3 elements in the periodic table in the first insulating layer is higher than or equal to 0.1 atomic % and lower than or equal to 5 atomic %, and
wherein the first conductive layer and the second conductive layer each comprise a region having a nitrogen concentration lower than or equal to 1 atomic %.

11. The semiconductor device according to claim 10,
wherein the second conductive layer is configured to be one of a pair of electrodes of the capacitor and is configured to be one of a source electrode and a drain electrode of the transistor.

12. The semiconductor device according to claim 10,
wherein the first conductive layer is configured to be one of a pair of electrodes of the capacitor and is configured to be a gate electrode of the transistor.

13. The semiconductor device according to claim 10,
wherein the at least one of the Group 3 elements in the periodic table is one or both of lanthanum and yttrium.

14. The semiconductor device according to claim 10,
wherein the first conductive layer and the second conductive layer each comprise tungsten or ruthenium.

15. The semiconductor device according to claim 10,
wherein the capacitor further comprises a first layer and a second layer,
wherein the first layer is positioned between the first conductive layer and the first insulating layer,
wherein the second layer is positioned between the first insulating layer and the second conductive layer,
wherein the first layer comprises a metal included in the first conductive layer and oxygen, and
wherein the second layer comprises a metal included in the second conductive layer and oxygen.

16. The semiconductor device according to claim 10,
wherein a semiconductor layer included in the transistor comprises one or both of indium and zinc.

17. The semiconductor device according to claim 1, wherein the second insulating layer has a barrier property against oxygen.

18. The semiconductor device according to claim 10, wherein at least parts of the transistor and the capacitor are positioned in an opening portion.
